(19) United States
(12) Patent Application Publication
(10) Pub. No.: US 2008/0185705 A1
(43) Pub. Date: Aug. 7, 2008

(54) Microelectronic packages and methods therefor

(75) Inventors: Philip R. Osborn, San Jose, CA (US); Belgacem Haba, Saratoga, CA (US); Ellis Chau, San Jose, CA (US); Giles Humpston, Aylesbury (GB); Masud Beroz, San Jose, CA (US); Teck-Gyu Kang, San Jose, CA (US); Dat Nghe Duong, San Jose, CA (US); Jae M. Park, San Jose, CA (US); Jesse Burl Thompson, Brentwood, CA (US); Richard Dewitt Crisp, Castro Valley, CA (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/895,191

(22) Filed: Aug. 23, 2007

Related U.S. Application Data
(63) Continuation of application No. 11/641,608, filed on Dec. 19, 2006, now abandoned.
(60) Provisional application No. 60/753,605, filed on Dec. 23, 2005.

(51) Int. Cl. H01L 23/48

(52) U.S. Cl. 257/690; 257/E23.169

(57) ABSTRACT

A microelectronic package includes a microelectronic element having a first face including contacts, and a flexible substrate having a first surface and a second surface, conductive posts projecting from the first surface and conductive terminals accessible at the second surface, at least some of the conductive terminals and the conductive posts being electrically interconnected and at least some of the conductive terminals being offset from the conductive posts. The first surface of the flexible substrate is juxtaposed with the first face of the microelectronic element so that the conductive posts project from the flexible substrate toward the first face of the microelectronic element. The conductive posts are electrically interconnected with the contacts of the microelectronic element and at least some of the conductive terminals are movable relative to the microelectronic element.

### CROSS REFERENCE TO RELATED APPLICATIONS

This application is a continuation of U.S. application Ser. No. 11/641,608, filed on Dec. 19, 2006, which application claims the benefit of U.S. Provisional Patent Application No. 60/753,605 filed Dec. 23, 2005, the disclosures of which are incorporated herein by reference.

### FIELD OF THE INVENTION

The present invention relates to microelectronic packages and to methods of making and testing microelectronic packages.

### BACKGROUND OF THE INVENTION

Microelectronic devices such as semiconductor chips typically require many input and output connections to other electronic components. The input and output contacts of a semiconductor chip or other comparable device are generally disposed in grid-like patterns that substantially cover a surface of the device (commonly referred to as an “area array”) or in elongated rows which may extend parallel to and adjacent each edge of the device's front surface, or in the center of the front surface. Typically, devices such as chips must be physically mounted on a substrate such as a printed circuit board, and the contacts of the device must be electrically connected to electrically conductive features of the circuit board.

Semiconductor chips are commonly provided in packages that facilitate handling of the chip during manufacture and during mounting of the chip on an external substrate such as a circuit board or other circuit panel. For example, many semiconductor chips are provided in packages suitable for surface mounting. Numerous packages of this general type have been proposed for various applications. Most commonly, such packages include a dielectric element, commonly referred to as a “chip carrier” with terminals formed as plated or etched metallic structures on the dielectric. These terminals typically are connected to the contacts of the chip itself by features such as thin traces extending along the chip carrier itself and by fine leads or wires extending between the contacts of the chip and the terminals or traces. In a surface mounting operation, the package is placed onto a circuit board so that each terminal on the package is aligned with a corresponding contact pad on the circuit board. Solder or other bonding material is provided between the terminals and the contact pads. The package can be permanently bonded in place by heating the assembly so as to melt or “reflow” the solder or otherwise activate the bonding material.

Many packages include solder masses in the form of solder balls, typically about 0.1 mm and about 0.8 mm (5 and 30 mils) in diameter, attached to the terminals of the package. A package having an array of solder balls projecting from its bottom surface is commonly referred to as a ball grid array or “BGA” package. Other packages, referred to as land grid array or “LGA” packages are secured to the substrate by thin layers or lands formed from solder. Packages of this type can be quite compact. Certain packages, commonly referred to as “chip scale packages,” occupy an area of the circuit board equal to, or only slightly larger than, the area of the device incorporated in the package. This is advantageous in that it reduces the overall size of the assembly and permits the use of short interconnections between various devices on the substrate, which in turn limits signal propagation time between devices and thus facilitates operation of the assembly at high speeds.

Assemblies including packages can suffer from stresses imposed by differential thermal expansion and contraction of the device and the substrate. During operation, as well as during manufacture, a semiconductor chip tends to expand and contract by an amount different from the amount of expansion and contraction of a circuit board. Where the terminals of the package are fixed relative to the chip or other device, such as by using solder, these effects tend to cause the terminals to move relative to the contact pads on the circuit board. This can impose stresses in the solder that connects the terminals to the contact pads on the circuit board. As disclosed in certain preferred embodiments of U.S. Pat. Nos. 5,679,977; 5,148,266; 5,148,265; 5,455,390; and 5,518,964, the disclosures of which are incorporated by reference herein, semiconductor chip packages can have terminals that are movable with respect to the chip or other device incorporated in the package. Such movement can compensate to an appreciable degree for differential expansion and contraction.

Testing of packaged devices poses another formidable problem. In some manufacturing processes, it is necessary to make temporary connections between the terminals of the packaged device and a test fixture, and operate the device through these connections to assure that the device is fully functional. Ordinarily, these temporary connections must be made without bonding the terminals of the package to the test fixture. It is important to assure that all of the terminals are reliably connected to the conductive elements of the test fixture. However, it is difficult to make connections by pressing the package against a simple test fixture such as an ordinary circuit board having planar contact pads. If the terminals of the package are not coplanar, or if the conductive elements of the test fixture are not coplanar, some of the terminals will not contact their respective contact pads on the test fixture. For example, in a BGA package, differences in the diameter of the solder balls attached to the terminals, and non-planarity of the chip carrier, may cause some of the solder balls to lie at different heights.

These problems can be alleviated through the use of specially constructed test fixtures having features arranged to compensate for non-planarity. However, such features add to the cost of the test fixture and, in some cases, introduce some unreliability into the test fixture itself. This is particularly undesirable because the test fixture, and the engagement of the device with the test fixture, should be more reliable than the packaged devices themselves in order to provide a meaningful test. Moreover, devices used for high-frequency operation are typically tested by applying high frequency signals. This requirement imposes constraints on the electrical characteristics of the signal paths in the test fixture, which further complicates construction of the test fixture.

Additionally, when testing packaged devices having solder balls connected with terminals, solder tends to accumulate on those parts of the test fixture that engage the solder balls. This accumulation of solder residue can shorten the life of the test fixture and impair its reliability.

A variety of solutions have been put forth to deal with the aforementioned problems. Certain packages disclosed in the aforementioned patents have terminals that can move with respect to the microelectronic device. Such movement can compensate to some degree for non-planarity of the terminals during testing.

U.S. Pat. Nos. 5,196,726 and 5,214,308, both issued to Nishiguchi et al., disclose a BGA-type approach in which bump leads on the face of the chip are received in cup-like sockets on the substrate and bonded therein by a low-melting point material. U.S. Pat. No. 4,975,079 issued to Beaman et al. discloses a test socket for chips in which dome-shaped contacts on the test substrate are disposed within conical guides. The chip is forced against the substrate so that the solder balls enter the conical guides and engage the dome-shaped pins on the substrate. Sufficient force is applied so that the dome-shaped pins actually deform the solder balls of the chip.

A further example of a BGA socket may be found in commonly assigned U.S. Pat. No. 5,802,699, issued Sep. 8, 1998, the disclosure of which is hereby incorporated by reference herein. The '699 patent discloses a sheet-like connector having a plurality of holes. Each hole is provided with at least one resilient laminar contact extending inwardly over a hole. The bump leads of a BGA device are advanced into the holes so that the bump leads are engaged with the contacts. The assembly can be tested, and if found acceptable, the bump leads can be permanently bonded to the contacts.

Commonly assigned U.S. Pat. No. 6,202,297, issued Mar. 20, 2001, the disclosure of which is hereby incorporated by reference herein, discloses a connector for microelectronic devices having bump leads and methods for fabricating and using the connector. In one embodiment of the '297 patent, a dielectric substrate has a plurality of posts extending upwardly from a front surface. The posts may be arranged in an array of post groups, with each post group defining a gap therebetween. A generally laminar contact extends from the top of each post. In order to test a device, the bump leads of the device are each inserted within a respective gap thereby engaging the contacts which wipe against the bump lead as it continues to be inserted. Typically, distal portions of the contacts deflect downwardly toward the substrate and outwardly away from the center of the gap as the bump lead is inserted into a gap.

Commonly assigned U.S. Pat. No. 6,177,636, the disclosure of which is hereby incorporated by reference herein, discloses a method and apparatus for providing interconnections between a microelectronic device and a supporting substrate. In one preferred embodiment of the '636 patent, a method of fabricating an interconnection component for a microelectronic device includes providing a flexible chip carrier having first and second surfaces and coupling a conductive sheet to the first surface of the chip carrier. The conductive sheet is then selectively etched to produce a plurality of substantially rigid posts. A compliant layer is provided on the second surface of the support structure and a microelectronic device such as a semiconductor chip is engaged with the compliant layer so that the compliant layer lies between the microelectronic device and the chip carrier, and leaving the posts projecting from the exposed surface of the chip carrier. The posts are electrically connected to the microelectronic device. The posts form projecting package terminals that can be engaged in a socket or solder-bonded to features of a substrate as, for example, a circuit panel. Because the posts are movable with respect to the microelectronic device, such a package substantially accommodates thermal coefficient of expansion mismatches between the device and a supporting substrate when the device is in use. Moreover, the tips of the posts can be coplanar or nearly coplanar.

Despite all of the above-described advances in the art, still further improvements in making and testing microelectronic packages would be desirable.

### SUMMARY OF THE INVENTION

One aspect of the invention provides a microelectronic package including a microelectronic element such as a semiconductor chip and a flexible substrate spaced from and overlying a first face of the microelectronic element. The package according to this aspect of the invention desirably includes a plurality of conductive posts extending from the flexible substrate and projecting away from the microelectronic element, with at least some of the conductive posts being electrically interconnected with said microelectronic element. Most preferably, the package according to this aspect of the invention includes a plurality of support elements disposed between the microelectronic element and said substrate and supporting said flexible substrate over the microelectronic element. Desirably, at least some of the conductive posts are offset in horizontal directions parallel to the plane of the flexible substrate from the support elements. For example, the support elements may be disposed in an array with zones of the flexible substrate disposed between adjacent support elements, and the posts may be disposed near the centers of such zones.

The offset between the posts and the support elements allows the posts, and particularly the bases of the posts adjacent the substrate, to move relative to the microelectronic element. Most preferably, the arrangement allows each post to move independently of the other posts. The movement of the posts allows the tips of the plural posts to simultaneously engage contact pads on a circuit board despite irregularities in the circuit board or the package, such as warpage of the circuit board. This facilitates testing of the package using a simple test board, which may have substantially planar contacts, and avoids the need for specialized, expensive test sockets.

Most preferably, the flexible substrate overlies the front or contact-bearing face of the microelectronic element. At least some of the support elements desirably are electrically conductive elements such as solder balls. The conductive support elements may electrically interconnect at least some of the contacts of the microelectronic element with at least some of the conductive posts. In preferred forms, this arrangement can prove low-impedance conductive paths between the posts and the microelectronic element, suitable for high-frequency signal transmission. Most desirably, at least some of the posts are connected to at least some of the contacts on the microelectronic element by conductive support elements immediately adjacent to those posts. Preferably, conductive traces provided on the flexible substrate electrically interconnect at least some of the conductive posts with at least some of the conductive support elements. These traces may be very short; the length of each trace desirably is equal to the offset distance between a single post and a single support element.

A further aspect of the present invention provides a microelectronic assembly, which desirably includes a package as discussed above and a circuit panel having contact pads. Tips of the posts remote from the flexible substrate confront the contact pads and are electrically connected thereto, most preferably by electrically conductive bonding material such as solder. As further discussed below, the assembly can be compact and highly reliable.

A further aspect of the invention provides a microelectronic package, which includes a microelectronic element and a flexible substrate spaced from and overlying said microelectronic element. The flexible substrate is supported above said front face of said microelectronic element so that said substrate is at least partially unconstrained in flexure. For example, the flexible substrate may be supported by support elements as described above, or by other means such as a continuous compliant layer. Here again, the package includes a plurality of conductive posts extending from the flexible substrate and projecting away from the microelectronic element, the conductive posts being electrically connected to the microelectronic element. The conductive posts have bases facing toward the flexible substrate. The package according to this embodiment of the invention desirably includes elements referred to herein as “focusing elements” disposed between the bases of at least some of the posts and the substrate and mechanically interconnecting the bases of the conductive posts with the substrate. The focusing elements desirably have smaller areas than the bases of the posts. As further discussed below, this arrangement facilitates flexing of the substrate and movement of the posts.

Yet another aspect of the invention provides methods of processing microelectronic packages. Method according to this aspect of the invention desirably include the step of advancing a microelectronic package having a flexible substrate supported over a surface of a microelectronic element and having electrically conductive posts projecting from said substrate until tips of said posts engage contact pads on a test circuit panel and the substrate flexes so that at least some base portions of said posts adjacent said flexible substrate move relative to the microelectronic element. In preferred methods according to this aspect of the present invention, movement of the bases of the posts contribute to movement of the tips, allowing the tips to engage contact pads even where the contact pads themselves are not coplanar with one another.

The method according to this aspect of the invention may include the further steps of maintaining the tips of the posts in contact with said contact pads and testing the package during the maintaining step, as by transmitting signals to and from the package through the engaged contact pads and posts. The method may be practiced using a simple circuit panel, with simple contact pads. The method may further include disengaging the tips from the contact pads after testing, and may also include bonding the tips of the posts to electrically conductive elements of a circuit panel after disengagement from the test circuit panel.

One aspect of the present invention, a provides a microelectronic package which includes a mounting structure, a microelectronic element associated with the mounting structure, and a plurality of conductive posts physically connected to the mounting structure and electrically connected to the microelectronic element. The conductive posts desirably project from the mounting structure in an upward direction. At least one of the conductive posts may be an offset post. Each offset post preferably has a base connected to the mounting structure, the base of each offset post defining a centroid. As further explained below, where the base has a regular, biaxially symmetrical or point symmetrical shape such as a circle, the centroid is simply the geometric center of the base. Each offset post also desirably defines an upper extremity having a centroid, the centroid of the upper extremity being offset from the centroid of the base in a horizontal offset direction transverse to the upward direction. When the package according to this aspect of the invention is engaged with an external unit such as a test fixture, vertically directed contact forces are applied by the contact pads of the external unit. The contact forces applied to each offset post are centered at the centroid of the upper extremity. The reaction forces applied by the mounting structure to the base of the post are centered at the centroid of the base. Because these centroids are offset from one another, the forces applied to the post tend to tilt it about a horizontal axis. Tilting of the post causes the upper extremity of the post to wipe across the surface of the contact pad, which promotes good contact between the post and the contact pad. The mounting structure desirably is deformable, so that the bases of the posts can move relative to the microelectronic element in the tilting mode discussed above. The mounting structure also may be arranged to deform so as to permit translational movement of the posts in a vertical direction, toward the microelectronic element. The movement of individual posts may differ, so that the tips of numerous posts can be engaged with numerous contact pads even where the tips of the posts are not coplanar with one another, the contact pads are not coplanar with one another, or both, prior to engagement of the posts and contact pads.

In certain embodiments, each offset post may have a tip end defining a plane transverse to the upward direction. In other embodiments, each offset post may comprise a first body including the base of the offset post and a second body formed atop the first body, the second body including the extremity of the offset post. The offset posts may have sharp features at or adjacent their upper extremities.

The mounting structure may include a flexible substrate, which may have conductive traces formed thereon for electrically interconnecting the posts with a microelectronic element. The flexible substrate may be a generally sheet like substrate extending substantially in a horizontal plane, the substrate having a top surface and a bottom surface, the conductive posts projecting upwardly from the top surface. The flexible substrate may also include a plurality of gaps extending through the substrate and defining a plurality of regions, different ones of the posts being disposed on different ones of the regions such as disclosed in commonly assigned U.S. patent application Ser. No. 10/985,119, entitled “MICRO PIN GRID WITH PIN MOTION ISOLATION,” filed on Nov. 10, 2004, the disclosure of which is hereby incorporated herein by reference. The package may incorporate a support layer such as a compliant layer disposed between the flexible substrate and the microelectronic element. In other embodiments, the package may include a plurality of support elements spaced apart from one another and disposed between the flexible substrate and the microelectronic element, the bases of the posts being spaced horizontally from the support elements as described in greater detail in the co-pending, commonly assigned U.S. patent application Ser. No. 11/014,439, entitled “MICROELECTRONIC PACKAGES AND METHODS THEREFOR,” filed on Dec. 16, 2004, the disclosure of which is hereby incorporated herein by reference.

The microelectronic element of the package preferably has faces and contacts, the contacts being electrically interconnected with the conductive posts. In certain embodiments, the contacts are exposed at a first face of the microelectronic element and the mounting structure overlies the first face. In other embodiments, the contacts are exposed at a first face of the microelectronic element and the mounting structure overlies a second, oppositely directed face of the microelectronic element.

A further aspect of the invention includes methods of processing packages such as those discussed above. In such methods, the package is tested by advancing the microelectronic package toward a substrate such as a test fixture having contact pads. The package is advanced until the upper extremities of one or more posts engage the contact pads of the substrate. During engagement, at least one of the offset posts preferably tilts about a horizontal axis. As described above, the tilting of the posts provides a wiping action of the post tips on opposing contact pads of a test board. The conductive posts may then be maintained in contact with the contact pads of the substrate during testing the package. After the testing step, the package may be disengaged from the contact pads, and the conductive posts of the microelectronic package may be bonded to electrically conductive elements of a circuit panel.

Another aspect of the present invention provides a microelectronic package including a mounting structure, a microelectronic element associated with the mounting structure, and a plurality of conductive terminals carried on the mounting structure. Each of the conductive terminals desirably has an exposed contact surface. The terminals, the mounting structure or both are plastically deformable by the contact forces applied upon engagement of the terminals with an external unit such as a test fixture. Thus, the exposed contact surfaces can be displaced relative to the microelectronic element. In certain embodiments, at least some of the conductive terminals are plastically deformable posts having tips defining at least some of the contact surfaces, the plastically deformable posts being plastically deformable so that the tips can be displaced relative to the bases of the posts. In other embodiments, the mounting structure includes a plastically deformable support structure. As further explained below, the plastically deformable elements of the package in certain preferred embodiments allow the contact surfaces of the terminals to move through an appreciable range of motion, greater than that which could be achieved using elements of comparable size operating entirely in the elastic mode during engagement with the test substrate. Preferred embodiments according to this aspect of the invention thus provide a package with the ability to compensate for substantial non-planarity of the terminals, of the test fixture, or both.

A related aspect of the invention provides further methods of processing a microelectronic package. In such a method, the microelectronic package may be processed by engaging the exposed conductive terminals of the microelectronic package with an external element such as a test fixture so as to plastically deform at least one element of the package so as to bring the conductive terminals into electrical contact with the test fixture. The package may then be tested while the conductive terminals are engaged with the test fixture. After testing the conductive terminals may be disengaged from the test fixture, and bonded to contact pads of a circuit panel. The package may be heated during assembly or testing.

In yet another aspect of the invention, of the present invention, a microelectronic package includes a microelectronic element, and a plurality of electrically conductive posts projecting upwardly away from the microelectronic element, whereby each post has an upper extremity remote from the microelectronic element. At least some of the posts are preferably multi-element posts, each multi-element post including plurality of tip elements defining the upper extremity of the posts. The tip elements are desirably adapted to deform upon engagement with a contact pad so that the tip elements move away from one another and wipe across an opposing contact pad.

A still further aspect of the invention provides methods of making microelectronic packages and elements of such packages. A method according to this aspect of the invention desirably includes providing a blank made of a conductive material such as copper, applying a fluid under pressure, desirably a liquid, to the blank to form at least one conductive terminal in the blank, and providing electrical interconnections to the at least one conductive terminal. The at least one conductive terminal may be a conductive post. The method may also include heating the blank so as to make the blank more ductile during the forming operation.

In preferred embodiments, the blank is placed atop a mold having one or more depressions formed therein and the blank is secured over the one or more depressions of the mold. Fluid pressure is desirably applied to using a pressure chamber engaged with the blank so as to force portions of the blank into the depressions. In other embodiments, the fluid pressure is applied by directing a fluid stream against a face of the blank. Terminal formation using fluid pressure facilitates the formation of conductive terminals having complex shapes. Such complex conductive terminals may also be produced in large volumes and at low cost.

The methods according to this aspect of the invention may further include providing electrical interconnections to the at least one conductive terminal, desirably by removing portions of the blank, such as by using an etching process, to form at least one conductive trace connected with the at least one conductive terminal. The at least one conductive terminal may comprise a plurality of conductive terminals and the at least one conductive trace may comprise a plurality of conductive traces, with each conductive trace interconnected with one of the conductive terminals. At least one of the conductive traces may be electrically interconnected with a microelectronic element, such as a semiconductor chip.

The method of making a microelectronic package may also include providing a mounting structure such as a dielectric substrate so that the at least one conductive terminal and the at least one trace are physically connected to the dielectric substrate. The dielectric substrate may be united with the blank either before, during or after portions of the blank are removed to form the at least one conductive trace.

In certain preferred embodiments of the present invention a microelectronic package includes a microelectronic element, such as a semiconductor chip, having faces and contacts, and a flexible substrate overlying and spaced from a first face of the microelectronic element. The flexible substrate may include a dielectric sheet or a polymeric film. The package also preferably includes a plurality of conductive terminals exposed at a surface of the flexible substrate, the conductive terminals being electrically interconnected with the microelectronic element. In this aspect of the invention, the flexible substrate most desirably includes a gap extending at least partially around at least one of the conductive terminals and defining a region holding one or more terminals which region can be displaced at least partially independently of the remainder of the substrate. In preferred embodiments according to this aspect of the present invention, the gap facilitates flexing of the substrate, and thus facilitates movement of the terminals. This action is useful during engagement of the terminals with a test fixture.

The flexible substrate may include a plurality of gaps defining a plurality of regions of the substrate. In such an arrangement, each of the conductive terminals may be connected with one of the plurality of regions so that the conductive terminals are free to move independently of one another. For example, the gap in the flexible substrate may extend more than halfway around the at least one of the conductive terminals to define a flap portion of the flexible substrate that is hingedly connected with a remaining portion of the flexible substrate. The conductive terminals may be mounted on the flap portion of the flexible substrate.

The conductive terminals desirably face away from the first face of the microelectronic element. The conductive terminals may include conductive posts that extend from the flexible substrate and project away from the first face of the microelectronic element. The tips of the posts can move in horizontal directions upon flexure of the substrate. As further discussed below, this can cause the tips of the posts to wipe across the surfaces of terminals on a test circuit board.

The microelectronic package may also include a support layer disposed between the first face of the microelectronic element and the flexible substrate. The support layer may include one or more openings, the openings being partially aligned with the conductive terminals so as to provide asymmetrical support to the terminals. As further explained below, such asymmetrical support can promote tilting of the terminals and wiping action. In other embodiments, the at least one opening in the support layer is substantially aligned with one of said conductive terminals. The support layer optionally may be formed from a compliant material.

In other preferred embodiments, the gap defines first and second regions of the flexible substrate, whereby the first region is movable relative to the second region, and the at least one of the conductive terminals lies in the first region of the flexible substrate. The gap may extend at least partially around two or more of the conductive terminals. The gap may also lie between two or more of the conductive terminals. The gap may have an asymmetrical shape, a symmetrical shape, or may be in the form of a circular segment. The gap may also be continuous or intermittent. In still other preferred embodiments, the flexible substrate may have a plurality of gaps that give the substrate a web-like appearance. In this case, the electrically conductive components of the package are provided on the substrate, between the gaps.

The contacts of the microelectronic element are desirably accessible at the first face of the microelectronic element. That is, the flexible substrate overlies the front or contact-bearing face of the microelectronic element. However, the microelectronic element may have a second face opposite the first face and the contacts may be accessible at the second face of the microelectronic element.

The microelectronic package may also include conductive elements, such as conductive traces provided on said flexible substrate, for electrically interconnecting said conductive terminals and said microelectronic element.

In a further aspect of the present invention, a microelectronic package includes a microelectronic element having faces and contacts, a support layer, such as a compliant support layer, overlying a first face of the microelectronic element, and a flexible substrate overlying the support layer and spaced from the first face of the microelectronic element. The package also desirably includes a plurality of conductive terminals exposed at a surface of the flexible substrate, the conductive terminals being electrically interconnected with the microelectronic element. The support layer has at least one opening at least partially aligned with at least one of the conductive terminals. The openings in the support layer enhance flexibility of the substrate in the vicinity of the terminals. In certain embodiments, the terminals are substantially aligned with the openings of the support layer.

In other embodiments, the conductive terminals are only partially aligned with the plurality of openings. Stated another way, the terminals are offset with respect to the openings to provide asymmetrical support. As further explained below, this causes the terminals to tilt as the substrate flexes over the openings. Here again, the conductive terminals may include conductive posts extending from the flexible substrate and projecting away from the first face of the microelectronic element.

In still another preferred embodiment of the present invention, a microelectronic package includes a microelectronic element having faces and contacts, a support layer, such as a compliant support layer, overlying a first face of the microelectronic element, the support layer having a plurality of openings, and a plurality of conductive terminals overlying the microelectronic element and being electrically interconnected with the microelectronic element. Each conductive terminal desirably has a base having a first section overlying the support layer and a second section overlying one of the openings of the support layer. Here again, the terminals may be in the form of posts. In this arrangement, the terminals may be physically held over the openings by structures other than a flexible dielectric substrate. For example, the traces connecting the terminals to the microelectronic element may also serve as flexible mountings for the terminals. In this arrangement as well, the support layer can be configured to provide asymmetrical support and to cause the terminals to tilt upon engagement with contact elements as, for example, the contact elements of a test fixture.

Still further aspects of the present invention provide methods of processing microelectronic element. In certain methods according to this aspect of the invention, a microelectronic package having a microelectronic element, a mounting structure and a plurality of terminals carried on the mounting structure and electrically connected to the microelectronic element, is advanced toward a mating unit such as a test board until the terminals engage contact elements of the mating unit and vertically-directed contact forces applied by the contact elements to the terminals cause the mounting structure to deform so that at least some of the terminals move. The deformation of the mounting structure may cause the terminals to tilt about horizontal axes. Where the terminals are vertically-extensive structures such as posts, this causes the tips of the posts to wipe across the contact elements of the mating unit. Where the mounting structure includes a flexible substrate having gaps therein, a support layer having openings therein, or both, these features facilitate deformation of the mounting structure.

In certain preferred embodiments of the present invention, an assembly for testing microelectronic devices includes a microelectronic element having faces and contacts, a flexible substrate, such as a dielectric sheet, spaced from and overlying a first face of the microelectronic element, and a plurality of conductive posts extending from the flexible substrate and projecting away from the first face of the microelectronic element. At least some of the conductive posts are desirably electrically interconnected with the microelectronic element. The conductive posts may have a base facing toward the flexible substrate. The assembly may incorporate one or more of the features disclosed in commonly assigned U.S. Provisional Application Ser. No. 60/662,199, entitled “MICROELECTRONIC PACKAGES AND METHODS THEEFOR,” filed Mar. 16, 2005 [TESSERA 3.8-429], the disclosure of which is hereby incorporated by reference herein.

The assembly also desirably includes a plurality of support elements disposed between the microelectronic element and the substrate. The support elements desirably support the flexible substrate over the microelectronic element, with at least some of the conductive posts being offset from the support elements. A compliant material may be disposed between the flexible substrate and the microelectronic element.

In certain preferred embodiments, at least one of the conductive support elements includes a mass of a fusible material. In other preferred embodiments, at least one of the conductive support elements includes a dielectric core and an electrically conductive outer coating over the dielectric core. The support element may also be elongated, having a length that is greater than its width or diameter.

The microelectronic element may be a printed circuit board or a test board used to test devices such as microelectronic elements and microelectronic packages. The first face of the microelectronic element may be a front face of the microelectronic element and the contacts may be accessible at the front face. In certain preferred embodiments, at least some of the support elements are electrically conductive. The conductive support elements desirably electrically interconnect at least some of the contacts of the microelectronic element with at least some of the conductive posts. In certain preferred embodiments, the support elements include a plurality of second conductive posts extending from the flexible substrate. The second conductive posts preferably project toward the first face of the microelectronic element, with at least some of the second conductive posts being electrically interconnected with the first conductive posts. In certain preferred embodiments, a first conductive post is electrically interconnected to a contact through a second conductive post disposed immediately adjacent to the first conductive post.

The assembly may also include a support frame engaging the flexible substrate. In certain preferred embodiments the flexible substrate has an outer periphery and the support frame is attached to the outer periphery of the flexible substrate. The support frame may be a ring that is attached to the outer periphery of the flexible substrate. The support frame may be made of sturdy materials such as metal, ceramic and hardened plastic.

The testing assembly may also include conductive traces provided on the flexible substrate, whereby the conductive traces electrically interconnect at least some of the conductive posts with at least some of the contacts on the microelectronic element. In certain preferred embodiments, the flexible substrate has a bottom surface facing the first face of the microelectronic element and the conductive traces extend along the bottom surface of the flexible substrate. In other preferred embodiments, the flexible substrate has a top surface facing away from the first face of the microelectronic element and the conductive traces extend along the top surface of the flexible substrate.

The contacts may be spaced from one another in a grid array over the first face of the microelectronic element. In other preferred embodiments, at least some of the contacts are aligned in a row. The contacts may be uniformly spaced from one another over the first face of the microelectronic element. In further preferred embodiments, some of the contacts are uniformly spaced from one another and other contacts are non-uniformly spaced from one another.

The conductive posts may be elongated, whereby the posts have a length that is substantially greater than the width or diameter of the posts. The support elements may be disposed in an array so that the support elements define a plurality of zones on the flexible substrate, each zone being bounded by a plurality of the support elements defining corners of the zone, with different ones of the conductive posts being disposed in different ones of the zones. In preferred embodiments, only one of the conductive posts is disposed in each of the zones.

In another preferred embodiments of the present invention, a microelectronic assembly includes a microelectronic element having faces and contacts, a flexible substrate spaced from and overlying a first face of the microelectronic element, and a plurality of first conductive posts extending from the flexible substrate and projecting away from the first face of the microelectronic element, at least some of the conductive posts being electrically interconnected with the microelectronic element. The assembly also desirably includes a plurality of second conductive posts extending from the flexible substrate and projecting toward the first face of the microelectronic element, the second conductive posts supporting the flexible substrate over the microelectronic element, at least some of the first conductive posts being offset from the second conductive posts.

In preferred embodiments, at least some of the second conductive posts are electrically conductive, the second conductive posts electrically interconnecting at least some of the contacts of the microelectronic element with at least some of the first conductive posts. At least some of the first conductive posts may be connected to at least some of the contacts by second conductive posts located immediately adjacent to the first conductive posts. The assembly may also include conductive traces provided on the flexible substrate, whereby the conductive traces electrically interconnect at least some of the first conductive posts with at least some of the contacts on the microelectronic element. In certain preferred embodiments, at least one of the conductive traces extends between adjacent conductive posts.

In certain preferred embodiments, the assembly may also include a low temperature cofired ceramic (LTCC) structure having a plurality of ceramic layers that are attached together including a bottom layer with contacts, whereby the first conductive posts are electrically interconnected with the contacts of the bottom layer of the LTCC structure. The assembly may also include a sealing cap in contact with a top layer of the LTCC structure and in thermal communication with a second face of the microelectronic element.

In another preferred embodiment of the present invention, a microelectronic assembly includes a microelectronic element having faces and contacts, and a flexible substrate spaced from and overlying a first face of the microelectronic element, the flexible substrate having conductive traces provided thereon. The assembly also desirably includes a plurality of conductive elements extending between the contacts of the microelectronic element and the conductive traces for spacing the flexible substrate from the microelectronic element and for electrically interconnecting the microelectronic element and the conductive traces. The conductive elements may be elongated, conductive posts. The conductive traces preferably have inner ends connected with the conductive elements and outer ends that extend beyond an outer perimeter of the microelectronic element. The outer ends of the conductive traces are desirably movable relative to the contacts of the microelectronic element. The assembly may also include an encapsulant material disposed between the microelectronic element and the flexible substrate.

In another preferred embodiment of the present invention, a microelectronic assembly desirably includes a circuitized substrate having metalized vias extending from a first surface of the substrate toward a second surface of the substrate. The assembly may also include a microelectronic package having conductive posts projecting therefrom, the conductive posts being at least partially inserted into openings of the metalized vias for electrically interconnecting the microelectronic package and the substrate. The microelectronic package may include a microelectronic element having faces and contacts, a flexible substrate spaced from and overlying a first face of the microelectronic element, and a plurality of support elements extending between the microelectronic element and the flexible substrate for spacing the flexible substrate from the microelectronic element. The conductive posts are preferably electrically interconnected with the contacts of the microelectronic element and are provided on a region of the flexible substrate that is located outside a perimeter of the microelectronic element. The conductive posts are desirably movable relative to the contacts of the microelectronic element.

In another preferred embodiment of the present invention, a method of making a post array substrate includes providing a flexible substrate having traces thereon, the substrate having top and bottom surfaces. The method also preferably includes providing first conductive posts on the flexible substrate, the first conductive posts projecting from the top surface of the substrate, with at least some of the first conductive posts being electrically interconnected with the traces. The method may also include providing second conductive posts on the flexible substrate, the second conductive posts projecting from the bottom surface of the substrate, with the first and second conductive posts extending away from one another.

The method may also include electrically interconnecting at least some of the second conductive posts with at least some of the first conductive posts. The substrate may be assembled with a microelectronic element, such as a chip or printed circuit board, so that the top surface of the substrate faces away from the microelectronic element. The assembling step preferably comprises using the second conductive posts for supporting the substrate above the microelectronic element so that the substrate is at least partially free to flex. The method may also include providing a filler material, such as a compliant, dielectric encapsulant, between the substrate and the microelectronic element.

Desirably, at least some of the first conductive posts are offset, in horizontal directions parallel to the plane of the flexible substrate, from the second conductive posts. For example, the second conductive posts may be disposed in an array with zones of the flexible substrate disposed between adjacent support elements, and the first conductive posts may be disposed near the centers of the zones. The offset between the first conductive posts and the second conductive posts allows the first conductive posts, and particularly the bases of the first conductive posts adjacent the substrate, to move relative to the microelectronic element. Most preferably, the arrangement allows each first conductive post to move independently of the other first conductive posts. The movement of the first conductive posts allows the tips of the first conductive posts to simultaneously engage contact pads on an opposing microelectronic element, such as a chip or chip package, despite irregularities in the chip or the package, such as warpage of the chip or package.

Assemblies in accordance with preferred embodiments of the present invention facilitate testing of microelectronic elements and packages having non-planar contacts and interfaces, and avoids the need for specialized, expensive test equipment. In preferred methods according to this aspect of the present invention, movement of the bases of the conductive posts contribute to movement of the tips of the posts, allowing the tips to engage opposing contact pads even where the contact pads themselves are not coplanar with one another.

As noted above, conductive traces may be provided on a flexible substrate for electrically interconnecting at least some of the first conductive posts with at least some of the second conductive posts. These traces may be very short; the length of each trace desirably is equal to the offset distance between a first conductive post and a second conductive post. In preferred forms, this arrangement can prove low-impedance conductive paths between the posts and the microelectronic element, suitable for high-frequency signal transmission.

In certain preferred embodiments of the present invention, a microelectronic assembly includes a microelectronic element such as semiconductor chip having a front fact including contacts. A flexible substrate is secured over the front face of the microelectronic element. The flexible substrate includes at least one opening that is in alignment with at least one of the contacts provided on the microelectronic element. The flexible substrate preferably includes conductive traces extending over the flexible substrate and conductive posts attached to the ends of the conductive traces. The conductive posts preferable project away from the microelectronic element. The conductive traces are electrically interconnected with the one or more contacts on the microelectronic element by wire bonds that have a profile height. An encapsulant is preferably provided over the wire bonds, whereby the encapsulant has a profile height that is less than the height of the conductive posts. In one preferred embodiment, a stencil may be provided over the substrate for stenciling the encapsulant over the wire bonds. The stencil is preferably more rigid then the flexible substrate. In certain preferred embodiments, the stencil may engage the conductive posts for bending the flexible substrate at the edges of the microelectronic element during a stenciling operation.

In another preferred embodiment of the present invention, the conductive posts are formed using a stud bumping process. In certain preferred embodiments, a machine similar to a wire bonding machine may be used for forming a stud bump having a ball section engaged with a top surface of a substrate, contact or conductive pad and a tail that projects upwardly from the ball section. The stud bumping machine may be programmed to position the stud bumps at various locations on a substrate or microelectronic element. The ball size and tail height of the stud bump may be varied by changing the profile of the bore of the capillary of the stud bumping machine. In certain preferred embodiments, multiple stud bumps may be stacked one atop another for controlling the overall height of the conductive post. In preferred embodiments, the stud bump is made of a conductive material and includes an outer layer that is preferably made from a noble metal such as gold. In certain preferred embodiments, the core of the stud bump is made of a conductive metal such as copper and the outer layer of the stud bump is formed by depositing a layer of nickel and then a layer of gold atop the nickel layer. In certain preferred embodiments, some of the conductive posts may have a greater length or height than other conductive posts formed on the same substrate. In other preferred embodiments, a first set of conductive post may have a first height, a second set of conductive post may have a second height that is different than the first height and a third set of conductive post may have a third height that is different than the first and second heights.

In another preferred embodiment of the present invention, a microelectronic element includes a conductive pad having two or more conductive post projecting therefrom. The two or more conductive posts are preferably spaced from one another atop the single conductive pad. Although the invention is not limited by any particular theory of operation, it is believed that providing two or more conductive posts on a single conductive pad will provide a mechanism for capturing a conductive element such as a solder ball. In more preferred embodiments, a microelectronic element includes a conductive pad having three conductive posts that are spaced from one another for capturing a conductive mass such as a solder ball. The spaced conductive posts may be formed using a stud bumping machine. The above described stud bump structures may be formed on any of the assemblies disclosed herein.

In another preferred embodiment, of the present invention, a substantially rigid substrate has one or more vias extending therethrough. The vias may be metalized so as to provide conductive pads on the top and bottom surfaces of the substrate. A flexible substrate may be provided over either the top or bottom surface of the rigid substrate. The flexible substrate preferably has one or more conductive traces formed thereon. The conductive traces preferably have first ends that are in contact with one of the conductive pads on the top or bottom surface of the substrate and second ends that overly one of the vias. Providing the flexible substrate over the vias provides mechanical decoupling of the traces from the substrate. One or more conductive posts may be attached to the second ends of the traces overlying the vias. In other preferred embodiments, the conductive posts extend from both the top and bottom surfaces of the substrate. In these embodiments, a first set of conductive posts are attached to the first substrate overlying the top surface and a second set of conductive post are attached to a second flexible substrate overlying the bottom surface of the ridges substrate. The conductive posts are movable relative to the rigid substrate for providing compliancy and vertical movement. In another preferred embodiment of the present invention, the vias through the rigid substrate are not metalized. The electrical interconnection between the top and bottom surfaces of the rigid substrate is provided by elongated conductive elements that extend through the rigid substrate, adjacent the non-metalized vias. In still another preferred embodiment of the present invention, the vias in the rigid substrate are non-metalized. The rigid substrate includes metalized auxiliary vias that are located adjacent the main non-metalized vias. The metalized auxiliary vias provide the electrical interconnection from the top to the bottom surface of the rigid substrate.

In another preferred embodiment of the present invention, a microelectronic assembly includes a bare chip or wafer having contacts on a front face thereof. The bare chip or wafer is juxtaposed with a flexible substrate having conductive posts on a top surface thereof and conductive terminals on a bottom surface thereof. At least some of the conductive posts are not aligned with some of the conductive terminals. The conductive posts are preferably interconnected with the conductive terminals. During assembly, the tip ends of the conductive post are abutted against the contacts of the chip or wafer for electrically interconnecting the chip or wafer with the conductive terminals on the flexible substrate. An encapsulant may be provided between the chip/wafer and the flexible substrate. Conductive elements such as solder balls may be provided in contact with the conductive terminals. The misalignment of the conductive terminals with the conductive posts provides compliancy to the package and enables the conductive terminals to move relative to the chip/wafer. In certain preferred embodiments, the conductive posts have an outer layer of gold that is pressed directly against the chip contacts. In other preferred embodiments, the electrical interconnection between the conductive posts and the contacts is formed using an anisotropic conductive film or an anisotropic conductive paste, whereby the conductive particles are disposed between the conductive posts and the contacts. In another preferred embodiment of the present invention, the encapsulant for holding the chip/wafer and the flexible substrate together includes a non-conductive film or paste.

In another preferred embodiment of the present invention, a flexible substrate, such as a dielectric film, includes a conductive trace extending over a bottom surface thereof, and an aperture extending between the top surface and the bottom surface of the flexible substrate. The conductive trace is accessible through the aperture. A conductive mass such as a solder sphere is deposited into the aperture in the dielectric film and onto the conductive trace. Because the solder sphere is unable to wet to the dielectric film, a gap typically forms between the solder and the dielectric film when the solder is transformed into a fusible mass. A polymer material is provided in the gap between the fusible mass and the dielectric film. The polymeric material minimizes the contact angle between the fusible mass and the top surface of the flexible substrate. Although the present invention is not limited by any particular theory of operation, it is believed that providing a polymer collar or ring around the fusible mass will minimize the contact angle with the top surface of the flexible substrate and thereby minimize stress on the fusible mass. As a result, the conductive mass may have a greater profile height than is normally possible, while reducing the likelihood that the conductive mass will peel away from the conductive trace under stress.

In another preferred embodiment of the present invention, a substrate such as a printed circuit board has compliant, conductive lands formed thereon. The compliant lands are metalized and enable an electrical interconnection with the circuitized substrate to be formed. In one preferred embodiment, the substrate includes a top surface and one or more compliant masses formed on the top surface. One or more conductive traces are formed atop the substrate. The conductive traces include a portion that extends of the compliant masses for forming compliant, conductive lands. In one preferred embodiment, the compliant masses project above the top surface of the substrate. In other preferred embodiments, the substrate includes cavities or recesses formed in the top surface thereof and the compliant masses are deposited in the cavities. As a result, the compliant, conductive lands do not extend above the top surface of the substrate. In another preferred embodiment of the present invention, the substrate has recesses formed therein for defining air pockets, and the conductive traces extend over the air pockets. The conductive traces have ends forming conductive lands that are in at least partial alignment with the air pockets. The air pockets provide flexibility for the conductive lands so as to enable to conductive lands to move relative to the substrate.

In another preferred embodiment of the present invention, a substrate includes a top surface having support elements such as solder spheres provided thereon. The solder spheres support and space a flexible substrate from the top surface of the substrate. The flexible substrate preferably has conductive traces formed thereon, with conductive lands connected to the conductive traces. The conductive lands are preferably positioned between the solder spheres so as to provide compliancy to the conductive lands. In certain preferred embodiments, a substrate may have one or more conductive lands formed thereon. The conductive lands may have one or more radially extending gaps formed therein, the radially extending gaps dividing the conductive land into one or more flexible leaves that are able to flex and bend in response to forces. In certain preferred embodiments, a conductive post may be pressed against a segmented land to move the flexible leaves. In certain preferred embodiments, a conductive post may be inserted completely through a land, whereby the flexible leaves bend for locking the conductive post to the conductive land.

In another preferred embodiment of the present invention, a flexible substrate may have a first set of conductive posts provided at one end thereof and a second set of conductive post provided at an opposite end thereof. The flexible substrate preferably has a gap with no conductive posts that extends between the first set of conductive posts and the second set of conductive posts. The first set of conductive posts may be connected to a first microelectronic element such as a printed circuit board and the second set of conductive posts may be connected with a second microelectronic element such as a second printed circuit board. The flexible region of the flexible substrate between the first and second sets of conductive posts enables the assembly to be folded over or bent. In certain preferred embodiments, the flexible substrate supporting the conductive posts is backed by a backing layer. A compliant layer may be positioned between the backing layer and the flexible substrate for providing the conductive posts with compliancy relative to the backing layer.

In another preferred embodiment of the present invention, the substrate structure described above may be folded over so that the first set of conductive posts project upwardly and the second set of conductive posts project downwardly. A compliant material such as an elastomer may be provided between the folded over flexible substrate, between the first and second sets of conductive posts, to provide compliancy to the connection component. The connection component may be positioned between a first microelectronic element above the first set of conductive pins and a second microelectronic element below the second set of conductive posts.

These and other preferred embodiments of the present invention will be described in more detail below.

### BRIEF DESCRIPTION OF THE DRAWINGS

FIG. 1 is a diagrammatic sectional view of a package according to one embodiment of the invention.

FIG. 2 is a fragmentary plan view of the package shown in FIG. 1.

FIG. 3 is a diagrammatic elevational view depicting the package of FIGS. 1-2 in conjunction with a test circuit panel during one step of a method according to one embodiment of the invention.

FIG. 4 is a view similar to FIG. 3 but depicting a later stage of the method.

FIG. 5 is a diagrammatic, idealized perspective view depicting a portion of the package shown in FIGS. 1-4.

FIG. 6 is a fragmentary sectional view depicting a portion of an assembly including the package of FIGS. 1-5.

FIGS. 7-10 are fragmentary sectional views depicting packages according to additional embodiments of the invention.

FIG. 11 is a diagrammatic perspective view depicting a package according to a further embodiment of the invention.

FIG. 12 is a diagrammatic sectional view of the package shown in FIG. 11.

FIGS. 13 and 14 are fragmentary plan views similar to FIG. 2 but depicting packages according to further embodiments of the invention.

FIGS. 15 and 16 are diagrammatic sectional view depicting packages according to still further embodiments of the invention.

FIG. 17A shows a perspective view of an assembly, in accordance with certain preferred embodiments of the present invention.

FIG. 17B shows a sectional view of the assembly of FIG. 17A.

FIG. 17C shows a detailed view of a section of the assembly shown in FIG. 17B.

FIG. 18 shows a cross-sectional view of an assembly, in accordance with other preferred embodiments of the present invention.

FIG. 19 shows a cross-sectional view of an assembly, in accordance with further preferred embodiments of the present invention.

FIG. 20A shows a front elevational view of a testing assembly during a method of testing a microelectronic element, in accordance with one preferred embodiment of the present invention.

FIG. 20B shows the testing assembly of FIG. 20A during a later stage of testing the microelectronic element.

FIG. 21 shows a cross-sectional view of an assembly for testing microelectronic elements, in accordance with still further preferred embodiments of the present invention.

FIGS. 22A-22C show a method of making an assembly including a flexible substrate having conductive posts, in accordance with certain preferred embodiments of the present invention.

FIGS. 23A-23B show a method of testing an assembly including a flexible substrate having conductive posts, in accordance with another preferred embodiment of the present invention.

FIG. 24 shows a front elevational view of a metallic plate used for making a microelectronic subassembly, in accordance with certain preferred embodiments of the present invention.

FIGS. 25A-25E show a method of making a microelectronic subassembly, in accordance with certain preferred embodiments of the present invention.

FIG. 26 shows a front elevational view of the subassembly of FIG. 25E.

FIG. 27A shows another view of the subassembly shown in FIG. 26.

FIG. 27B shows a top plan view of the subassembly in FIG. 27A.

FIG. 28A shows a front elevational view of a microelectronic package, in accordance with certain preferred embodiments of the present invention.

FIG. 28B shows the microelectronic package of FIG. 28A being connected to a circuit board, in accordance with certain preferred embodiments of the present invention.

FIGS. 29A and 29B show a microelectronic package, in accordance with other preferred embodiments of the present invention.

FIGS. 30A-30D show a microelectronic package having a plastically deformable component, in accordance with other preferred embodiments of the present invention.

FIGS. 31A and 31B show a microelectronic package having plastically deformable terminals, in accordance with yet further preferred embodiments of the present invention.

FIG. 32A is a fragmentary plan view of a microelectronic package, in accordance with one preferred embodiment of the present invention.

FIG. 32B is a cross-sectional view of the package shown in FIG. 32A.

FIGS. 33A and 33B show a fragmentary sectional view of the package of FIG. 32A during a testing operation, in accordance with certain preferred embodiments of the present invention.

FIG. 34 is a diagrammatic elevational view of an assembly including the package of FIGS. 32A-33B.

FIG. 35 shows a fragmentary plan view of a microelectronic package, in accordance with other preferred embodiments of the present invention.

FIG. 36A shows a fragmentary plan view of a microelectronic package, in accordance with yet other preferred embodiments of the present invention.

FIG. 36B shows a cross-sectional view of the microelectronic package shown in FIG. 36A.

FIG. 37A shows a fragmentary plan view of a microelectronic package, in accordance with still other preferred embodiments of the present invention.

FIG. 37B shows a cross-sectional view of the microelectronic package shown in FIG. 37A.

FIG. 38A shows a fragmentary plan view of a microelectronic package, in accordance with yet other preferred embodiments of the present invention.

FIG. 38B shows a cross-sectional view of the microelectronic package shown in FIG. 38A.

FIG. 39 shows a cross-sectional view of the microelectronic package shown in FIG. 38A during a testing operation.

FIG. 40 shows a cross-sectional view of the microelectronic package, in accordance with still further preferred embodiments of the present invention.

FIGS. 41A-41C show a method of making a microelectronic assembly, in accordance with certain preferred embodiments of the present invention.

FIG. 42 shows a perspective view of a conductive post, in accordance with certain preferred embodiments of the present invention.

FIG. 43 shows a cross-sectional view of the conductive post shown in FIG. 42.

FIG. 44 shows a perspective view of conductive posts, in accordance with certain preferred embodiments of the present invention.

FIG. 45 shows a side view of a conductive post, in accordance with another preferred embodiment of the present invention.

FIG. 46 shows a method of connecting two microelectronic elements, in accordance with certain preferred embodiments of the present invention.

FIG. 47 shows a method of connecting two microelectronic elements, in accordance with another preferred embodiment of the present invention.

FIG. 48 shows a perspective view of a microelectronic assembly, in accordance with certain preferred embodiments of the present invention.

FIG. 49 shows a cross-sectional view of a microelectronic assembly, in accordance with certain preferred embodiments of the present invention.

FIG. 50 shows a cross-sectional view of a microelectronic assembly, in accordance with another preferred embodiment of the present invention.

FIG. 51 shows a cross-sectional view of a microelectronic assembly, in accordance with yet another preferred embodiment of the present invention.

FIG. 52 shows a cross-sectional view of a microelectronic assembly, in accordance with still another preferred embodiment of the present invention.

FIG. 53 shows a cross-sectional view of a microelectronic assembly, in accordance with certain preferred embodiments of the present invention.

FIGS. 54A-54B show a method of testing a microelectronic assembly, in accordance with certain preferred embodiments of the present invention.

FIG. 55 shows a cross-sectional view of a microelectronic assembly, in accordance with yet another preferred embodiment of the present invention.

FIG. 56 shows a graph depicting stress concentration factors for a conductive element.

FIGS. 57A and 57B show cross-sectional views of a microelectronic assembly, in accordance with certain preferred embodiments of the present invention.

FIG. 58 shows a perspective view of the microelectronic assembly shown in FIGS. 57A and 57B.

FIGS. 59A-59C show a method of making a microelectronic assembly, in accordance with certain preferred embodiments of the present invention.

FIGS. 60A-60B show a method of connecting two microelectronic elements, in accordance with certain preferred embodiments of the present invention.

FIGS. 61A-61B show a method of testing a microelectronic assembly, in accordance with certain preferred embodiments of the present invention.

FIGS. 62A-62C show a method of testing a microelectronic assembly.

FIG. 63 shows a cross-sectional view of a microelectronic assembly, in accordance with certain preferred embodiments of the present invention.

FIG. 64 shows a cross-sectional view of a microelectronic assembly, in accordance with another preferred embodiment of the present invention.

FIG. 65 shows a cross-sectional view of a microelectronic assembly, in accordance with yet another preferred embodiment of the present invention.

FIG. 66 shows a cross-sectional view of a microelectronic assembly, in accordance with still another preferred embodiment of the present invention.

FIG. 67 shows a cross-sectional view of a microelectronic assembly, in accordance with further preferred embodiments of the present invention.

FIG. 68A shows a top plan view of a conductive trace and a conductive pad, in accordance with certain preferred embodiments of the present invention.

FIG. 68B shows a cross-sectional view of a microelectronic element having a conductive post being connected with the conductive pad of FIG. 68A.

FIG. 69A shows a cross-sectional view of a microelectronic assembly, in accordance with certain preferred embodiments of the present invention.

FIG. 69B shows a bottom view of the microelectronic assembly shown in FIG. 69A.

FIG. 70A shows a perspective view of a microelectronic assembly, in accordance with certain preferred embodiments of the present invention.

FIG. 70B shows a cross-sectional view of the microelectronic assembly shown in FIG. 70A.

FIG. 71A shows a perspective view of a microelectronic assembly, in accordance with other preferred embodiments of the present invention.

FIG. 71B shows a cross-sectional view of the microelectronic assembly shown in FIG. 71A.

FIG. 72 shows a cross-sectional view of a microelectronic assembly, in accordance with certain preferred embodiments of the present invention.

FIG. 73 shows a cross-sectional view of a microelectronic assembly, in accordance with further preferred embodiments of the present invention.

FIG. 74 shows a cross-sectional view of a microelectronic assembly, in accordance with still further preferred embodiments of the present invention.

FIG. 75 shows a cross-sectional view of a microelectronic assembly, in accordance with another preferred embodiment of the present invention.

FIG. 76 shows a cross-sectional view of a microelectronic assembly, in accordance with yet another preferred embodiment of the present invention.

FIG. 77 shows a cross-sectional view of a microelectronic assembly, in accordance with certain preferred embodiments of the present invention.

FIG. 78 shows a cross-sectional view of a microelectronic assembly, in accordance with further preferred embodiments of the present invention.

FIG. 79 shows a cross-sectional view of a microelectronic assembly, in accordance with still further preferred embodiments of the present invention.

FIG. 80 shows a cross-sectional view of a microelectronic assembly, in accordance with yet another preferred embodiment of the present invention.

FIGS. 81-82 show a method of making a microelectronic assembly, in accordance with certain preferred embodiments of the present invention.

FIG. 83 shows a cross-sectional view of a microelectronic assembly, in accordance with certain preferred embodiments of the present invention.

FIG. 84 shows a cross-sectional view of a microelectronic assembly, in accordance with another preferred embodiment of the present invention.

FIG. 85 shows a cross-sectional view of a microelectronic assembly, in accordance with yet another preferred embodiment of the present invention.

### DETAILED DESCRIPTION OF PREFERRED EMBODIMENTS

In accordance with one preferred embodiment of the present invention, a microelectronic package 100 includes a microelectronic element, such as a semiconductor chip 102, having a front or contact bearing face 104 and electrical contacts 106 exposed at face 104. A passivation layer 108 may be formed over the contact bearing face 104 with openings at contacts 106.

The microelectronic package 100 also includes conductive support elements 110 such as solder balls in substantial alignment and electrically interconnected with contacts 106. As best seen in FIG. 2, contacts 106 and support elements 110 are disposed in an array which in this case is a rectilinear grid, having equally spaced columns extending in a first horizontal direction x and equally spaced rows extending in a second horizontal direction y orthogonal to the first horizontal direction. Each contact 106 and support element 110 is disposed at an intersection of a row and a column, so that each set of four support elements 110 at adjacent intersections, such as support elements 110a, 110b, 110c and 110d, defines a generally rectangular, and preferably square, zone 112. The directions referred to in this disclosure are directions in the frame of reference of the components themselves, rather than in the normal gravitational frame of reference. Horizontal directions are directions parallel to the plane of the front surface 104 of the chip, whereas vertical directions are perpendicular to that plane.

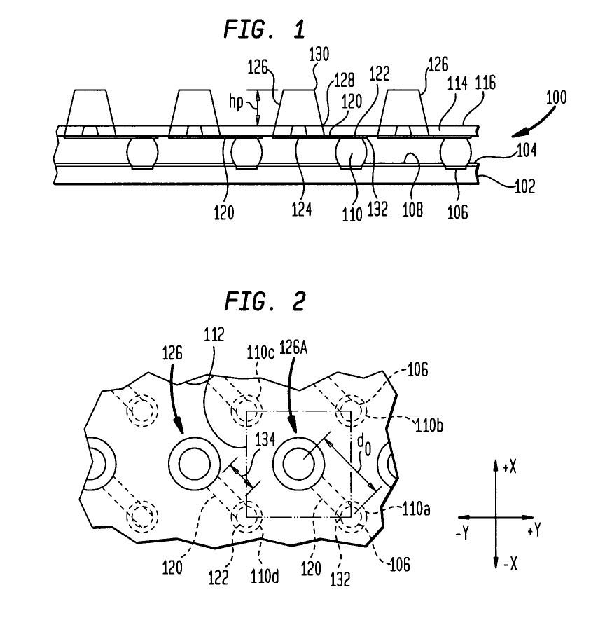

The package also includes a flexible dielectric substrate 114, such as a polyimide or other polymeric sheet, including a top surface 116 and a bottom surface 118 remote therefrom. Although the thickness of the dielectric substrate will vary with the application, the dielectric substrate most typically is about 10 μm-100 μm thick. The flexible sheet 114 has conductive traces 120 thereon. In the particular embodiment illustrated in FIG. 1, the conductive traces are disposed on the bottom surface 118 of the flexible sheet 114. In other preferred embodiments, however, the conductive traces 120 may extend on the top surface 116 of the flexible sheet 114, on both the top and bottom faces or within the interior of the flexible substrate 114. Thus, as used in this disclosure, a statement that a first feature is disposed “on” a second feature should not be understood as requiring that the first feature lie on a surface of the second feature. Conductive traces 96 may be formed from any electrically conductive material, but most typically are formed from copper, copper alloys, gold or combinations of these materials. The thickness of the traces will also vary with the application, but typically is about 5 μm-25 μm. Traces 120 are arranged so that each trace has a support end 122 and a post end 124 remote from the support end.

Electrically conductive posts or pillars 126 project from the top surface 116 of flexible substrate 114. Each post 126 is connected to the post end 124 of one of the traces 120. In the particular embodiment of FIGS. 1 and 2, the posts 126 extend upwardly through the dielectric sheet 114, from the post ends of the traces. The dimensions of the posts can vary over a significant range, but most typically the height hₚ of each post above the top surface 116 of the flexible sheet is about 50-300 μm. Each post has a base 128 adjacent the flexible sheet 114 and a tip 130 remote from the flexible sheet. In the particular embodiment illustrated, the posts are generally frustoconical, so that the base 128 and tip 130 of each post are substantially circular. The bases of the posts typically are about 100-600 μm in diameter, whereas the tips typically are about 40-200 μm in diameter. The posts may be formed from any electrically conductive material, but desirably are formed from metallic materials such as copper, copper alloys, gold and combinations thereof. For example, the posts may be formed principally from copper with a layer of gold at the surfaces of the posts.

The dielectric sheet 114, traces 120 and posts 126 can be fabricated by a process such as that disclosed in co-pending, commonly assigned U.S. Provisional Patent Application Ser. No. 60/508,970, the disclosure of which is incorporated by reference herein. As disclosed in greater detail in the '970 application, a metallic plate is etched or otherwise treated to form numerous metallic posts projecting from the plate. A dielectric layer is applied to this plate so that the posts project through the dielectric layer. An inner or side of the dielectric layer faces toward the metallic plate, whereas the outer side of the dielectric layer faces towards the tips of the posts. The dielectric layer may be fabricated by coating a dielectric such as polyimide onto the plate around the posts or, more typically, by forcibly engaging the posts with the dielectric sheet so that the posts penetrate through the sheet. Once the sheet is in place, the metallic plate is etched to form individual traces on the inner side of the dielectric layer. Alternatively, conventional processes such as plating may form the traces or etching, whereas the posts may be formed using the methods disclosed in commonly assigned U.S. Pat. No. 6,177,636, the disclosure of which is hereby incorporated by reference herein. In yet another alternative, the posts may be fabricated as individual elements and assembled to the flexible sheet in any suitable manner, which connects the posts to the traces.

As best appreciated with reference to FIG. 2, the support ends 122 of the leads are disposed in a regular grid pattern corresponding to the grid pattern of the support elements, whereas the posts 126 are disposed in a similar grid pattern. However, the grid pattern of the posts is offset in the first and second horizontal directions x and y from the grid pattern of the support ends 122 and support elements 110, so that each post 126 is offset in the −y and +x directions from the support end 122 of the trace 120 connected to that post.

The support end 122 of each trace 120 overlies a support element 110 and is bonded to such support element, so that each post 126 is connected to one support element. In the embodiment illustrated, where the support elements are solder balls, the bonds can be made by providing the support elements on the contacts 106 of the chip and positioning the substrate or flexible sheet 114, with the posts and traces already formed thereon, over the support elements and reflowing the solder balls by heating the assembly. In a variant of this process, the solder balls can be provided on the support ends 122 of the traces. The process steps used to connect the support ends of the traces can be essentially the same used in flip-chip solder bonding of a chip to a circuit panel.

As mentioned above, the posts 126 are offset from the support elements 110 in the x and y horizontal directions. Unless otherwise specified herein, the offset distance do (FIG. 2) between a post and a support element can be taken as the distance between the center of area of the base 128 (FIG. 1) of the post and the center of area of the upper end 132 (FIG. 1) of the support element 110. In the embodiment shown, where both the base of the post and the upper end of the support element have circular cross-sections, the centers of area lie at the geometric centers of these elements. Most preferably, the offset distance do is large enough that there is a gap 134 (FIG. 2) between adjacent edges of the base of the post and the top end of the support element. Stated another way, there is a portion of the dielectric sheet 114 in gap 134, which is not in contact with either the top end 132 of the support element or the base 128 of the post.

Each post lies near the center of one zone 112 defined by four adjacent support elements 110, so that these support elements are disposed around the post. For example, support elements 110a-110d are disposed around post 126A. Each post is electrically connected by a trace and by one of these adjacent support elements to the microelectronic device 102. The offset distances from a particular post to all of the support elements adjacent to that post may be equal or unequal to one another.

In the completed unit, the upper surface 116 of the substrate or flexible sheet 114 forms an exposed surface of the package, whereas posts 126 project from this exposed surface and provide terminals for connection to external elements.

The conductive support elements 110 create electrically conductive paths between the microelectronic element 102 and the flexible substrate 114 and traces 120. The conductive support elements space the flexible substrate 114 from the contact bearing face 104 of microelectronic element 102. As further discussed below, this arrangement facilitates movement of the posts 126.

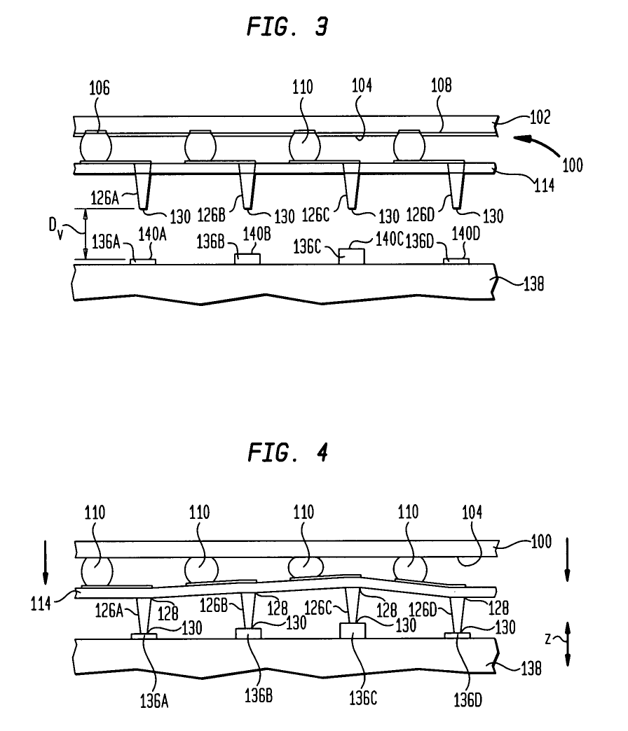

Referring to FIG. 3, in a method of operation according to a further embodiment of the invention, a microelectronic package 100 such as the package discussed above with reference to FIGS. 1 and 2 is tested by juxtaposing the conductive posts 126 with contact pads 136 on a second microelectronic element 138 such as a circuitized test board. The conductive posts 126A-126D are placed in substantial alignment with top surfaces of the respective contact pads 136A-136D. As is evident in the drawing figure, the top surfaces 140A-140D of the respective contact pads 136A-136D are disposed at different heights and do not lie in the same plane. Such non-planarity can arise from causes such as warpage of the circuit board 138 itself and unequal thicknesses of contact pads 136. Also, although not shown in FIG. 3, the tips 130 of the posts may not be precisely coplanar with one another, due to factors such as unequal heights of support elements 110; non-planarity of the front surface 104 of the microelectronic device; warpage of the dielectric substrate 114; and unequal heights of the posts themselves. Also, the package 100 may be tilted slightly with respect to the circuit board. For these and other reasons, the vertical distances Dv between the tips of the posts and the contact pads may be unequal.

Referring to FIG. 4, the microelectronic package 100 is moved toward the test board 138, by moving the test board, the package or both. The tips 130 of the conductive posts 126A-126D engage the contact pads 136 and make electrical contact with the contact pads. The tips of the posts are able to move so as to compensate for the initial differences in vertical spacing Dv (FIG. 3), so that all of the tips can be brought into contact with all of the contact pads simultaneously using only a moderate vertical force applied to urge the package and test board 138 together. In this process, at least some of the post tips are displaced in the vertical or z direction relative to other post tips.

A significant portion of this relative displacement arises from movement of the bases 128 of the posts relative to one another and relative to microelectronic element 100. Because the posts are attached to flexible substrate 114 and are offset from the support elements 110, and because the support elements space the flexible substrate 114 from the front surface 104 of the microelectronic element, the flexible substrate can deform. Further, different portions of the substrate associated with different posts can deform independently of one another.

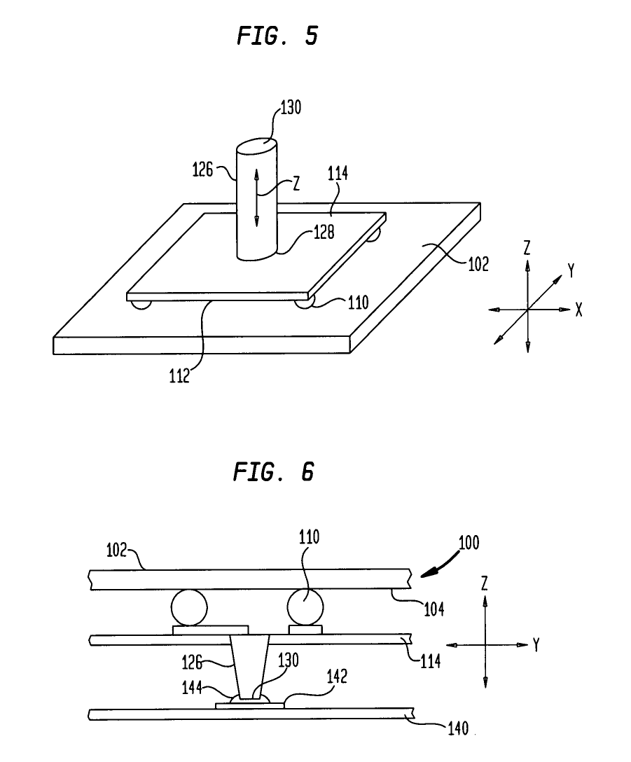

An idealized representation of the deformation of a single region 112 of substrate 114 is shown in FIG. 5. The support elements 110 disposed at the corners of the region allow the central part of the region to bend downwardly toward the microelectronic element 102, allowing the base 128 of post 126 to also move downward toward the microelectronic element. This deformation is idealized in FIG. 5 as a pure displacement of the post and the center of the region in the vertical or z direction. In practice, the deformation of the substrate may include bending and/or stretching of the substrate so that the motion of the base may include a tilting about an axis in the x-y or horizontal plane as well as some horizontal displacement of the base, and may also include other components of motion. For example, one portion of the region may be reinforced by a trace, and will tend to be stiffer than the other portions of the region. Also, a particular post may be positioned off-center in its region 112, so that the post lies closer to one support element, or to a pair of support elements, on one side of the post. For example, post 126a (FIG. 2) may be disposed closer to support elements 110a and 110b than to support elements 110c and 110d. The relatively small portion of the substrate between the post and support elements 110a and 110b will be stiffer in bending than the relatively large portion of the substrate between the posts and support elements 110c and 110d. Such non-uniformities tend to promote non-uniform bending and hence tilting motion of the posts. Tilting of the posts tends to move the tips 130 toward the microelectronic element. The support elements 110 at the corners of the individual regions substantially isolate the various regions from one another, so that the deformation of each region is substantially independent of the deformation of other regions of the substrate 114. Depending on the configuration of the posts, the posts 126 themselves may also flex or buckle to some degree, which provides additional movement of tips 76 in the vertical or z direction.

The independent displacement of the posts relative to one another allows all of the post tips 130 to contact all of the contact pads 136 on the test substrate. For example, the flexible substrate 114 in the vicinity of conductive post 126C flexes substantially more than the flexible substrate in the vicinity of conductive post 126B. In turn, the flexible substrate 114 in the vicinity of conductive post 126B flexes substantially more than the flexible substrate in the vicinity of conductive post 126A.

Because all of the post tips 130 can be engaged reliably with all of the contact pads 136, the package can be tested reliably by applying test signals, power and ground potentials through the test circuit board 138 and through the engaged posts and contact pads. Moreover, this reliable engagement is achieved with a simple test circuit board 138. For example, the contact pads 136 of the test circuit board are simple, planar pads. The test circuit board need not incorporate special features to compensate for non-planarity or complex socket configurations. The test circuit board can be made using the techniques commonly employed to form ordinary circuit boards. This materially reduces the cost of the test circuit board, and also facilitates construction of the test circuit board with traces (not shown) in a simple layout compatible with high-frequency signals. Also, the test circuit board may incorporate electronic elements such as capacitors in close proximity to the contact pads as required for certain high-frequency signal processing circuits. Here again, because the test circuit board need not incorporate special features to accommodate non-planarity, placement of such electronic elements is simplified. In some cases, it is desirable to make the test circuit board as planar as practicable so as to reduce the non-planarity of the system and thus minimize the need for pin movement. For example, where the test circuit board is highly planar a ceramic circuit board such as a polished alumina ceramic structure, only about 20 μm of pin movement will suffice.

The internal features of package 100 are also compatible with high-frequency signals. The conductive support elements, traces and posts provide low-impedance signal paths between the tips of the posts and the contacts 106 of the microelectronic element. Because each post 126 is connected to an immediately adjacent conductive support element 110, traces 120 are quite short. The low-impedance signal paths are particularly useful in high-frequency operation, as, for example, where the microelectronic element must send or receive signals at a frequency of 300 MHz or more.

After testing the microelectronic package 100 may be removed from the test circuit board 138 and permanently interconnected with another substrate such as a circuit panel 140 (FIG. 6) having contact pads 142, as by bonding the tips 130 of posts 126 to the contact pads of the circuit panel using a conductive bonding material 144 such as a solder. The solder-bonding process may be performed using conventional equipment commonly used for surface-mounting microelectronic components. Thus, the solder masses may be provided on the posts 126 or on the contact pads 142, and may be reflowed after engaging the posts with the contact pads. During reflow, the surface tension of the solder tends to center the posts on the contact pads. Such self-centering action is particularly pronounced where the tips of the posts are smaller than the contact pads. Moreover, the solder 144 wets the sides of the posts to at least some extent, and thus forms a fillet encircling the tip of each post, as well as a strong bond between the confronting surfaces of the posts and pads.

Moreover, the tips 130 of the posts 126 can move relative to the microelectronic element 102 to at least some degree during service so as to relieve stresses arising from differential thermal expansion and contraction. As discussed above in connection with the testing step, the individual posts 126 can move relative to the microelectronic element and relative to the other posts by flexure or other deformation of substrate 114. Such movement can appreciably relieve stresses in the solder bonds between the posts and the contact pads, which would otherwise occur upon differential thermal expansion or contraction of the circuit board 140 and microelectronic element 102. Moreover, the conductive support elements or solder balls 110 can deform to further relieve stresses in solder masses 144. The assembly is highly resistant to thermal cycling stresses, and hence highly reliable in service.

An underfill material (not shown) such as an epoxy or other polymeric material may be provided around the tips of the posts and around the contact pads, so as to reinforce the solder bonds. Desirably, this underfill material only partially fills the gap between the package 100 and the circuit board 140. In this arrangement, the underfill does not bond the flexible substrate 114 or the microelectronic device to the circuit board. The underfill only reinforces the posts at their joints with the contact pads. However, no reinforcement is required at the bases of the posts, inasmuch as the joint between the base of each post and the associated trace is extraordinarily resistant to fatigue failure.

The assembly is also compact. Some or all of the posts 126 and contact pads 142 are disposed in the area occupied by the microelectronic element 102, so that the area of circuit board 140 occupied by the assembly may be equal to, or only slightly larger than, the area of the microelectronic element itself, i.e., the area of the front surface 104 of the microelectronic element 100.

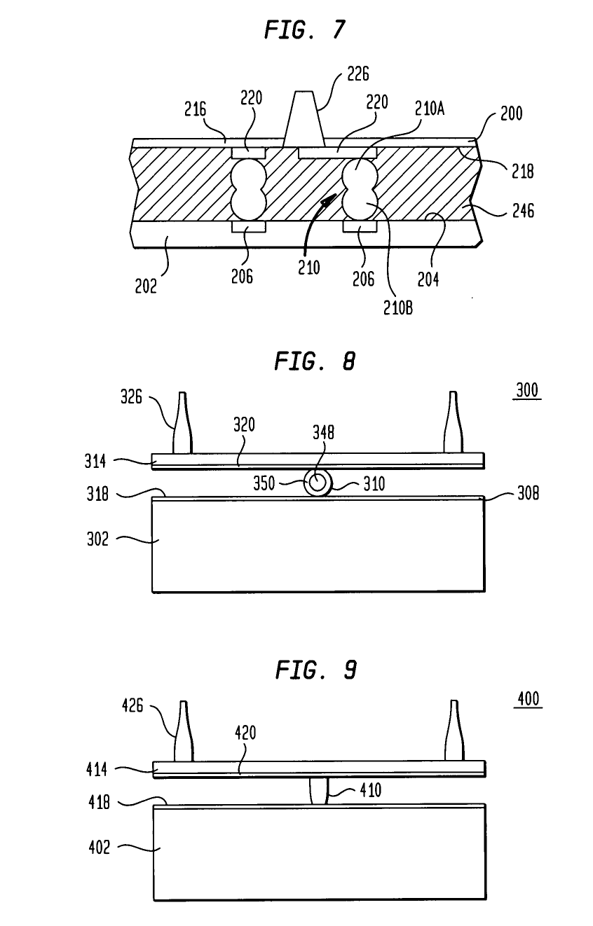

FIG. 7 shows a portion of a microelectronic package 200 in accordance with another embodiment of the present invention. This package includes a microelectronic element 202, such as a semiconductor chip, having contacts 206 on a face surface thereof. The package also includes a flexible substrate 214 such as a flexible dielectric film having a top surface 216, a bottom surface 218, conductive traces 220 and conductive posts 226 projecting from the top surface 216. The conductive posts 226 are electrically interconnected with traces 220 at the bases of the posts. One or more of the conductive traces 220 are electrically interconnected with contacts 206 by conductive elements 210. These features may be similar to the corresponding features of the embodiment discussed above with reference to FIGS. 1-6. In the embodiment shown in FIG. 7, each conductive support element 210 includes two conductive elements stacked one atop another so that a first conductive element 210A is positioned over a second conductive element 210B. Conductive elements 210A and 210B are fused with one another to from an elongated conductive element 210. In other preferred embodiments, three or more conductive elements may be stacked one atop another between conductive trace 220 and contact 206. The stacking of the conductive elements enables the height of the flexible substrate 214 to be adjusted relative to the surface of the semiconductor chip 202. This provides additional clearance between the flexible substrate 214 and the chip surface 204, which can accommodate additional displacement of the post bases. Moreover, the elongated conductive elements 210 are more readily deformable, which can provide additional movability to the posts.

In the embodiment of FIG. 7, a compliant material 246 is positioned between the flexible substrate 214 and the microelectronic element 202. The compliant layer 246 preferably does not substantially restrict movement of the posts. The compliant material prevents contaminants from entering the package. Merely by way of example, compliant material 246 may be a gel, foam or the like. Despite the presence of the compliant material, conductive elements 210 still support the flexible substrate 214 to a substantial degree.

Referring to FIG. 8, a package 300 according to a further preferred embodiment of the present invention is similar to the packages discussed above, except that each conductive support elements 310 includes a core 348 covered by an outer conductive coating 350. Core 348 may be a conductive, high-melting material such as copper, whereas coating 350 may be a lower-melting material such as a solder. Alternatively, core 348 may be formed from a nonconductive material such as glass, ceramic or a polymer.

Referring to FIG. 8, in a package 400 according to yet another preferred embodiment of the present invention, the conductive support elements include elongated conductive pillars 410. These pillars may be formed integrally with traces 420 and posts 426. The tips of pillars 410 abut the contacts (not shown) of microelectronic element 402, and may be bonded to the contacts by a solder, eutectic bonding material, diffusion bond or other metallurgical bond.

FIG. 10 shows a microelectronic package 500 in accordance with yet another preferred embodiment of the present invention. The microelectronic package 500 includes a microelectronic element 502 such as a semiconductor chip having a front or contact-bearing surface with contacts 506. The microelectronic element 502 has a relatively fine pitch so that the contacts 506 and support elements 510 are relatively close to one another. In this arrangement, the offset distance Dₒ between the base 528 of each post 526 and the adjacent support elements 510 is relatively small; a portion of the base may overlap with the adjacent support elements. Here again, flexible substrate 514 includes top surface 516 and bottom surface 518 remote therefrom, and conductive traces 520 are provided on the flexible substrate. In this embodiment, the package also includes a focusing conductive element 552 positioned between the base 528 of each conductive post 526 and the top surface 516 of flexible substrate 514. The focusing or second conductive element 552 has a smaller area than does the base 528 of conductive post 526. The focusing conductive elements mechanically interconnect the bases of the posts with the flexible substrate and traces 520, and also electrically interconnect the posts and the traces. The relatively small area of the focusing elements helps to maintain the flexibility of the flexible substrate 514 and traces. Stated another way, the focusing conductive elements 552 facilitate movement of the conductive posts 526 in a fine pitch environment. The focusing conductive elements can be formed integrally with the posts and traces as, for example, by etching the bases of the posts after protecting the remainder of the posts using a suitable mask or plating. Focusing conductive elements can be employed to enhance the movability of conductive posts in structures where a flexible substrate is supported by elements other than support elements. For example, focusing conductive elements can be provided in structures of the type shown in embodiments of the aforementioned U.S. Pat. No. 6,177,636 where a flexible substrate is supported only by a compliant layer or by compliant pads disposed beneath the posts.

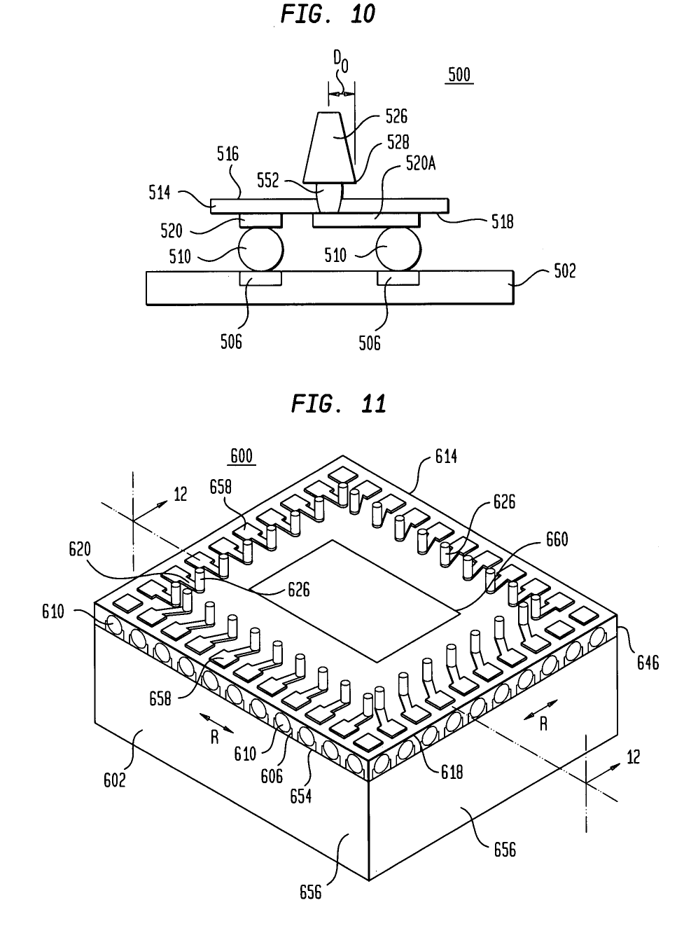

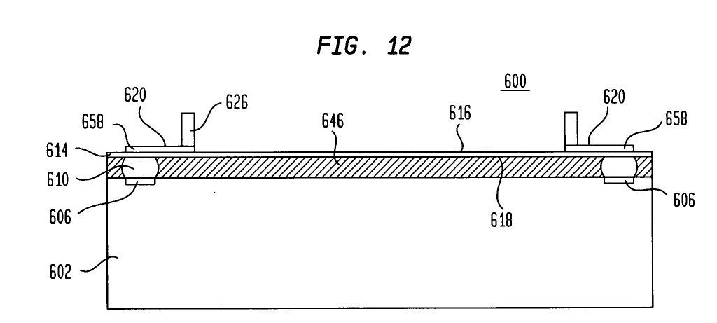

As shown in FIGS. 11 and 12, a microelectronic package 600 according to a further embodiment includes a microelectronic element 602, such as a semiconductor chip, having contacts 606 exposed at a front surface thereof. In this embodiment, however, the contacts 606 are not disposed in a uniform array but instead are disposed in rows 654 located adjacent the edges 656 of the chip. Each row thus extends in a row direction R in the horizontal plane of the chip front surface, such row direction being parallel to the edges of the chip. Here again, the package includes a flexible dielectric substrate 614, having a top surface 616 and a bottom surface 618. The flexible substrate 614 includes contact pads 658 disposed on top surface 616 and accessible at bottom surface 618 through holes in the substrate. Conductive traces 620 extend from the contact pads 658 to posts 626. Here again, the flexible substrate 614 is assembled with the microelectronic element 602 using conductive elements 610, such as solder balls. Here again, the conductive elements 610 space and at least partially support the flexible substrate 614 over the contact bearing face of the microelectronic element 602. In addition, the conductive elements 610 form an electrical interconnection between contacts 606 of microelectronic element 602 and conductive pads 658 of flexible substrate 614, and thus connect posts 626 to contacts 606. The microelectronic package 600 optionally includes a compliant layer 646, such as a curable elastomer, gel or the like disposed between the bottom surface 618 of flexible substrate 614 and the front face of microelectronic element 602. In a further variant, the compliant layer may also comprise a porous compliant layer formed from a multiplicity of pads defining channels between the pads. A curable elastomer optionally may be injected in the channels between the compliant pads, as disclosed in commonly assigned U.S. Pat. No. 5,659,952, the disclosure of which is hereby incorporated by reference herein.

Here again, posts 626 are offset from the support elements 610 and contacts 606. In this case, the offset directions of the posts are transverse to the row directions R. That is, each post is offset from the associated contact pad 658, support element 610 and chip contact 606 in a direction transverse to the row direction of the row containing the associated contact pad 658. The offset directions point inwardly, toward the geometric center of the chip front surface, so that the posts are disposed inside the area bounded by the rows. Stated another way, traces 620 fan in from the contact pads 658 to the posts 626.

Referring to FIG. 11, the flexible substrate 614 has an opening 660 so as to enhance the flexibility of the flexible substrate. In this embodiment as well, the conductive posts have can move relative to the contact bearing face of the microelectronic element 602.

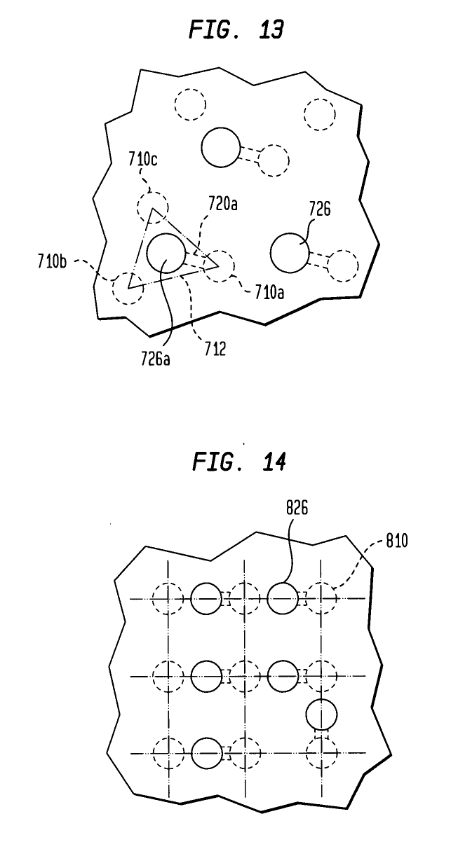

Numerous further variations and combinations of the features discussed above can be used. For example, where the contacts on a chip are disposed in an array, such array need not be a rectilinear, regular array as shown in FIG. 2. For example, as shown in FIG. 13, the contacts and support elements 710 may be disposed in an irregular pattern or in a hexagonal or triangular array. In the particular pattern of FIG. 13, post 726a lies in a region 712 bounded by three support elements 710a, 710b and 710c, and is electrically connected to one of these support elements by a trace 720a.

In a further arrangement (FIG. 14), the support elements 810 are arranged in rectilinear rows and columns, but the posts 826 are disposed in the rows or columns such that each post lies between two adjacent support elements 810. Moreover, it is not essential to have a one-to-one association between posts, traces and support elements. For example, a given post may be connected by two or more traces to two or more posts. Conversely, a given support element may be electrically connected to two or more posts. In yet another variant, one or more of the posts may be electrically connected to support elements remote from such posts. Also, the flexible substrate may include elements such as conductive planes that serve as ground planes or power distribution planes.

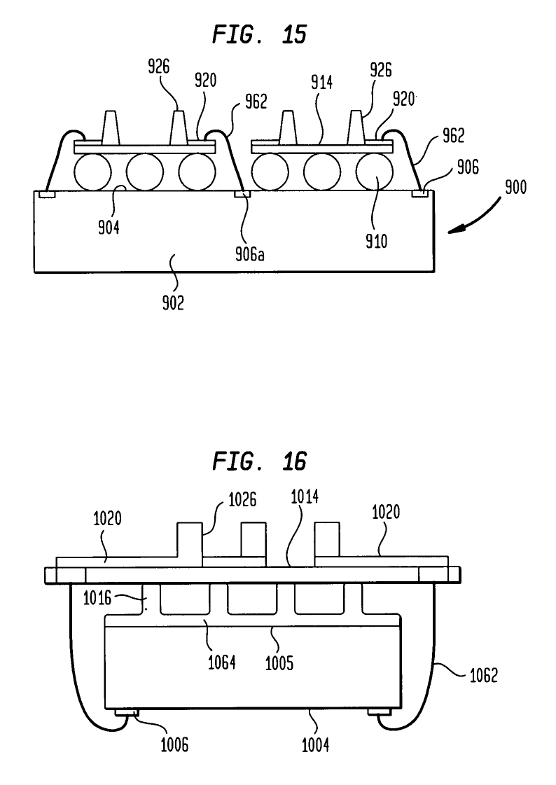

The support elements need not be electrically conductive. For example, as shown in FIG. 15, a package 900 includes a flexible support substrate 914 supported over the front surface 904 of a chip 902 by support elements 910 which are formed from a dielectric material as, for example, small spheres of glass or polymer. The traces 920 on the flexible substrate, and hence the posts 926, are electrically connected to the contacts 906 of the chip by wire bonds 962. Here again, the posts 926 are offset from the support elements 910 so that the bases of the posts can move upon flexure of the support element 914. In the embodiment of FIG. 15, some of the contacts 906a on the chip are disposed in one or more rows adjacent the center of the chip, whereas others are disposed in rows adjacent the edges of the chip. In a further variant (not shown), the contacts of the chip are connected to the traces 920 by leads formed integrally with the traces. Leads 962 extend to center contacts 906a through a slot or hole in substrate 914. Alternatively, two separate substrates can be positioned on opposite sides of the center contact row.

In yet another variant (FIG. 16) the flexible substrate 1020 is supported over a rear surface 1005, opposite from the contact-bearing or front surface 1004. Stated another way, the chip is “face-up” relative to substrate 1014. The traces 1020 of and hence the posts 1026 are electrically connected to the contacts 1006 by leads 1062 such as wire bonds or leads integral with the traces. Here again, the posts 1026 are offset from the support elements 1010 so that in this embodiment as well, movement of the posts is facilitated by flexing of the substrate between support elements. In the embodiment of FIG. 16, support elements 1010 are nonconductive and are formed as portions of a continuous layer 1064. Merely by way of example, such a continuous layer with projecting support elements may be formed by molding or embossing a polymeric layer.

The foregoing discussion has referred to an individual microelectronic element. However, the package may include more than one microelectronic element or more than one substrate. Moreover, the process steps used to assemble the flexible substrate, support elements and posts to the chips may be performed while the chips are in the form of a wafer. A single large substrate may be assembled to an entire wafer, or to some portion of the wafer. The assembly may be severed so as to form individual units, each including one or more of the chips and the associated portion of the substrate. The testing operations discussed above may be performed prior to the severing step. The ability of the packages to compensate for non-planarity in a test board or in the wafer itself greatly facilitates testing of a large unit.

The substrate and traces may deform locally in regions surrounding the posts. These regions tend to deform upwardly, leaving concavities in the bottom surface of the substrate. The posts may have heads, and these heads may be lodged partially or completely within the concavities. To control deformation of the substrate, the top surface of the substrate may be abutted against a die having holes aligned with locations where posts are forced through the substrate. Such a die can also help to prevent delamination of the substrate and traces. In variants of the process, the traces may be disposed on the top or bottom surface of a single-layer substrate. The resulting post-array substrate can be assembled with a microelectronic element to form a package as discussed above, or can be used in any other microelectronic assembly where a small post array is desirable. The assembly process allows selective placement of posts. It is not essential to provide the lands and holes in the traces. Thus, posts can be placed at any location along any trace. Moreover, the posts may be formed from essentially any conductive material. Different posts may be formed from different materials. For example, posts subject to severe mechanical loading can be formed entirely or partially from hard refractory metals such as tungsten, while other posts may be formed from softer metals such as copper. Also, some or all of the posts may be formed entirely or partially from corrosion-resistant metals such as nickel, gold or platinum.

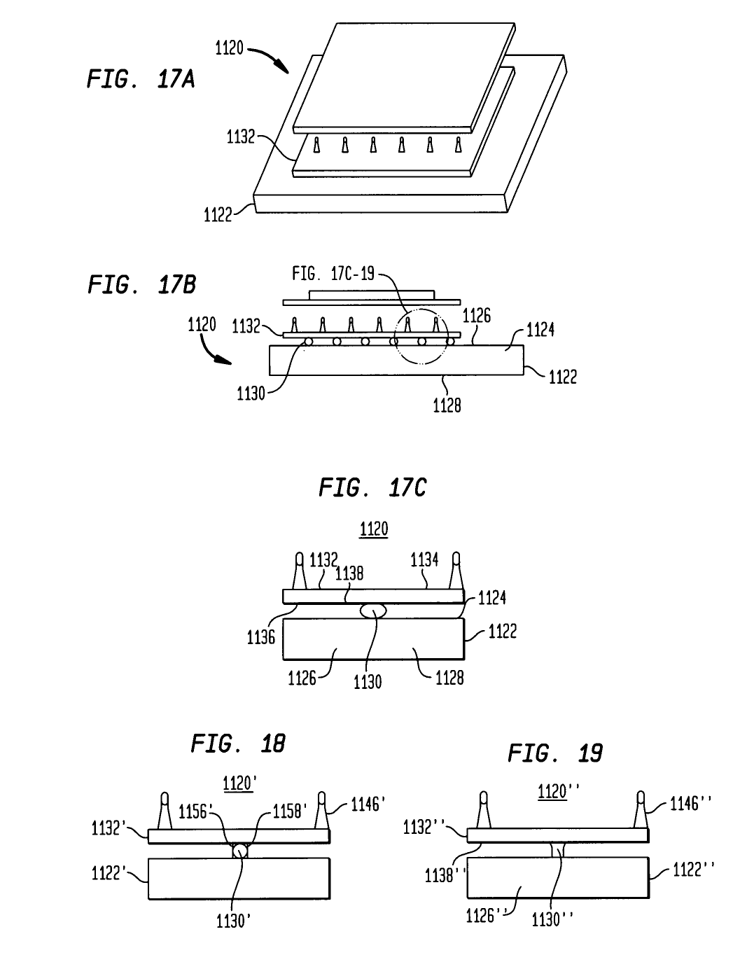

Referring to FIGS. 17A-17C, in accordance with certain preferred embodiments of the present invention, a testing assembly 1120 for microelectronic elements includes a test board 1122, such as a printed circuit board or circuitized substrate, having has a first surface 1124 with conductive pads 1126 and a second surface 1128 remote from the first surface 1124. A passivation layer (not shown) may be formed over the contact bearing face 1124 with openings at the conductive pads 1126.

Referring to FIGS. 17B-17C, the testing assembly 1120 includes conductive support elements 1130 such as solder balls in substantial alignment and electrically interconnected with conductive pads 1126. The testing assembly 1120 also has a flexible dielectric substrate 1132, such as a polyimide or other polymeric sheet, including a top surface 1134 and a bottom surface 1136 remote therefrom. Although the thickness of the dielectric substrate 1132 will vary with the application, the dielectric substrate most typically is about 10 μm-100 μm thick. The flexible, dielectric substrate 1132 has conductive traces 1138 thereon. In the particular embodiment illustrated in FIGS. 17B-17C, the conductive traces 1138 are disposed on the bottom surface 1136 of the flexible, dielectric substrate 1132. However, in other embodiments, the conductive traces 1138 may extend on the top surface 1134 of the flexible, dielectric substrate 1132, on both the top and bottom surfaces or within the interior of flexible, dielectric substrate 1132. Thus, as used in this disclosure, a statement that a first feature is disposed “on” a second feature should not be understood as requiring that the first feature lie on a surface of the second feature. The conductive traces 1138 may be formed from any electrically conductive material, but most typically are formed from copper, copper alloys, gold or combinations of these materials. The thickness of the traces will also vary with the application, but typically is about 5 μm-25 μm. Traces 1138 are arranged so that each trace has a support end and a post end remote from the support end.

The test assembly 1120 preferably includes electrically conductive posts or pillars 1146 that project from the top surface 1134 of flexible substrate 1132. Each post 1146 is connected to the post end 1142 of one of the traces 1138. The posts 1146 may extend upwardly through the dielectric sheet 1132, from the post ends of the traces 1138. The dimensions of the posts can vary over a significant range, but most typically the height hₚ of each post above the top surface 1134 of the flexible sheet is about 50-300 μm. Each post may have a base adjacent the flexible sheet and a tip remote from the flexible sheet. The bases of the posts are preferably about 100-600 μm in diameter, whereas the tips are preferably about 40-200 μm in diameter. The posts may be formed from any electrically conductive material, but desirably are formed from metallic materials such as copper, copper alloys, gold and combinations thereof. For example, the posts may be formed principally from copper with a layer of gold at the surfaces of the posts.

The dielectric sheet 1132, traces 1138 and posts 1146 may be fabricated by a process such as that disclosed in co-pending, commonly assigned U.S. Provisional Patent Application Ser. No. 60/508,970, the disclosure of which is hereby incorporated by reference herein. As disclosed in greater detail in the '970 application, a metallic plate is etched or otherwise treated to form numerous metallic posts projecting from the plate. A dielectric layer is applied to this plate so that the posts project through the dielectric layer. An inner face of the dielectric layer faces toward the metallic plate, whereas the outer face of the dielectric layer faces towards the tips of the posts. The dielectric layer may be fabricated by coating a dielectric such as polyimide onto the plate around the posts or, more typically, by forcibly engaging the posts with the dielectric sheet so that the posts penetrate through the sheet. Once the sheet is in place, the metallic plate is etched to form individual traces on the inner side of the dielectric layer. Alternatively, conventional processes such as plating may form the traces or etching, whereas the posts may be formed using the methods disclosed in commonly assigned U.S. Pat. No. 6,177,636, the disclosure of which is hereby incorporated by reference herein. In yet another alternative, the posts may be fabricated as individual elements and assembled to the flexible sheet in any suitable manner, which connects the posts to the traces.

In the completed unit, the upper surface 1134 of the substrate or flexible sheet 1132 forms an exposed surface of the package, whereas posts 1146 project from this exposed surface and provide terminals for connection to external elements.

The conductive support elements 1130 create electrically conductive paths between the test board 1122 and the flexible substrate 1132 and traces 1138. The conductive support elements space the flexible substrate 1132 from the first face 1124 of the test board 1122. As further discussed below, this arrangement facilitates movement of the posts 1146.

Referring to FIG. 18, a testing assembly 1120′ in accordance with another preferred embodiment of the present invention includes test board 1122′, dielectric substrate 1132′ and conductive posts 1146′ projecting from the dielectric substrate. The assembly also includes conductive support elements 1130′ having a core 1156′ covered by an outer conductive coating 1158′. Core 1156′ may be a conductive, high-melting material such as copper, whereas coating 1158′ may be a lower-melting material such as a solder. Alternatively, core 1156′ may be formed from a nonconductive material such as glass, ceramic or a polymer.

Referring to FIG. 19, a testing assembly 1120″ in accordance with yet another preferred embodiment of the present invention includes test board 1122″, dielectric substrate 1132″ and conductive posts 1146″ projecting from the dielectric substrate. The assembly also has conductive support elements 1130″ including elongated conductive pillars 1130″. These pillars may be formed integrally with traces 1138″ and conductive posts 1146″. The tips of the conductive pillars 1130″ abut the conductive pads 1126″ of the test board 1122″, and may be bonded to the contacts by a solder, eutectic bonding material, diffusion bond or other metallurgical bond.

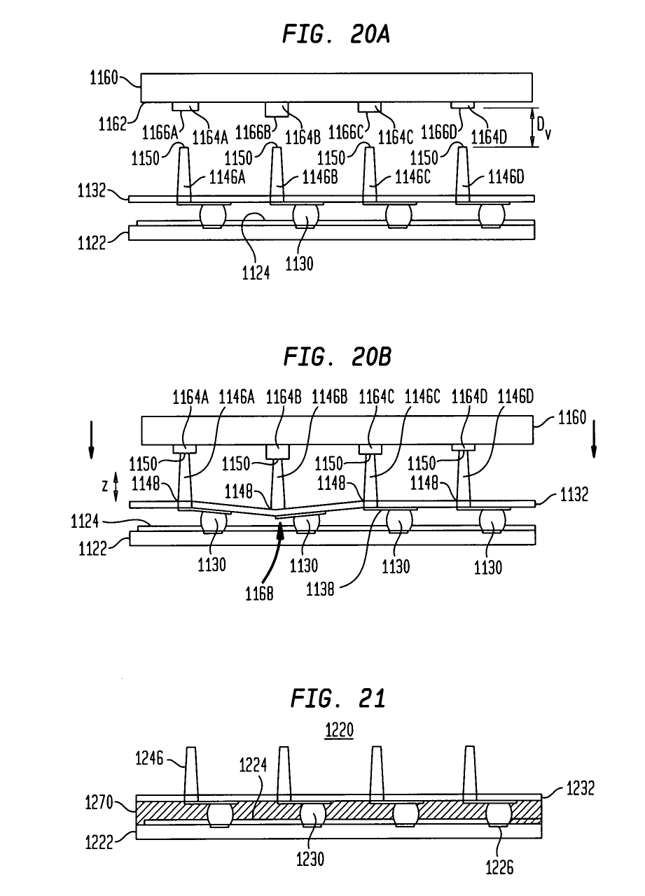

FIGS. 20A and 20B show a method of testing a microelectronic element 1160 using the testing assembly 1120 shown and described above in FIGS. 17A-17C. The microelectronic element 1160, such as a semiconductor chip, has a front face 1162 including contacts 1164 accessible at the front face and a rear face 1166 remote therefrom. In order to test the microelectronic element 1160, the contacts 1164 of the microelectronic element are juxtaposed with the conductive posts 1146 of the test board 1122. The contacts 1164A-1164D are placed in substantial alignment with top surfaces 1150 of the respective conductive posts 1146A-1146D. As is evident in the drawing figure, the top surfaces 1166A-1166D of the respective contact pads 1164A-1164D are disposed at different heights and do not lie in the same plane. Such non-planarity can arise from causes such as warpage of the microelectronic element 1160 itself and unequal thicknesses of contact pads 1164. Also, although not shown in FIG. 20A, the tips 1150 of the posts 1146 may not be precisely coplanar with one another, due to factors such as unequal heights of support elements 1130; non-planarity of the first surface 1124 of the test board 1122; warpage of the dielectric substrate 1132; and unequal heights of the posts themselves. Also, the microelectronic element 1160 may be tilted slightly with respect to the test board. For these and other reasons, the vertical distances Dv between the contacts 1164 and the tips of the posts 1146 may be unequal.

Referring to FIG. 20B, the microelectronic element 1160 is moved toward the test board 1122, by moving the test board, the microelectronic element or both toward one another. The contacts 1164 engage the conductive posts 1146A-1146D for making electrical contact with the conductive posts. The tips 1150 of the posts 1146A-1146D are able to move so as to compensate for the initial differences in vertical spacing Dv (FIG. 20A), so that all of the tips can be brought into contact with all of the contact pads simultaneously using with only a moderate vertical force applied to urge the microelectronic element 1160 and the test board 1122 together. In this process, at least some of the post tips 1146A-1146D are displaced in the vertical or z direction relative to others of the post tips.

A significant portion of this relative displacement arises from movement of the bases 1148 of the posts relative to one another and relative to test board 1120. Because the posts are attached to flexible substrate 1132 and are offset from the support elements 1130, and because the support elements space the flexible substrate 1132 from the first surface 1124 of the test board, the flexible substrate 1132 can deform. Further, different portions of the substrate associated with different posts can deform independently of one another. As pressure is applied by contacts 1164 onto the posts 1146, the support elements 1130 allow region 1168 of flexible substrate 1132 to bend downwardly toward the test board 1122, allowing the base 1148 of post 1146B to also move downward toward the test board. This deformation is idealized in FIG. 20B as a pure displacement of the post and the center of the region in the vertical or z direction. In practice, the deformation of the substrate 1132 may include bending and/or stretching of the substrate so that the motion of the base may include a tilting about an axis in the x-y or horizontal plane as well as some horizontal displacement of the base, and may also include other components of motion. For example, one portion of the region may be reinforced by a conductive trace (not shown), which will tend to be stiffer than the other portions of the region. Also, a particular post may be positioned off-center in its region 1168, so that the post lies closer to one support element 1130, or to a pair of support elements, on one side of the post. For example, post 1146a may be disposed closer to support elements 1130a and 1130b than to support elements 1130c and 1130d. The relatively small portion of the substrate between the post and support elements 1130a and 1130b will be stiffer in bending than the relatively large portion of the substrate between the posts and support elements 1130c and 1130d. Such non-uniformities tend to promote non-uniform bending and hence tilting motion of the posts. Tilting of the posts tends to move the tips 1150 toward the test board 1122. The support elements 1130 at the corners of the individual regions substantially isolate the various regions from one another, so that the deformation of each region is substantially independent of the deformation of other regions of the flexible, dielectric substrate 1132. Depending on the configuration of the posts, the posts 1146 themselves may also flex or buckle to some degree, which provides additional movement of tips 1150 in the vertical or z direction.

Referring to FIG. 20B, the independent displacement of the posts 1146 relative to one another allows all of the contacts 1164 of the microelectronic element 1160 to contact all of the post tips 1150 on the test board 1122. For example, the flexible substrate 1132 in the vicinity of conductive post 1146B flexes substantially more than the flexible substrate in the vicinity of conductive post 1146C. In turn, the flexible substrate 1132 in the vicinity of conductive post 1146C flexes substantially more than the flexible substrate in the vicinity of conductive post 1146D.

Because all of the contacts 1164 can be engaged reliably with all of the post tips 1150, the microelectronic element 1160 can be tested reliably by applying test signals, power and ground potentials through the test board 1122 and through the engaged contacts and posts.

The test circuit board can be made using the techniques commonly employed to form ordinary circuit boards. The test circuit board may incorporate electronic elements such as capacitors in close proximity to the contact pads as required for certain high-frequency signal processing circuits. The internal features of the microelectronic element 1160 are also compatible with high-frequency signals. The conductive support elements 1130, traces 1138 and posts 1146 provide low-impedance signal paths between the tips 1150 of the posts and the contacts 1164 of the microelectronic element 1160. Because each post 1146 is connected to an immediately adjacent conductive support element 1130, traces 1138 may be quite short. The low-impedance signal paths are particularly useful in high-frequency operation, as, for example, where the microelectronic element must send or receive signals at a frequency of 300 MHz or more.

After testing, the microelectronic element 1160 may be removed from the testing assembly 1120 and packaged using an interposer such as a circuitized, dielectric film. The microelectronic package, such as a ball grid array package, may be connected with contact pads on a circuit panel using a conductive bonding material such as solder. The solder-bonding process may be performed using conventional equipment commonly used for surface-mounting microelectronic components. Thus, the solder masses may be provided on the terminals of the microelectronic package, and may be reflowed after engaging the terminals with the conductive pads.

Referring to FIG. 21, in certain preferred embodiments of the present invention, a testing assembly 1220 has a compliant material 1270 positioned between a flexible substrate 1232 and a test board 1222. The compliant material layer 1270 preferably does not substantially restrict movement of conductive posts 1246. The compliant material desirably prevents contaminants from entering the testing assembly 1220. Merely by way of example, the compliant material 1270 may be a gel, foam or the like. Despite the presence of the compliant material, conductive elements 1230 still support the flexible substrate 1232 to a substantial degree.

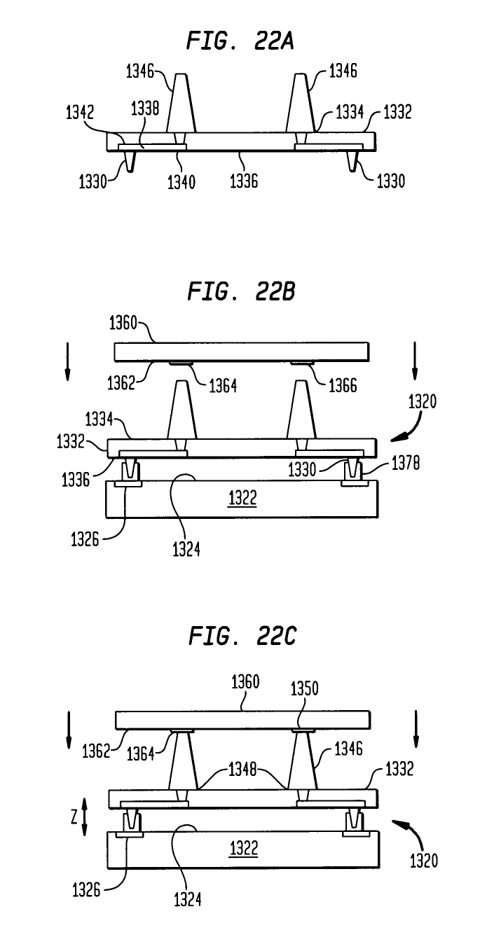

Referring to FIG. 22A, a microelectronic assembly in accordance with another preferred embodiment of the present invention includes an interposer having a flexible dielectric substrate 1332 with a first surface 1334 and a second surface 1336 remote therefrom. The interposer includes first conductive posts 1346 projecting upwardly from the first surface 1334 of the flexible substrate 1332 and second conductive posts 1330 projecting downwardly from flexible substrate 1332. The first and second conductive posts 1346, 1330 are electrically interconnected using conductive traces 1338 having first ends 1340 attached to second conductive posts 1330 and second ends 1342 attached to first conductive posts 1346.

Referring to FIG. 22B, the interposer may be assembled with a test board 1322 by juxtaposing the second surface 1336 of the flexible substrate 1332 with the active surface 1324 of test board 1322. The second conductive posts 1330 are electrically interconnected with the conductive pads 1326 of the test board 1322. In certain preferred embodiments, the second posts 1330 are electrically interconnected to the conductive pads 1326 using a fusible conductive material such as solder 1378. A filler material (not shown), such as a compliant layer of dielectric encapsulant, may be provided between the flexible substrate 1332 and the test board 1322.

The combination of the interposer and the test board 1322 form a testing assembly 1320 that may be used for testing microelectronic elements such as semiconductor chips and microelectronic packages. Referring to FIG. 22C, the testing assembly 1320 is used for testing a semiconductor chip 1360 having a first surface 1362 including contacts 1364. In order to test the chip, the contacts 1364 are abutted against the tip ends 1350 of the first conductive posts 1346. The contacts 1364 are placed in substantial alignment with top surfaces 1350 of the conductive posts 1346. Top surfaces 1366 of the contacts 1364 may be disposed at different heights and do not lie in the same plane. Such non-planarity can arise from causes such as warpage of the chip 1360 and/or unequal thickness of the contact 1364. In addition, the tips 1350 of the first conductive posts 1346 may not be precisely coplanar with one another, due to factors such as unequal heights of the second conductive posts 1330; non-planarity of the first surface 1324 of the test board 1322; warpage of the flexible substrate 1332; tilting of the chip 1360 with respect to the test board 1322; and unequal heights of the first conductive posts 1346 themselves. For these and other reasons, the vertical distances between the contacts 1364 and the tips 1350 of the posts 1346 may be unequal.

Referring to FIGS. 22B and 22C, the microelectronic element 1360 is moved toward the test board 1322, by moving the test board, the microelectronic element or both toward one another. The contacts 1364 engage the first conductive posts 1346 for making electrical contact with the conductive posts. The tips 1350 of the posts 1346 are able to move so as to compensate for the initial differences in vertical spacing so that all of the tips can be brought into contact with all of the contacts simultaneously using with only a moderate vertical force applied to urge the microelectronic element 1360 and the test board 1322 together. In this process, at least some of the tips of the first conductive posts 1346 are displaced in the vertical or z direction relative to others of the post tips.

A significant portion of this relative displacement arises from movement of the bases 1348 of the first conductive posts 1346 relative to one another and relative to test board 1320. Because the first conductive posts 1346 are attached to flexible substrate 1332 and are offset from the second conductive posts 1330, and because the second conductive posts 1330 space the flexible substrate 1332 from the first surface 1324 of the test board 1322, the flexible substrate 1332 can deform. Further, different portions of the flexible substrate 1332 associated with different posts can deform independently of one another. As pressure is applied by contacts 1364 onto the first conductive posts 1346, the misalignment of the second conductive posts 1330 relative to the first conductive posts allows one or more regions of the flexible substrate 1332 to bend toward the test board 1322, allowing the bases 1348 of the first conductive posts 1346 to also move downward toward the test board. In practice, the deformation of the substrate 1332 may include bending and/or stretching of the substrate so that the motion of the base may include a tilting about an axis in the x-y or horizontal plane as well as some horizontal displacement of the base, and may also include other components of motion.

Referring to FIG. 22C, the independent displacement of the first conductive posts 1346 relative to one another allows all of the contacts 1364 of the microelectronic element 1360 to contact all of the tips 1350 of the first conductive posts 1346 on the test board 722. Because all of the contacts 764 of the chip 1360 can be engaged reliably with all of the post tips 1350 of the first conductive posts 1346, the microelectronic chip 1360 can be tested reliably by applying test signals, power and ground potentials through the test board 1322 and through the engaged contacts and posts.

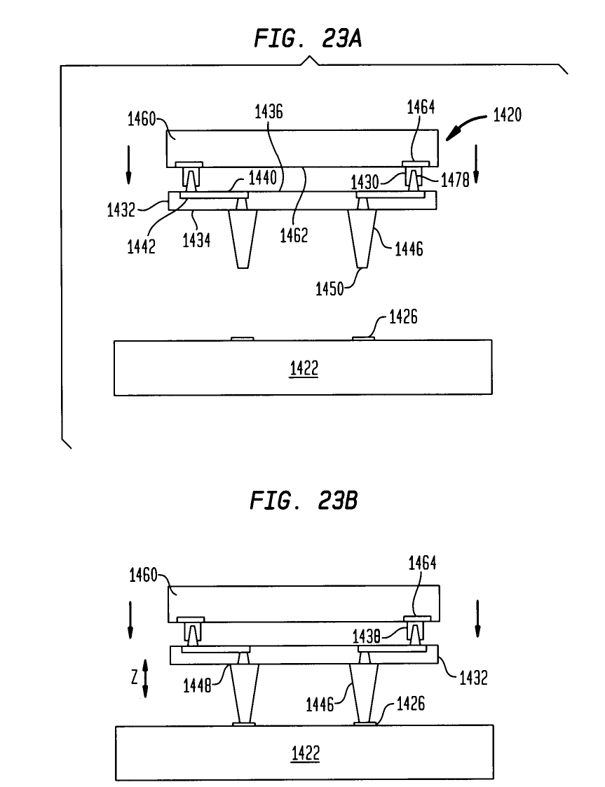

FIGS. 23A and 23B show a microelectronic assembly in accordance with another preferred embodiment of the present invention with the above-described flexible interposer being assembled with a microelectronic element 1460 to form a testable microelectronic package 1420. Referring to FIG. 23A, the testable package 1420 includes a microelectronic element, such as a semiconductor chip 1460, having a first face 1462 including contacts 1464. The testable package 1420 also includes a flexible interposer having a flexible, dielectric substrate 1432 with a first surface 1434 facing away from microelectronic element 1460 and a second surface 1436 facing toward the microelectronic element 1460. The flexible interposer includes first conductive posts 1446 that project from the first surface 1434 of flexible substrate 1432 and away from chip 1460. The first conductive posts 1446 include tip ends 1450 at lower ends thereof. The substrate 1432 also includes second conductive posts 1430 that project from the second surface 1436 of the substrate and toward the chip 1460. The second conductive posts 1430 may be electrically interconnected with contacts 1464 by a conductive material 1478 such as solder. The first and second conductive posts 1446, 1430 are desirably electrically interconnected with one another through conductive traces 1438 that are provided on flexible substrate. The conductive traces 1438 have first ends 1440 that are connected with first conductive posts 1446 and second ends 1442 that are connected with second conductive posts 1430.

The testable package 1420 may be tested by substantially aligning the first conductive posts 1446 with conductive pads 1426 of a test board 1422 and abutting the tip ends 1450 of the first conductive posts 1446 against the conductive pads 1426 as shown in FIG. 23B. As described above in earlier embodiments, the first conductive posts 1446 are free to move independently of other first conductive posts so as to ensure reliable contact between each first conductive post 1446 and each conductive pad 1426 on test board 1422. The tips 1450 of the first conductive posts 1446 are able to move so as to compensate for potential differences in vertical spacing so that all of the tips can be brought into contact with all of the conductive pads simultaneously using with only a moderate vertical force applied to urge the testable package 1420 and the test board 1422 together. In this process, at least some of the tips 1450 of the first conductive posts 1446 are displaced in the vertical or z direction relative to others of the post tips. Further, different portions of the flexible substrate 1432 associated with different first conductive posts 1446 can deform independently of one another. As pressure is applied by contacts 1464 onto the second conductive posts 1430, misalignment of the first conductive posts 1446 relative to the second conductive posts 1430 allows one or more regions of the flexible substrate 1432 to bend toward the test board 1422, allowing the bases 1448 of the first conductive posts 1446 to move toward the chip 1460. In practice, the deformation of the substrate 1432 may include bending and/or stretching of the substrate so that the motion of the base may include a tilting about an axis in the x-y or horizontal plane as well as some horizontal displacement of the base, and may also include other components of motion.

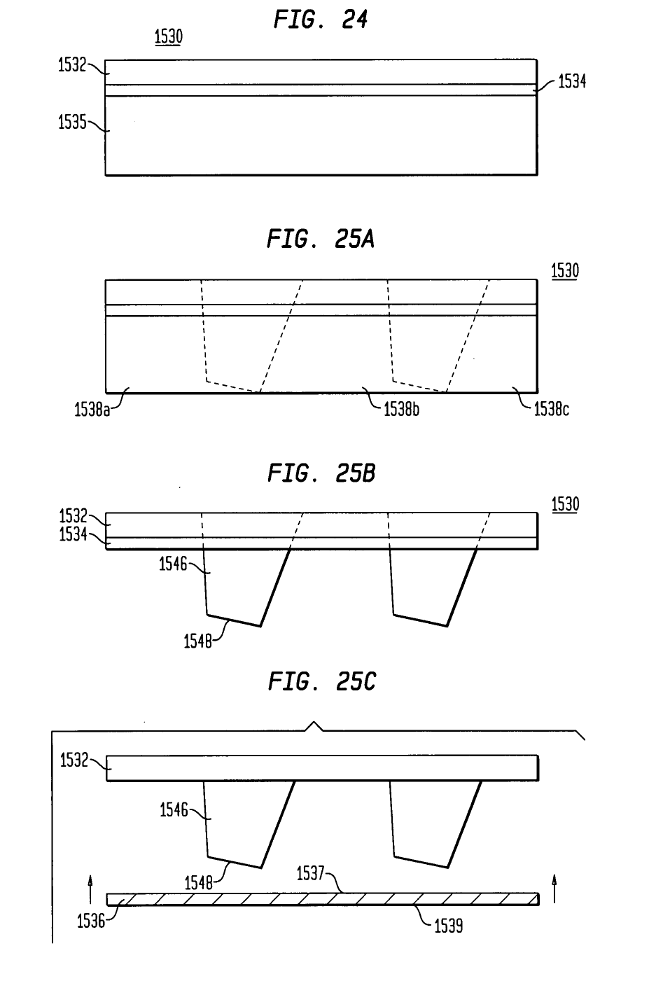

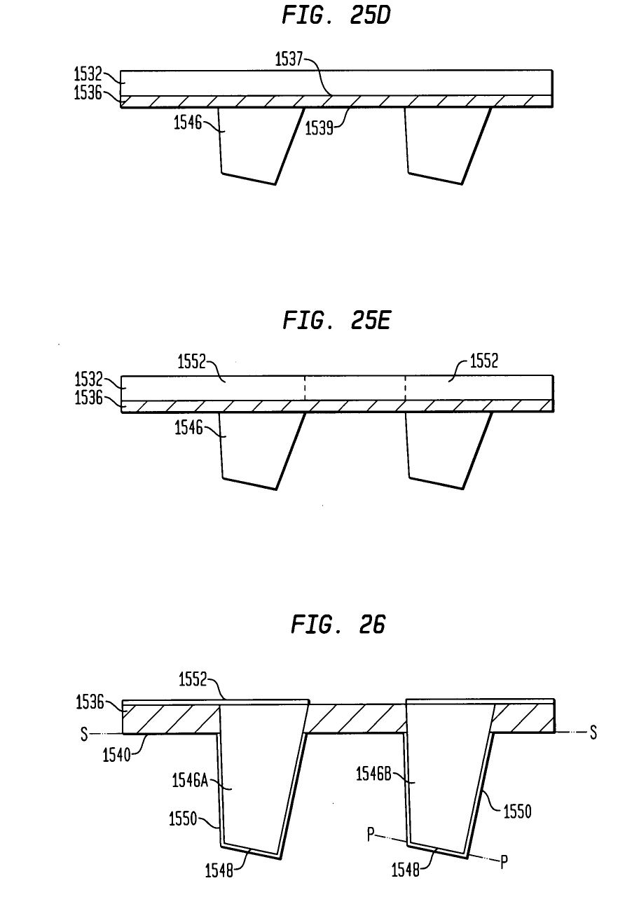

Referring to FIG. 24, in certain preferred embodiments of the present invention, a microelectronic subassembly may be fabricated by a process such as that disclosed in co-pending, commonly assigned U.S. Provisional Application No. 60/508,970, the disclosure of which is incorporated by reference herein. As disclosed in certain preferred embodiments of the '970 application, a metallic plate 1530 includes a top layer 1532 made of a conductive material, an intermediate etch stop layer 1534 and a bottom layer 1535 made of a conductive material. The top and bottom layers 1532, 1535 may include electrically conductive materials such as copper. The intermediate etch stop layer 1534 may include materials such as nickel. Referring to FIGS. 25A and 25B, the bottom layer 1535 of metallic plate 1530 is stamped or etched to remove portions 1538a, 1538b and 1538c of bottom layer 1535 so as to form conductive terminals or posts 1546. Referring to FIGS. 25B and 25C, after the posts 1546 have been formed, the etch stop layer 1534 is removed by a process that leaves the top layer 1532 and the posts 1546 in place. One preferred method for removing the etch stop layer includes a chemical etching process. Referring to FIGS. 25C and 25D, a flexible dielectric sheet 1536 such as a polyimide film is assembled with the top layer 1532 and the posts 1546 so that the posts 1546 project through the dielectric layer 1536. A first face 1537 of the dielectric sheet 1536 faces toward the top layer 1532 and a second face 1539 of the dielectric layer faces toward contact surfaces 1548 of the conductive terminals 1546. The dielectric layer may be fabricated by coating a dielectric layer such as a polyimide onto the top layer 1532 and around the terminals, or more typically, by forcibly engaging the terminals with the dielectric sheet so that the terminals penetrate through the sheet. Although the thickness of the dielectric substrate will vary with the application, the dielectric substrate most typically is about 15-100 μm thick. Referring to FIG. 25E, once the dielectric sheet is in place, the top layer is etched to form individual conductive traces 1552 on the first face 1537 of the dielectric layer 1536.

In the particular embodiment illustrated in FIGS. 25A-25E, the flexible dielectric substrate 1536 is assembled with top layer 1532 before the top layer is treated. However, in other embodiments, the flexible dielectric substrate 1536 may be attached to the top layer 1530 after the conductive traces have been formed or at a later process step. Alternatively, conventional processes such as plating may form the traces. An etching process may also be used, whereby the terminals or posts may be formed using the methods disclosed in commonly assigned U.S. Pat. No. 6,177,636, the disclosure of which is hereby incorporated by reference herein. In yet other preferred embodiments, the conductive terminals may be fabricated as individual elements and assembled to the flexible dielectric sheet in any suitable manner that connects the conductive terminals to the traces. As used herein, the terminology “conductive terminal” may also mean a conductive bump, or a conductive post having a height significantly greater than its width.

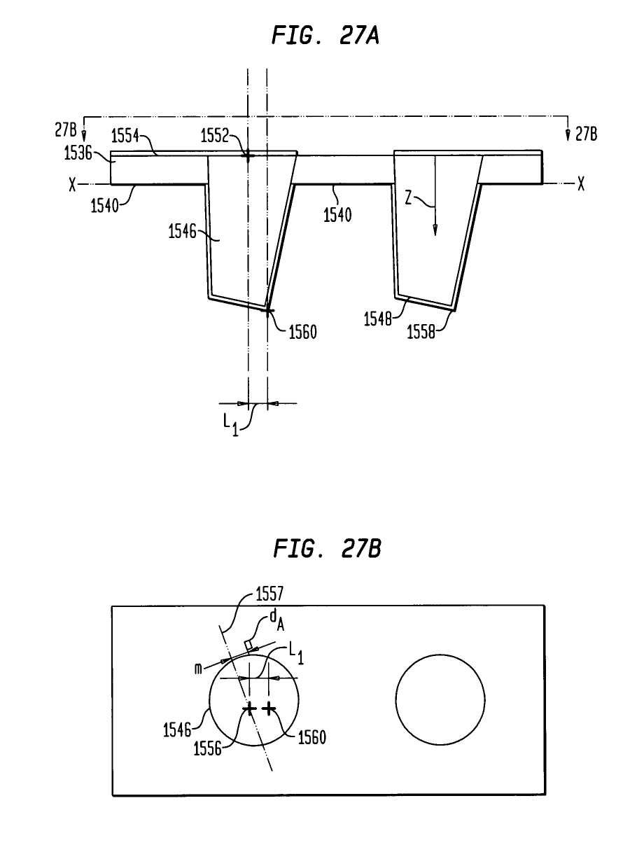

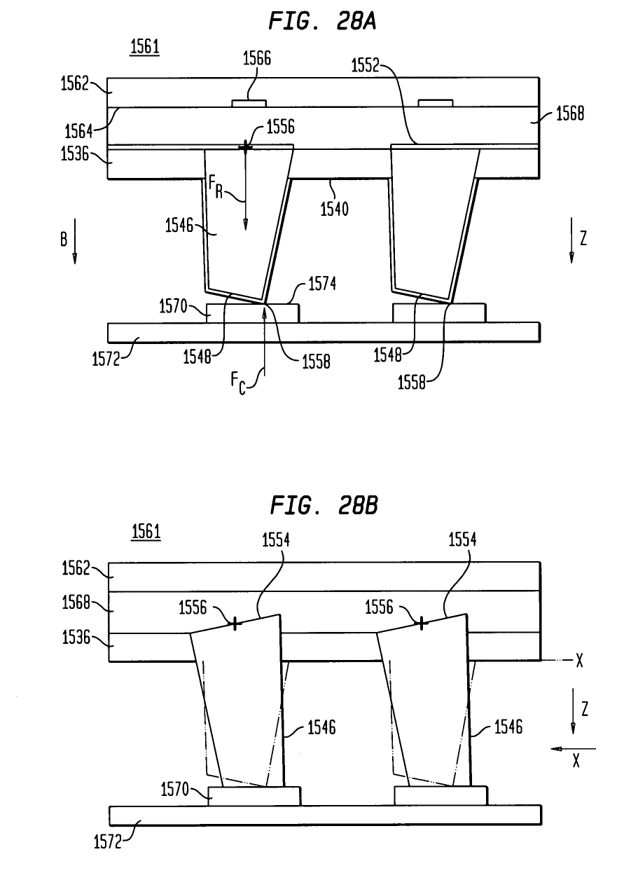

Referring to FIG. 26, each conductive terminal 1546 has an exposed contact surface 1548 that defines a plane P that is transverse to a plane S defined by bottom surface 1540 of flexible substrate 1536. A highly conductive metal layer 1550 such as gold may be formed over an outer surface of the conductive terminals 1546.

Referring to FIGS. 27A and 27B, each conductive post 1546 is physically connected to flexible substrate 1536 and projects from the flexible substrate in an upward direction designated z (pointing toward the bottom of the drawing in FIG. 27A). In a particular preferred embodiment shown in FIG. 27A, the upward direction Z preferably extends in a direction substantially perpendicular to plane X defined by the bottom surface 1540 of flexible substrate 1536. The base 1554 of conductive post 1546 defines a centroid 1556. The centroid is defined such that for any arbitrary line 1557 drawn through the centroid, the integral of the product of the distance or moment arm from the line to an incremental area element dA, taken over the area of the base lying on one side of the line is equal to the corresponding integral taken on the opposite side of the line, which is essentially a center of mass of the base of the conductive post 46. The conductive post 1546 also has an upper extremity 1558, which is the region of exposed contact surface 1548 that lies furthest away in the upward direction Z from the base of conductive post 1546. The upper extremity 1558 defines a centroid 1560 that is offset from the centroid 1556 of the base 1554 in a horizontal offset direction transverse to the upward direction Z. Desirably, there is a sharp edge bounding contact surface 1548, particularly at upper extremity 1558. As shown in FIGS. 27A and 27B, the centroid 1560 of extremity 1558 is offset a horizontal distance L₁ from the centroid 1556 of the base 1554.

Referring to FIG. 28A, the flexible dielectric substrate 1536 and the conductive posts 1546 mounted thereon are assembled with a microelectronic element 1562 such as a semiconductor chip having a front or contact-bearing face 1564 and electrical contacts 1566 exposed at face 1564. A passivation layer (not shown) may be formed over the contact-bearing face 1564 with openings at contacts 1566. The assembly also includes a support layer 1568 such as a compliant layer, which may be made of an elastomer, a gel on a stiffer material such as an epoxy or other adhesive. One or more of traces 1552 are preferably electrically interconnected with one or more of the contacts 1566 of semiconductor chip 1562 for electrically interconnecting the posts 1546 with the microelectronic element 1562.

Referring to FIGS. 28A and 28B, in a method of operation according to one embodiment of the present invention, the microelectronic package 1561 is tested by juxtaposing the conductive bumps 1546 with contact pads 1570 on a second microelectronic element 1572 such as a circuitized test board. The conductive bumps 1546 are placed in substantial alignment with top surfaces 1574 of the respective contact pads 1570. As the conductive bumps are advanced toward the contact 1570 with a compression of motion in the direction Z, the upper extremity 1558 of each contact surface is the first portion of contact surface 1548 to engage top surface 1574 of contact 1570. FIG. 5B, the microelectronic package is first moved in the direction Z so that the extremity 58 of each contact surface 48 engages the top surface 74 of contact pad 70. The downward force Fc applied on the contact pad 1570 through the conductive post 1546 15 causes the base 1554 of the conductive post 1546 to move into the compliant layer 1568. The vertical compression of the reaction force F_{R} is centered at the centroid 1551 of the base. The horizontal offset between these forces applies a torque or moment tending to tilt the post about a horizontal axis. In particular, as shown in FIG. 28B, the conductive post 1546 rotates about base centroid 1556 so that there is rotation of the conductive post about the horizontal axis defined by plane X. The microelectronic package is then moved horizontally in the direction X to provide an effective wipe mechanism for metal-to-metal contact between contact surface 1548 of conductive post 1546 and top surface 1574 of contact pad 1570.

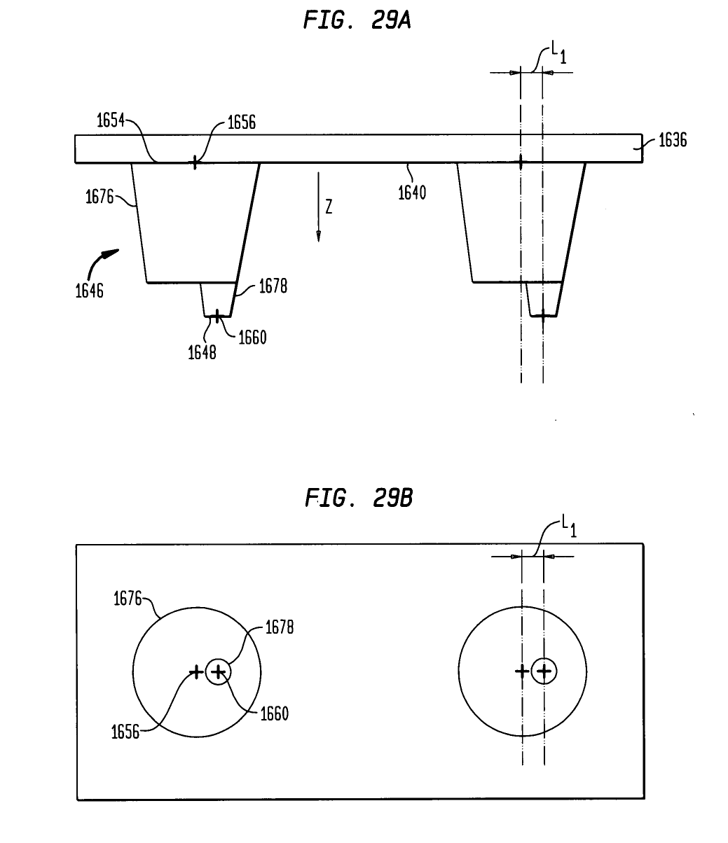

FIGS. 29A and 29B show a microelectronic assembly that is assembled in a manner substantially similar to the package described above in FIGS. 24-28B. The microelectronic assembly includes flexible substrate 1636 having conductive posts 1646 extending from a bottom surface 1640 in a direction Z. The conductive post 1646 has a first body 1676 and a second body 1678 formed atop the first body 1676. The first body 1676 has a base 1654 defining a centroid 1656. The second body 1678 has a contact surface 1648 defining a centroid 1660. The centroid 1660 at the contact surface 1648 of second body 1678 is offset from the base centroid 1656 of the first body 1676 by a horizontal distance L₁. The contact surface 1648 of second body 1678 defines the upper extremity of the conductive post 1646. During a testing operation, when the conductive posts 1646 are electrically interconnected with opposing contact pads on a test board (not shown), the upper extremity 1648 is preferably the first point of the conductive post 1646 to engage the contact pads. Due to the centroid 1660 being offset from base centroid 1656, the base 1654 of the conductive posts 1646 will tend to rotate about base centroid 1656 to provide a wipe mechanism for the device. In certain embodiments, the second body 1678 may be as large or larger than the first body 1676.

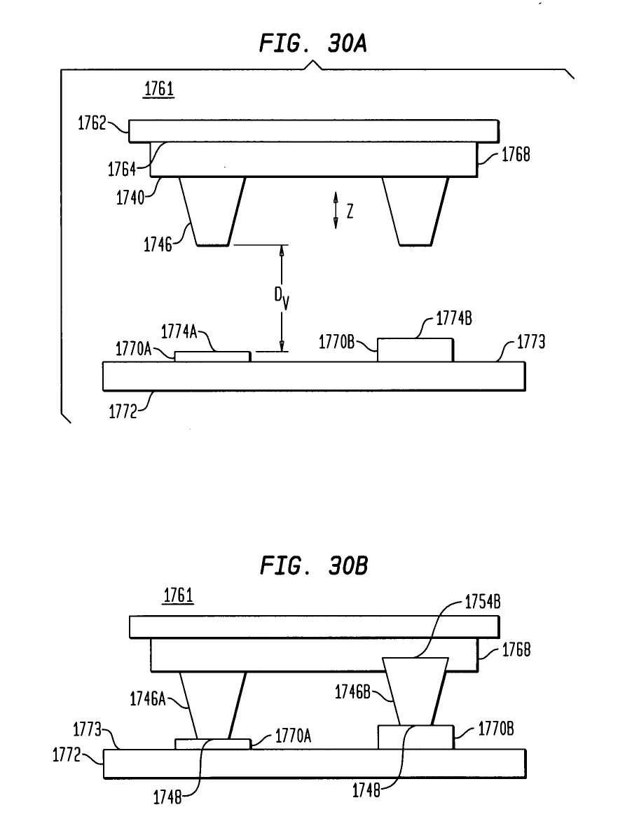

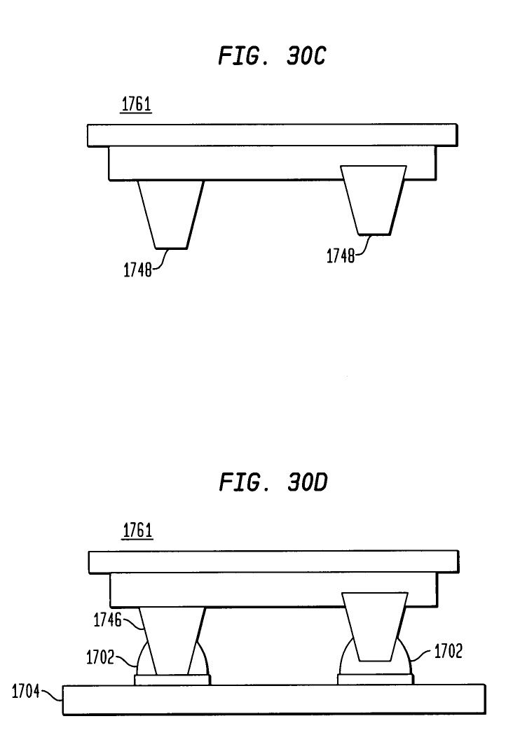

Referring to FIG. 30A, a microelectronic package 1761 includes a microelectronic element 1762 having a contact-bearing face 1764 and a mounting structure 1768 assembled over the contact-bearing face 1764 of the microelectronic element. The mounting structure 1768 may include a flexible substrate such as a flexible film and a compliant support layer beneath the film, or may include only a support layer and the conductive element used to connect terminals 1741 to microelectronic element 1762. The microelectronic package also preferably includes conductive terminals or posts 1746 provided on the mounting structure 1768. The mounting structure has a plastically deformable material incorporated therein so that the posts 1746 have compliancy along the axis designated Z, (FIG. 30A) orthogonal to a plane defined by a bottom surface 1740 of mounting structure 1768.

Here again, the microelectronic package 1761 is tested by juxtaposing the conductive posts 1746A, 1746B with contacts 1770A and 1770B of a circuit board 1772. The circuit board 1772 has a top surface 1773 at which contact pads 1770A and 1770B are exposed. A first contact pad 1770A has a top surface 1774A that defines a plane that is different height than a top surface 1774B of another contact pad. Such non-planarity can arise from causes such as warpage of the test substrate 1772 itself and unequal thicknesses of contact pads 1770. Also, although not shown in FIG. 30A, the tips of the posts 1746 may not be precisely coplanar with one another, due to factors such as non-planarity of the surface of the microelectronic device; warpage of the moving structure and unequal heights of the posts themselves. Also, the package may be tilted slightly with respect to the test substrate. For these and other reasons, the vertical distances Dv between the tips of the posts and the contact pads may be unequal.

Referring to FIG. 306B, when microelectronic package 1761 is tested, the conductive posts 1746 are advanced toward the opposing contact pads 1770 of test board 1772. As shown in FIG. 30B, the base 1754B of second conductive post 1746B is able to move into the plastically deformable mounting structure 1768. Even though the first conductive post 1746A may also move into the deformable mounting structure, such movement is not necessary when forming an electrical interconnection because of the height difference between contact pads 1770A and 1770B. Although not limited by any particular theory of operation, it is believed that providing a microelectronic package having a plastically deformable mounting structure enables the conductive posts of the package to move so as to accommodate for opposing contact pads that are non-planar.

In this embodiment as well, while the posts are engaged with the contact pads, the package is subjected to electrical testing by passing power, signals and ground potential through the engaged posts and contact pads.

Many materials can deform through a substantial range of plastic deformation, larger than the range of elastic deformation. Preferably, the mounting structure is susceptible to plastic deformation under relatively small forces, which are less than those forces required to damage the other elements of the package and test board. The relatively large range of plastic deformation allows for substantial movement of the posts during testing. Stated another way, a plastically deformable mounting structure can provide a greater range of movement of the posts than a structure of comparable dimensions, which is not susceptible to plastic deformation under the range of forces encountered during testing. As used in this disclosure, the term “plastic deformation” means a deformation which does not spontaneously reverse itself within a short time, such as a few minutes or seconds, after removal of the applied loads. Some plastically deformable materials have a shape memory, and can return to their original configuration upon heating or cooling after plastic deformation. Other plastically deformable materials, such as certain polymeric foams, tend to recover their original shape after prolonged storage. If these materials are employed, the package with a plastically-deformed mounting structure can be subjected to heating, cooling or prolonged storage after testing so as to return the posts or other terminals to their original configuration.

However, in many cases, the plastically deformed mounting structure cannot recover its original configuration, but instead is permanently deformed during the testing operation. As shown in FIG. 30C, the tips or contact surfaces 1748 of the posts have been permanently displaced to a non-planar configuration corresponding to the configuration of the contact pad surfaces. However, this does not pose a serious drawback. After testing, referring to FIG. 30D, the package can be permanently mounted to a circuit board 1704 using solder or other bonding material 1702 to connect the posts 1746 or other terminals to the contacts. The bonding material 1702 compensates for the non-planarity of the post tips. In a further variant, the package can be forced into engagement with a circuit board during the permanent mounting operation, thereby deforming the mounting structure again so as to bring the post tips or other contact surfaces of the terminals into conformity with the contact pads 1706 of the circuit board. In still another variant, the package can be abutted against a known planar surface after testing so as to bring the post tips into planarity. In a reverse arrangement, the test board used during the testing operation is a planar structure, having all of its contact pads coplanar. The plastic deformation of the mounting structure during testing in this variant will make the post tips more nearly coplanar with one another, and hence compensates for imperfections in the package.

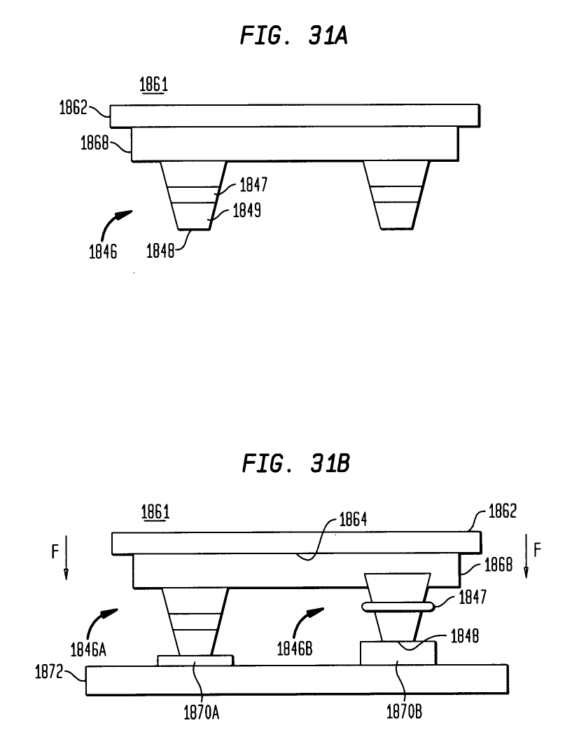

Referring to FIG. 31A, a microelectronic package 1861 includes a microelectronic element 1862 having contacts (not shown), a mounting structure 1868 associated with the microelectronic element 1862 and a plurality of conductive terminals 1846 carried on the mounting structure. Each conductive terminal 1846 has an exposed contact surface 1848 at a tip end thereof. Each of the conductive terminals 1846 is plastically deformable and includes a weaker region 1847 and a stronger region 1849. The weaker region 1847 is preferably able to more readily plastically deform than the stronger region of the terminal. Thus, the stronger material 1849 desirably has lower yield strength than the first or weaker material. The first material in the weaker region 1847 may include conductive materials such as annealed tin, annealed lead, annealed gold, and shape memory alloys. The first material may also be a non-conductive material, such as expanded polypropylene foam or other polymeric materials. Where the first material is a nonconductive material, the post may include a very weak conductive element extending across the non-conductive material so as to maintain electrical continuity.

Referring to FIG. 31B, in operation the microelectronic package 1861 is tested by aligning the conductive posts 1846 with contact pads 1870 on a test board 1872. As shown in FIG. 31B, the respective contact pads 1870A and 1870B of test board 1872 do not have top surfaces that lie in a common plane. As a result, the conductive posts 1846 will have to accommodate such non-planarity if a reliable electrical interconnection is to be formed. Due to the plastically deformable material 1847 in the conductive posts 1846, the exposed contact surface 1848 of second conductive posts 1846 is displaced relative to the contact-bearing face 1864 of microelectronic element 1862. As a result, the exposed contact surfaces of conductive posts are able to form reliable interconnections with the opposing contact pads. As explained above, the plastically deformable materials can provide a greater range of motion than could be obtained using elastic deformation. Here again, the testing step can result in a permanent change in the configuration of the post tips.

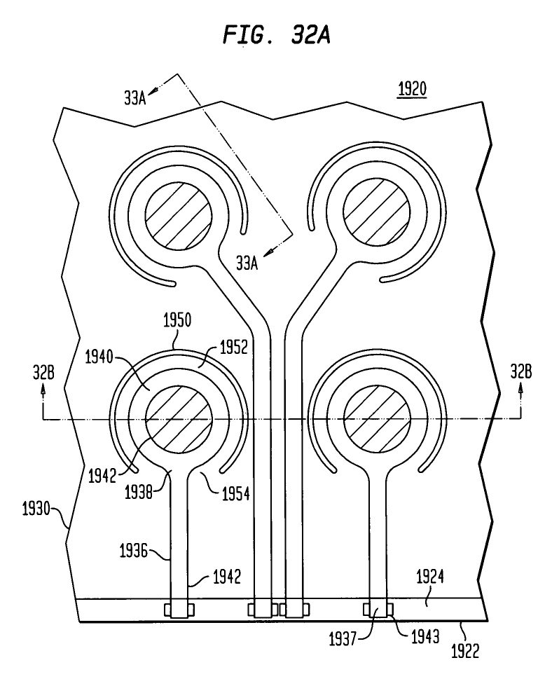

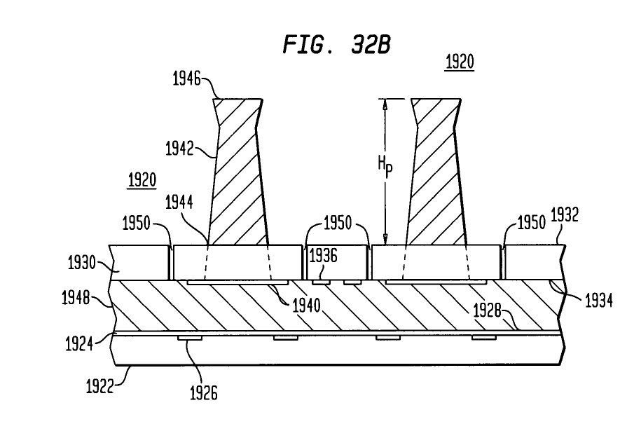

Referring to FIGS. 32A and 32B, a microelectronic package 1920 in accordance with one embodiment of the present invention includes a microelectronic element 1922 such as a semiconductor chip having a front or contact-bearing face 1924 and electrical contacts 1926 exposed at the face 1924. A passivation layer 1928 may be formed over the contact-bearing face 24 with openings at contacts 1926.

The microelectronic package 1920 preferably includes a flexible dielectric substrate 1930, such as a polyimide or other polymeric sheet, including a top surface 1932 and a bottom surface 1934 remote therefrom. Although the thickness of the dielectric substrate 1930 may vary depending upon the application, the dielectric substrate most typically is about 15-100 μm thick. The flexible sheet 1930 has conductive traces 36 thereon. In the particular embodiment illustrated in FIGS. 32A and 32B, the conductive traces are disposed on the bottom surface 1934 of the flexible sheet 1930. However, in other embodiments, the conductive traces 1936 may extend on the top surface 1932 of the flexible sheet 1930, on both the top and bottom surfaces or within the interior of flexible sheet 1930. Thus, as used in this disclosure, a statement that a first feature is disposed “on” a second feature should not be understood as requiring that the first feature lie on a surface of the second feature. Conductive traces 1936 may be formed from any electrically conductive material, but most typically are formed from copper, copper alloys, gold or combinations of these materials. The thickness of the traces 36 may also vary depending upon the application, but typically is about 10-25 μm. The traces 1936 are arranged so that each trace has a post end 1938 terminating at a capture pad 1940 and a connection end 1942 remote from the post end 1938.

Electrically conductive terminals in the form of posts or pillars 1942 project from the top surface 1932 of flexible substrate 1930. Each post 1942 is connected to the conductive capture pad 1940 at the post end 1930 of one of the traces 1936. In the particular embodiment of FIGS. 32A and 32B, the posts 1942 extend upwardly through the dielectric sheet 1930 from the capture pads 1940 of the traces 1936. The exact dimensions of the posts may vary over a significant range but most typically the height Hₚ of each post 1942 above the top surface 1932 of the flexible sheet 1930 is about 50-300 μm. Each post 1942 has a base 1944 adjacent the flexible sheet 1930 and a tip 1946 remote from the flexible sheet. In the particular embodiment illustrated, the posts extend in directions that are substantially parallel to one another. The bases of the posts typically are about 100-600 μm in diameter, and the tips typically are about 40-200 μm in diameter. The posts 1942 may be formed from any electrically conductive material, but desirably are formed from metallic material such as copper, copper alloys, gold and combinations thereof. For example, the posts may be formed principally from copper with a layer of gold at the surfaces of the posts.

The dielectric sheet 1930, traces 1936 and posts 1942 may be fabricated by a process such as that disclosed in co-pending, commonly assigned U.S. provisional patent application Ser. No. 60/508,970, the disclosure of which is incorporated by reference herein. As disclosed in greater detail in the '970 application, a metallic plate is etched or otherwise treated to form numerous metallic posts projecting from the plate. A dielectric layer is applied to this plate so that the posts project through the dielectric layer. An inner face or side of the dielectric layer faces toward the metallic plate, whereas the outer side of the dielectric layer faces towards the tips of the posts. The dielectric layer may be fabricated by coating a dielectric such as a polyimide onto the plate around the posts or, more typically, by forcibly engaging the posts with the dielectric sheet so that the posts penetrate through the sheet. Once the sheet is in place, the metallic plate is etched to form individual traces on the inner side of the dielectric layer. Alternatively, conventional processes such as plating may form the traces. An etching process may also be used whereby the posts may be formed using the methods disclosed in commonly assigned U.S. Pat. No. 6,177,636, the disclosure of which is hereby incorporated by reference herein. In yet another preferred embodiment, the posts may be fabricated as individual elements and assembled to the flexible sheet in any suitable manner that connects the posts 1942 to the traces 1936.

The microelectronic package 1920 also preferably includes a support layer such as a compliant layer 1948 disposed between flexible dielectric sheet 1930 and front face 1924 of semiconductor chip 1922. Merely by way of example, the compliant layer 1948 may be a gel, foam or the like, or a stiffer material such as an epoxy or other adhesive.

The flexible dielectric substrate 1930 includes at least one gap 1950 formed therein. The gap 1950 may be formed in the flexible substrate 1930 by any known method used to perforate a material such as by laser cutting, chemical etching, high pressure liquid stream cutting or mechanical punching. In the particular preferred embodiment shown in FIGS. 32A and 32B, a gap 1950 is formed at least partially around each conductive post 1942. The plurality of gaps 1950 defines a plurality of regions 1952 of flexible substrate 1930. One of the conductive posts 1942 is mounted on each region 1952 defined by one of the gaps 1950. Each region 1952 is connected to the remainder of the substrate 1930 by a flap section 1954.

The conductive traces 1936 are electrically connected to contacts 1943 on the microelectronic element 1922 and provide electrically conductive paths between the microelectronic element 1922 and the conductive posts 1942. In the particular arrangement shown, contacts 1943 are disposed in a row along an edge of surface 1924 of the microelectronic element 1922. In the particular arrangement shown, the traces are connected to the contacts by leads 1937 formed integrally with traces 1936. Any other suitable connection can be used as, for example, wire bonds extending between the traces and contacts. Also, the contacts 1943 need not be disposed adjacent an edge of the microelectronic element. Certain common semiconductor chips have contacts disposed in arrays distributed over the front surface of the chip, whereas others have contacts disposed in one or more rows near the center of the chip surface. The substrate 1930 and compliant layer 1948 may be provided with appropriate apertures, commonly referred to as bond windows, aligned with such contacts.

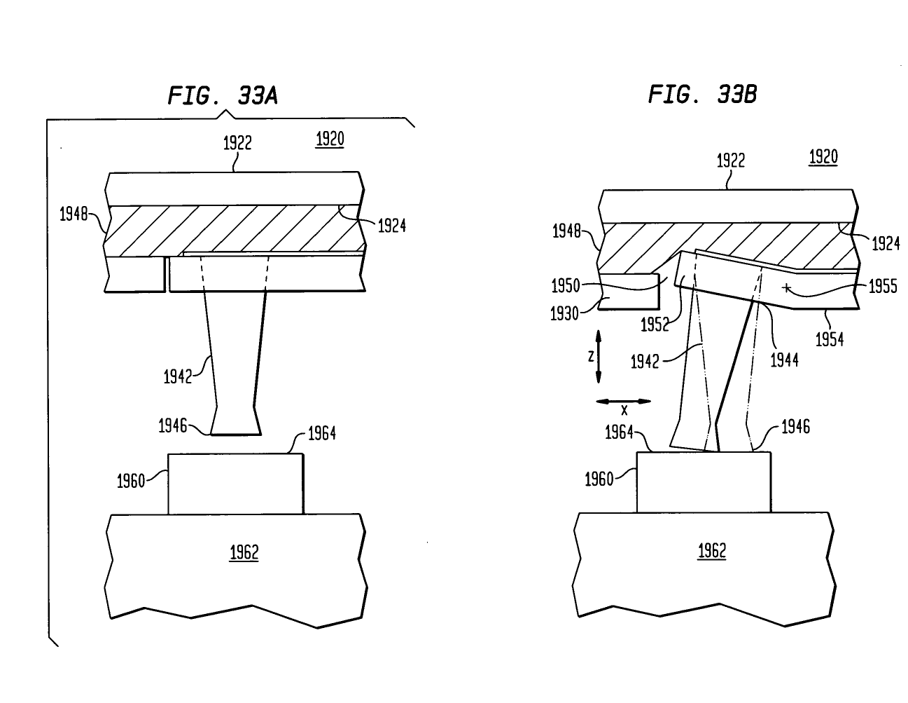

In a method of operation according to a further embodiment of the present invention, a microelectronic package 1920, such as the package described above with reference to FIGS. 32A and 32B, is tested by juxtaposing the conductive posts 1942 with contact pads 1960 on a second microelectronic element 1962 such as a circuitized test board (FIGS. 33A and 33B). The conductive posts 1942 are placed in substantial alignment with top surfaces 1964 of the respective contact pads 1960. The top surfaces may be disposed at different heights so that the top surfaces do not lie in the same plane. Such non-planarity can arise from causes such as warpage of the circuit board 1962 itself and unequal thickness of the contact pads 1960. In addition, the tips 1946 of the conductive posts 1942 may not be precisely co-planar with one another due to such factors as unequal heights of the conductive posts 1942; non-planarity of the front surface 1924 of semiconductor chip 1922 and non-uniformity of compliant layer 1948. In addition, the microelectronic package 1920 may be tilted slightly with respect to the circuit board 1962. For all of these and other reasons, the vertical distances between the tips 1946 of the conductive posts 1942 and the top surfaces 1964 of the contact pads 1960 may be unequal.

Referring to FIG. 33B, the microelectronic package 1920 is moved toward the test board 1962 by moving the test board, the package or both. Initially, the microelectronic package is moved downward in a direction indicated by axis Z so that the tips 1946 of conductive posts 1942 engage the top surface 1964 of contacts 1960. The gap 1950 extending through flexible substrate 1930 enables the region 1952 of substrate 1930 to have hinge-like movement at flap 1954. As a result, the base of each conductive post 1942 is able to move in a generally vertical direction, indicated as direction Z in FIG. 33B, substantially independently of the remainder of the substrate 1930 and substantially independently of the other conductive posts. Because movement of the posts does not require displacement of the entire substrate 1930, only those regions of compliant layer 1948 aligned with regions 1952 are compressed as the base 1944 of each post moves toward microelectronic element 1922. Stated another way, the forces applied in the Z direction by the contacts 1960 urging the posts toward the microelectronic element 1922 are substantially concentrated in those regions of the compliant layer 1948 aligned with regions 1952. The effectively increases the compliance of layer 1948, so that the posts 1942 can be moved to the same extent with lower forces than would be the case in an otherwise comparable system with a continuous substrate 1930, without the aforementioned gaps.

Substantially independent movability of the individual posts 1942 in the Z direction helps to assure that all of the posts 1942 can be brought into engagement with all of the corresponding contacts 1960 simultaneously. This helps to insure reliable electrical interconnections between the tips 1946 of conductive posts and contacts 1960. Moreover, because each region 1952 of the substrate tends to bend around the hinge-like flap 1954, each region, and the post 1942 connected thereto, tends to tilt around a theoretical horizontal axis 1955 in or near the flap 1954. Such tilting movement tends to cause the tip 1946 of the post mounted to such flap to move in a horizontal direction indicated by arrow X relative to the remainder of the package, and hence relative to the associated contact 1960, as the tips of the posts engage the contact. The posts move from the starting orientation shown in broken lines in FIG. 33B to the orientation shown in solid lines. The horizontal movement of the tips 1946 causes the tips to wipe across the top surfaces 1964 of the contacts, which further aids in establishing reliable electrical connections.

Additionally, the microelectronic package 1920 may also be moved in horizontal direction X relative to test board 1962 so as to provide additional wiping motion between tip 1946 and top surface 1964 of contact 1960.

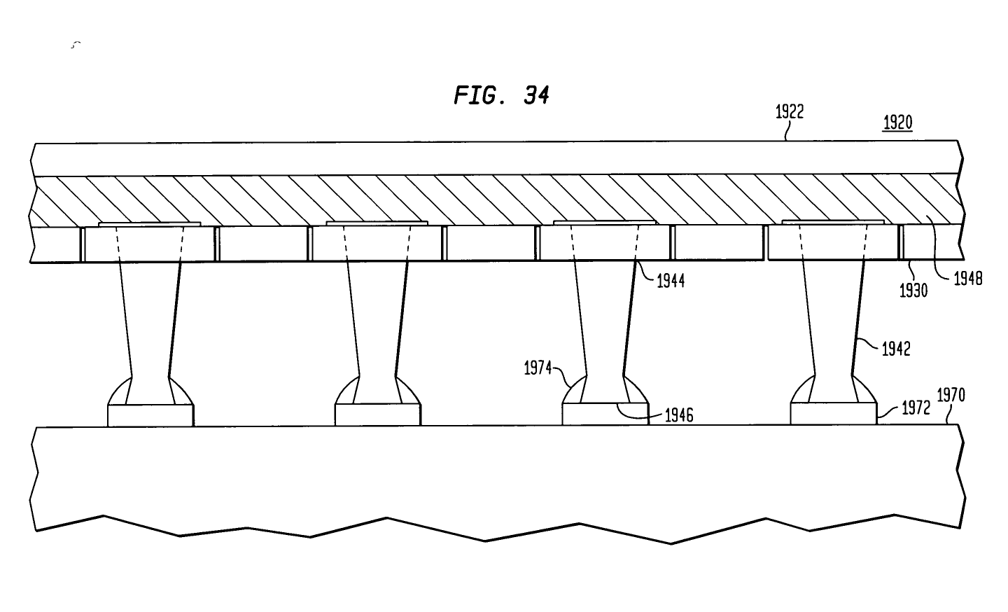

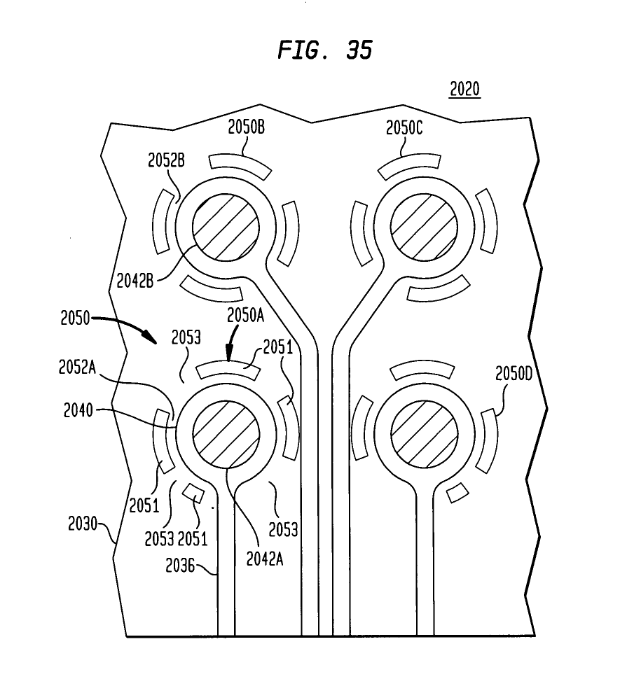

While the posts remain in contact with engagement with test board 1962, the microelectronic package 1920 is tested by applying signals and potentials such as power potentials and ground through the engaged posts 1942 and contact pads 1960. After testing, the package is separated from the test board 1962. The package then may be connected to a circuit panel such as a conventional circuit board 1970 (FIG. 34) by bonding the posts 1942 to the contact pads 1972 of the circuit board as, for example, by solder-bonding the tips 1946 of the posts to the contact pads. The solder may be applied to the posts or to the contact pads of the circuit board prior to assembly of the package with the circuit board, and reflowed using techniques and equipment commonly used in surface mounting. Most preferably, the solder forms fillets 1974 encompassing the tips 1946 of the posts. The posts reinforce the solder so as to form strong, reliable connections resistant to mechanical fatigue. During manufacture and during service, differential thermal expansion and contraction of the microelectronic element 1922 and the circuit board 1970 may tend to move contact pads 1972 relative to the microelectronic element. Preferably, in the completed assembly the tips 1946 can move to appreciably accommodate such relative motion and this limit stress on the solder bonds. Some of this relative motion may be provided by flexing of posts 1942. Also, the compliant layer 1948 and flexible substrate 1930 continue to allow the bases 1944 of the posts to move relative to the microelectronic element. Here again, the motion of the post bases may include both linear displacements and tilting as, for example, by bending of the flaps. The movement of the post bases 1944 may include movement of individual regions of the substrate, at least partially independently of movement of other regions of the substrate. In the completed assembly as well, the gaps, which effectively subdivide the substrate into independently movable regions, increase the movability of the post bases and increase the effective compliance of layer 1948.

Referring to FIG. 35, a microelectronic package 2020 in accordance with another preferred embodiment may have features similar to those discussed above with reference to FIGS. 32A-34. Thus, in the embodiment of FIG. 35, microelectronic package 2020 includes a flexible dielectric substrate 2030 having electrically conductive traces 2036, capture pads 2040 connected with traces 2036 and conductive posts 2042 connected with capture pads 2040. The flexible dielectric substrate 2030 has a plurality of gaps 2050 extending therethrough. A first gap 2050A is provided around first conductive post 2042A. The gap 2050A is intermittent, and incorporates multiple gap portions 2051 interspersed with webs 2053 of substrate material. Gap 2050A extends in a circular path at least partially about first conductive post 2042A. The first gap 2050A defines a first region 2052A that is distinct from remaining regions of the flexible dielectric substrate 2030. Substrate 2030 includes second gap 2050B surrounding second conductive post 2042B for defining a second region 2052B of the substrate. Similarly, the substrate 2030 includes third gap 2050C and fourth gap 2050D. In this embodiment as well, the substrate has plural gaps defining a plurality of distinct regions of the flexible substrate. Here again, one of the conductive posts is located in each such region. As a result, each conductive post is able to move independently of the other conductive posts. In this embodiment, the movement of the individual regions relative to the remainder of the substrate may include, for example, flexing of the webs 2053 as rather than the flap bending action discussed above. However, in this embodiment as well, subdivision of the substrate into individual regions enhances movability of the posts. For example, loads applied to the individual posts will be transmitted principally to localized regions of a compliant layer (not shown) disposed between the substrate and the microelectronic element, thereby increasing the effective compliance of the compliant layer.

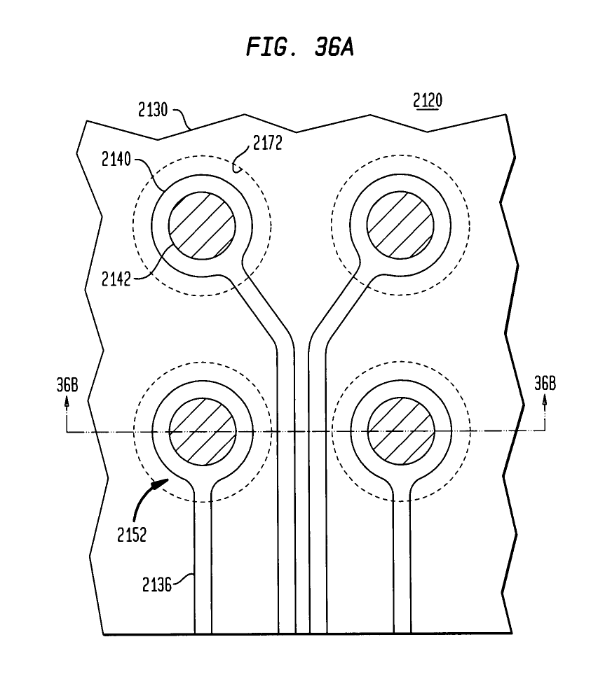

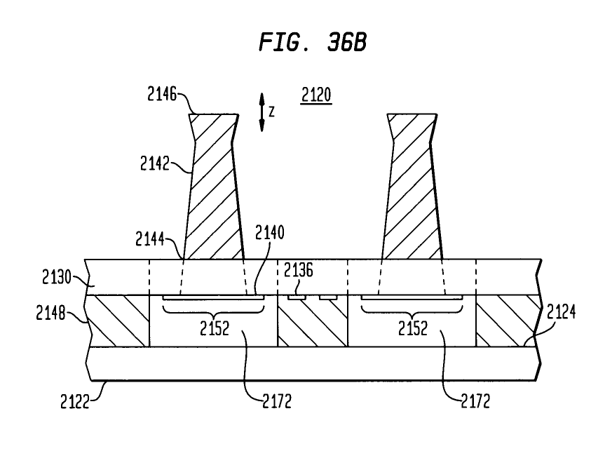

Referring to FIGS. 36A and 36B a microelectronic package 2120 in accordance with another embodiment of the present invention includes a microelectronic element such as a semiconductor chip 2122, a support layer 2148 overlying a front face 2124 of the semiconductor chip and a flexible dielectric substrate 2130 overlying the support layer 2148. The support layer may be compliant or rigid. The package further includes conductive posts 2142 mounted to the flexible dielectric substrate as described above with respect to FIGS. 32A and 32B. Here again, the conductive posts 2142 have bases 2144 physically connected to the substrate 2130 and have tip ends 2146 remote from the substrate. Each conductive post is attached to a capture pad 2140, which is electrically interconnected with a conductive trace 2136. In this embodiment, substrate 2130 does not include gaps as discussed above.

Support layer 2148 includes openings 2172 that are aligned with the respective bases 2144 of the conductive posts 2142. Openings 2172 in the compliant layer 2148 may be formed by etching, punching, laser or high-pressure liquid stream cutting of a continuous layer, or by forming the layer with the openings using a process such as molding or silk-screening of a curable material. Although the openings 2172 are depicted as extending entirely through the support layer 2148, this is not essential; the openings should be open to the surface of the support layer confronting the posts and flexible substrate, but need not be open to the opposite surface of the support layer, confronting the microelectronic element 2122. The alignment of the bases 2144 of the conductive posts 2142 with the openings 2172 facilitates movement of the conductive posts independently of one another. Thus, each post 2142 is disposed on a region 2152 of the substrate aligned with an opening 2172. Although these regions are not physically separated from the remainder of the substrate, each such region 2152 can deform by bowing or bending downwardly into the associated opening 2172. This type of deformation does not require deformation of other portions of the substrate 2130. Where the support layer 2148 has appreciable compliance, loads applied to an individual post 2142 may also cause some compression of those portions of the support layer surrounding openings 2172. Depending upon the compliance of the support layer and the properties of the substrate, some of the deformation caused by loads applied to one post may extend to or beyond the neighboring post. Nonetheless, the posts can still move independently of one another to a greater degree than would be the case without openings 2172. The openings materially increase the effective compliance of the system, as, for example, the motion imparted to a single post 2142 by application of a given load to such post.

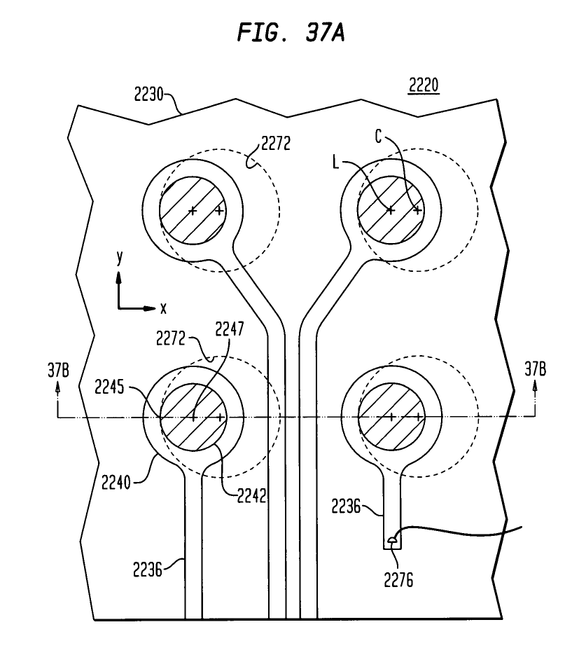

FIGS. 37A and 37B show a microelectronic package 2220 in accordance with another preferred embodiment of the present invention. The package includes a microelectronic element such as a semiconductor chip 2222, a support layer 2248 overlying the chip 2222 and a flexible dielectric substrate 2230 overlying the support layer 2248. The package includes conductive posts 2242 having bases 2244 and tip ends 2246. Each tip end includes a center 2274 defining a longitudinal axis L extending the length of the conductive post 2242. The base 2244 of post 2242 is connected by with a trace 2236. This package is generally similar to the package described above with reference to FIGS. 36A and 36B. However, in the package of FIGS. 37A and 37B, the base 2244 of each post does is not fully aligned with the opening 2272 extending through compliant layer 2248. Stated another way, the longitudinal axis L of the post is offset in a horizontal direction X from the center C of the associated opening 2272. A first or edge region 2245 of the conductive post base overlies the top surface of support layer 2248 and a second or central region 2247 of the post base overlies the opening 2272. However, the longitudinal axis L through the tip center 2274 is aligned with the opening 2272, and thus passes through central region 2247. During engagement with contact pads as, for example, in a testing operation as discussed with reference to FIG. 33B, vertical or Z-direction loads resulting from engagement of the post tips 2246 with the contact pads are applied generally along the axis L passing through the tip center and passing through the second or central region 2247 of the post base. This tends to push the second or central region 2247 of the post base, and the adjacent portion of substrate 2230, downwardly into opening 2272. However, the first or edge region 2245 of the post base is restrained to at least some degree against such downward movement by support layer 2248. As a result, the substrate in the vicinity of each post 2242 tends to bend about a horizontal axis in the vicinity of the post, so that the post tilts relative to the front face of the semiconductor chip 2222. In much the same way as explained above with reference to FIG. 33B, such deformation of the substrate allows the tip of each conductive post to move, substantially independently of the other posts, Z-axis direction as well toward microelectronic element 2222, and also provides wiping action in the horizontal or X direction.

In certain embodiments, the support layer 2248 between the flexible dielectric sheet 2230 and the semiconductor chip 2222 may be substantially rigid. Such a support layer provides particularly good conditions for bonding leads such as a wire bond 2276 to one or more of the traces 2236 on the flexible substrate. The relatively stiff support layer provides good support for forcible engagement of the wire bond with the trace.

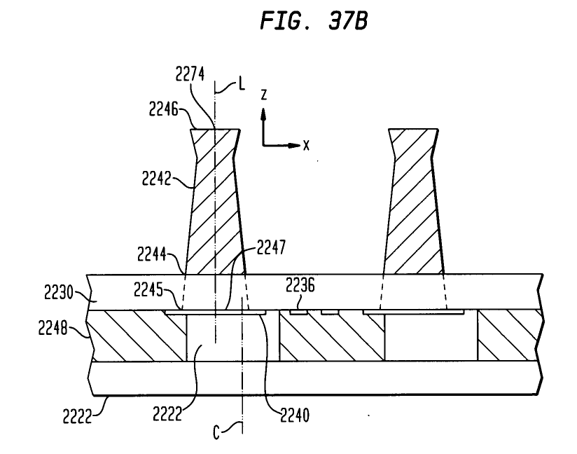

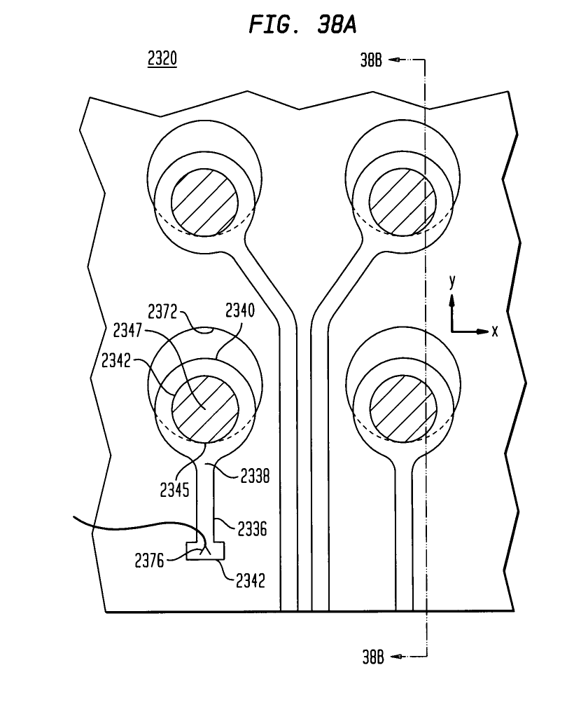

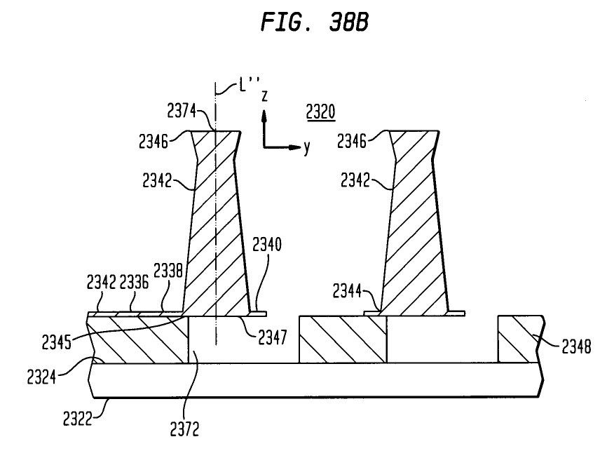

FIGS. 38A and 38B depict a microelectronic package 2320 including a microelectronic element such as a semiconductor chip 2322 having a contact-bearing face 2324 and a support layer 2348 overlying the contact-bearing face. The layer 2348 may be a compliant layer or may be substantially non-compliant. The microelectronic package includes conductive traces 2336 having post ends 2338 terminating at capture pads 2340 and posts 2342 and contact ends 2342 remote from the post ends. The package includes conductive posts 2342, each post having a base 2344 and a tip 2346 remote therefrom. In this embodiment, the traces 2336 and capture pads 2340, in conjunction with support layer 2348, serve as the physical mounting elements which hold the posts 2342.

In this embodiment as well, the tip of each post has a center point 2374 and a longitudinal axis L″ extends through the center, lengthwise along the post. Support layer 2348 has openings 2372 extending therethrough. The openings 2372 do not completely coincide with the capture pad 2340 and the base 2344 of conductive post 2342. Thus, in this embodiment as well, a first section 2345 of conductive post 2342 overlies layer 2348 and a second section 2347 of conductive post 2342 overlies opening 2372. Here again, the center point 2374 of tip 2346 and longitudinal axis L″ are aligned with opening 2372 of layer 2348. The post end 2338 of each trace forms a resilient hinge-like connection at the base 2344 of conductive posts 2342. The hinge-like connection enables the conductive posts to tilt action when the tip ends are abutted against opposing contacts. In this embodiment a flexible dielectric substrate is not required; the conductive posts and traces may be disposed directly atop layer 2348.

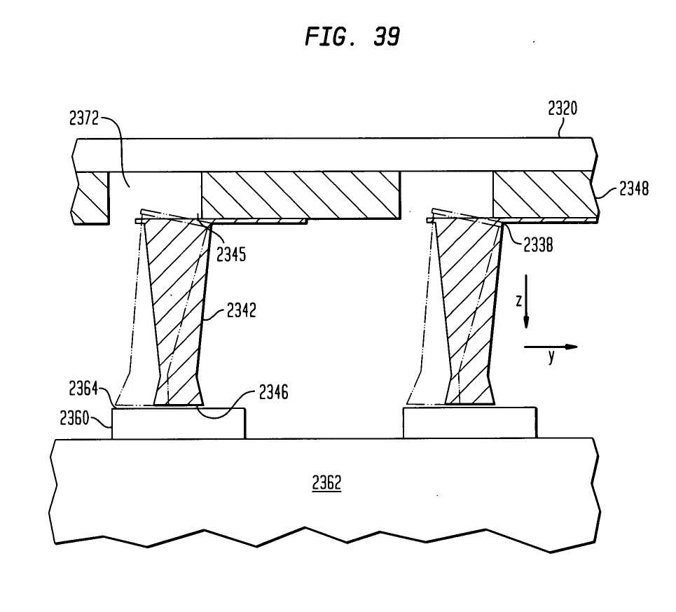

FIG. 39 shows the microelectronic package 2320 of FIGS. 38A and 38B during a testing operation. The microelectronic package 2320 is placed so that the tip ends 2346 of conductive posts 2342 are juxtaposed with top surfaces 2364 of contacts 2360 of a test substrate 2362. The microelectronic package 2320 is moved toward the test substrate in a direction indicated by axis Z until the tip ends 2346 engage the top surfaces 2364 of the contact 2360. Here again, engagement of the post tips with the contact surfaces 2364 causes the posts to tilt as shown in broken lines in FIG. 39, thus moving the tip of each post independently in the vertical or Z direction, and also providing some wiping motion in the Y direction. The microelectronic package as a whole may be moved relative to test substrate 2362 in the horizontal direction indicated by axis Y to provide additional wiping action.

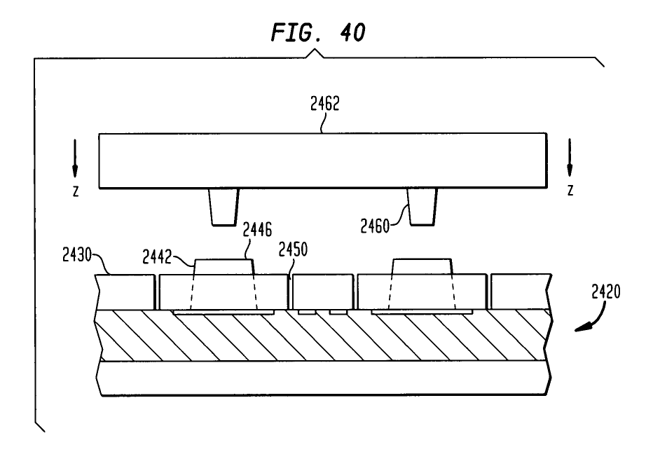

FIG. 40 shows a microelectronic package 2420 in accordance another embodiment of the present invention. The microelectronic package 2420 is substantially similar to that shown and described above in FIGS. 32A and 32B. However, the microelectronic package 2420 has conductive terminals 2442 in the form of generally planar pads rather than the elongated conductive posts described above. During testing, a second microelectronic element or test substrate 2462 having conductive probes 2460 may be juxtaposed with the conductive terminals 2442. During testing, the probes may be abutted against the top surface 2446 of the conductive terminals 2442. The gaps 2450 provided in flexible dielectric substrate 2430 enable each of the conductive terminals 2442 to move independently of one another in a Z direction for forming a more reliable electrical interconnection between the microelectronic package 2420 and the test board 2462. Similar flat pad terminals, and other types of terminals may be used in the other arrangements discussed above.

In the embodiments discussed above, the support structure that holds the terminals may tend to deform in a non-uniform manner so that the terminals tilt. However, it is not essential to provide discrete features such as the gaps and flap structures of FIGS. 32A-34 or the partially-aligned support layer of FIGS. 37A-39 in order to induce tilt in response to a vertically-directed contact force applied to the terminal. Merely by way of example, the support structure can include one or more layers of non-uniform compressibility or non-uniform stiffness, so that the vertical compliance of the support structure varies in horizontal directions. Provided that such non-uniformity causes the upwardly-directed reaction force applied by the support structure to the terminal to act a location horizontally offset from the line of action of the downwardly-directed contact force applied by the contact, the terminal will tend to tilt and provide the wiping action discussed above.

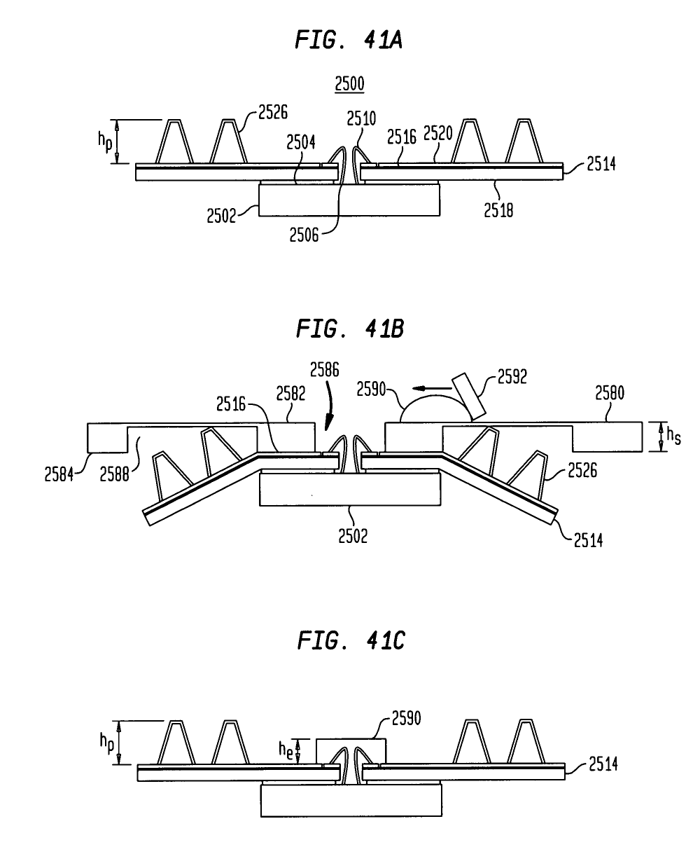

Referring to FIG. 41a in certain preferred embodiments of the present invention, a microelectronic assembly or package 2500 includes a microelectronic element such as a semiconductor chip 2502 having a front face 2504 with contacts 2506. The microelectronic assembly 2500 also includes a flexible substrate 2514 including a top surface 2516 and a bottom surface 2518 remote therefrom. The flexible substrate 2514 is preferably made from a dielectric material such as polyimide. The flexible substrate 2514 includes conductive traces 2520 extending over the top surface 2516 thereof. Conductive posts 2526 project from the top surface 2516 of the flexible substrate 2514. At least some of the conductive posts 2526 are electrically interconnected with the conductive traces 2516.

The assembly also desirably includes one or more wire bonds 2510 that are used for electrically interconnecting the chip contacts 2505 with the conductive traces 2516. As shown in FIG. 41a, the wire bonds 2510 have a profile height hₑ that is less than the height hₚ of the conductive posts 2526.

Referring to FIG. 41b, a stencil 2580 is placed atop the flexible substrate 2514. The stencil 2580 has a top surface 2582, a bottom surface 2584 and at least one opening 2586 extending therethrough. The stencil 2580 has a height hₛ that is less than the height hₚ (FIG. 41a) of the conductive posts 2526. The stencil 2580 is preferably stiffer or more rigid than the flexible substrate 2514. The stencil 2580 also preferably includes recesses 2588 formed in the bottom surface thereof 2584 for accommodating the conductive posts 2526. As shown in FIG. 41b, the stencil 2580 may be placed atop the microelectronic assembly 2500 so that the bottom surface 2584 of the stencil sits atop the top surface 2516 of the flexible substrate 2514. When the stencil 2580 is placed atop the substrate, the stencil pushes the array of conductive posts downwardly, thereby bending the substrate 2514 at the edges of semiconductor chip 2502. An encapsulating material 2590 is desirably stenciled into the opening 2586 using a tool 2592 such as a brush.

Referring to FIG. 41c, the encapsulant material 2590 may be cured and the stencil removed so that the flexible substrate 2514 may return to its normal unflexed configuration. The height of the encapsulant hₑ is preferably less than the height of the conductive posts hₚ.

In certain preferred embodiments of the present invention, microelectronic assemblies include an array of conductive posts or pins attached to a film or mechanical structure for permitting the pins a controlled degree of freedom in the direction of the long axis of the post. The conductive posts provide a structure for making electrical interconnections with conductive pads on a printed circuit board so as to accommodate a certain degree of non-planarity on the printed circuit board or the part to which the conductive posts are attached.

There are at least two methods of making conductive posts on a structure. One method is to use a plating process to build up the parts through apertures in a mask. The core of the conductive post is preferably made of copper having a surface finish of nickel then gold to render the post solderable and resistant to corrosion from oxidation. A further finishing operation may be necessary to correct for varying height between the posts so that all of the posts are substantially the same height.

An alternative method of forming conductive posts is to form the copper core of the posts by etching from a solid sheet. In this particular embodiment, the sheet is attached to a substrate and the outer surface of the copper sheet is masked to protect the ends of what will become the posts. Copper is removed by a chemical etching process and the pins are then covered with nickel and gold.

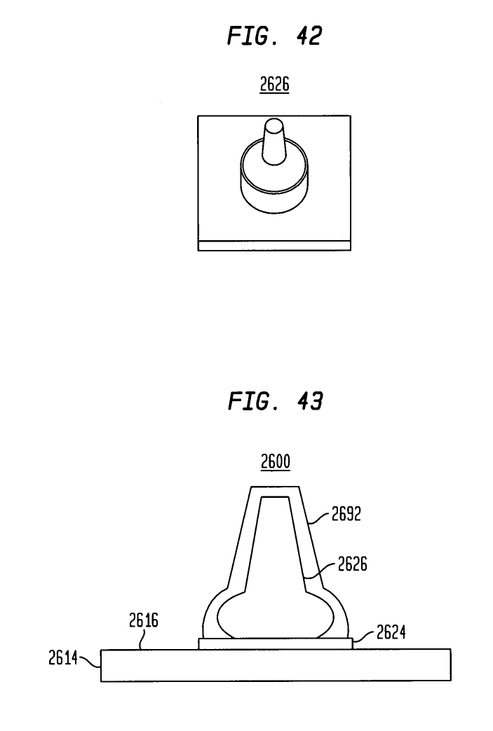

Referring to FIGS. 42 and 43, in accordance with one preferred embodiments of the present invention, one or more conductive posts are formed from stud bumps. Stud bumping is a well-known method of creating conductive protrusions, which has the advantage that stud bumps may be produced individually using a numerically controlled machine. Thus, the tooling is referred to as “soft,” which means that changing the relative location of the stud bumps on different jobs merely requires alteration of the software controlling the machine. FIG. 42 shows a perspective view of a conductive post 2626 that has been formed using a stud bumping process. FIG. 43 shows a cross-sectional view of the stud bump 2626 shown in FIG. 42. The stud bump 2626 is formed atop a microelectronic assembly 2600 including substrate 2614 having a top surface 2616 and a contact pad 2624 formed thereon. The conductive post 2626 is formed atop the contact pad 2624 using a stud bumping process. A nickel/gold coating 2692 is then deposited over the core of the conductive post 2626.

In certain preferred embodiments, the preferred height of the conductive posts is in the region of 50-300 microns. A number of technologies exist for achieving conductive post of this height, including control of the ball size and tail height through variation of the stud bump machine parameters, modification of the tail shape by changing the profile of the bore of the capillary and vertical stacking of multiple stud bumps.

Stud bumps may be formed from a variety of metals. Gold is the most common metal, however, copper, silver, aluminum and platinum stud bumps may also be utilized. Gold and platinum stud bumps do not oxidize and can therefore be used, as formed, to make electrical connections to the conductive pads on a printed circuit board or other microelectronic component. Gold stud bumps may be thermo-compression welded to achieve a permanent connection to a mating surface. Platinum, silver and copper stud bumps may also be connected by soldering. All five metals may also make electrical interconnection using conductive adhesives and anisotropically conductive films. Copper and silver stud bumps are likely to oxidize if left exposed to atmosphere, which makes electrical contacts unreliable and soldered or adhesively bonded connections of variable quality. Aluminum stud bumps will also oxidize. It is therefor likely that the copper, silver and aluminum stud bumps will be coated with protective layers of nickel and gold. The aluminum pins may require an additional zincate strike layer underneath the nickel layer.

To render the gold stud bumps compatible with solders, stud bumps are preferably coated with nickel then gold. Although platinum does not oxidize and is compatible with solders, it too is preferably coated with at least a layer of gold. Thus, irrespective of the core metal of the stud bumps, the stud bump is preferably finished with a layer of nickel, then gold. In certain preferred embodiments, the nickel layer is around five microns thick and the gold layer is around 0.5 microns thick. These metals can be applied at these thicknesses using a low cost method of electroless plating.

In the preferred embodiment shown in FIG. 43, the nickel layer strengthens the stud bumps and decreases their susceptibility to mechanical damage. Electroless plating obviates the need for the stud bumps to be connected to a common potential, as is the case for an electroplating process, although electroplating could be used by appropriate design of the wiring traces to which the stud pads on the substrate are connected.

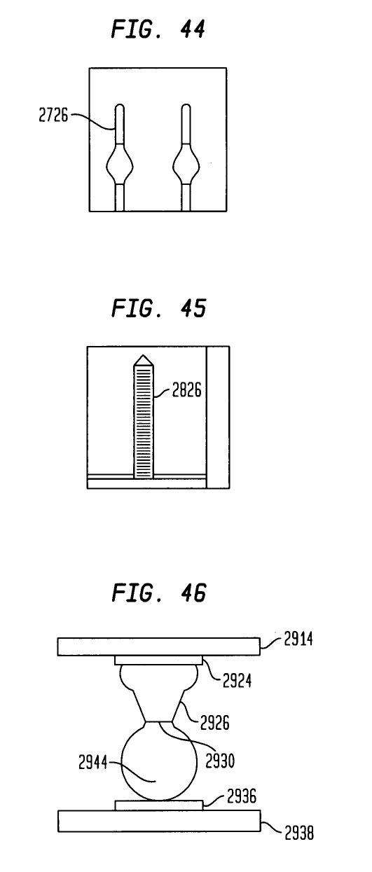

Referring to FIG. 44, in certain preferred embodiments of the present invention, a conductive post 2726 is formed using a stud bumping process. The tail height of the stud bump is controlled by varying the parameters of a stud-bumping machine. The tail shape and height of the stud bump may be modified, such as by changing the profile of the bore of the capillary.

Referring to FIG. 45, in another preferred embodiment of the present invention, conductive posts 2826 may be formed by vertically stacking a plurality of stud bumps one atop another. The stacking of the plurality of stud bumps enables the final height of the conductive post to be accurately controlled. The core of the conductive post may be covered with a non-oxidizing or noble metal such as gold.

Referring to FIG. 46, a microelectronic assembly includes a substrate 2914 having one or more conductive posts 2926 projecting therefrom. Each conductive post preferably sits atop a conductive pad 2924 provided on the substrate 2914. In order to form an electrical interconnection with a printed circuit board 2938 having conductive pads, a solders sphere 2944 is positioned atop one of the conductive pad 2936. In certain preferred embodiments, the solder sphere is held in place using flux. The tip end 2930 of the conductive post 2926 is abutted against the solder sphere 2944 and, while maintaining alignment, the solder sphere is reflowed. After reflow, the solder sphere 2944 is cooled for forming a permanent electrical interconnection between the conductive post 2926 and the contact pad 2936 on the printed circuit board 2938.

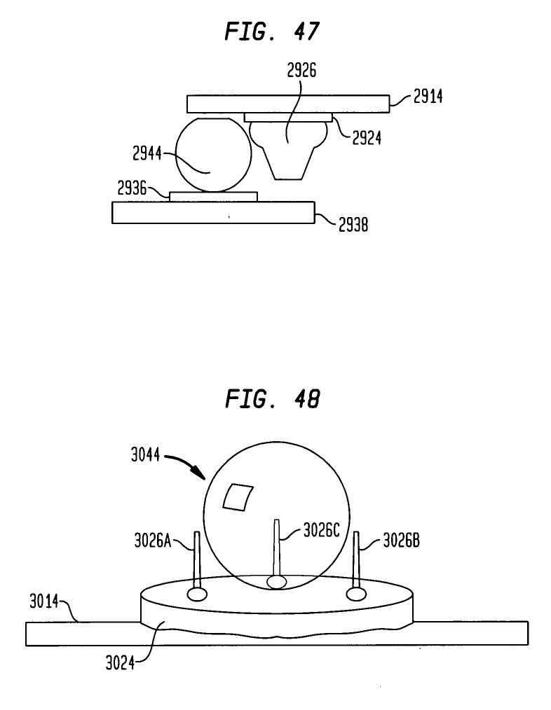

FIG. 47 shows the components of FIG. 46 including substrate 2914 having a conductive land 2924 and a conductive post 2926 projecting therefrom. The substrate 2914 is juxtaposed with a printed circuit board 2938 having conductive pads 2936. A solders sphere 2944 is desirably positioned atop the conductive pad 2936 and held in place using flux (not shown). The conductive post is placed to the side of the solders sphere 2944. The solder sphere 2944 is desirably reflowed, whereby the conductive post 2926 is pulled toward a center of the conductive pad 2936 by tension forces. The reflowed solder is preferably cooled for forming a permanent electrical interconnection between the substrate 2914 and the printed circuit board 2938.

Referring to FIG. 48, in accordance with another preferred embodiment of the present invention, more than one conductive post may be provided atop a conductive land on a substrate. As shown in FIG. 48, substrate 3014 includes one or more conductive lands 3024 provided thereon. Three spaced conductive posts 3026a, 3026b and 3026c are formed atop the conductive land 3024. The three conductive posts are preferably equally spaced from one another atop the conductive land 3024. In other preferred embodiments, multiples of two or more conductive posts may be used (e.g. four spaced conductive posts). The conductive posts 3026 may be formed using any of the processes described above. Such conductive posts may have a height to diameter ratio of greater than 5 to 1 and more preferably greater than 10 to 1. In even more preferred embodiments, the conductive posts may have a height to diameter ratio of 20 to 1 or more. As shown in FIG. 48, a single solder sphere 3044 is received within a receptacle formed by the three spaced conductive posts 3026a-3026c. As a result, the solders sphere 3044 can be accurately placed on the substrate 3014 using what is commonly referred to as a ball-drop technique. The spaced conductive posts hold the solder ball in place prior to reflow. Although the present invention is not limited by any particular theory of operation, it is believed that using spaced conductive posts atop a single conductive pad or land greatly improves the assembly process by obviating the need to balance the tip of a conductive posts on a single solder sphere or off set the post to the spheres as shown in FIG. 47.

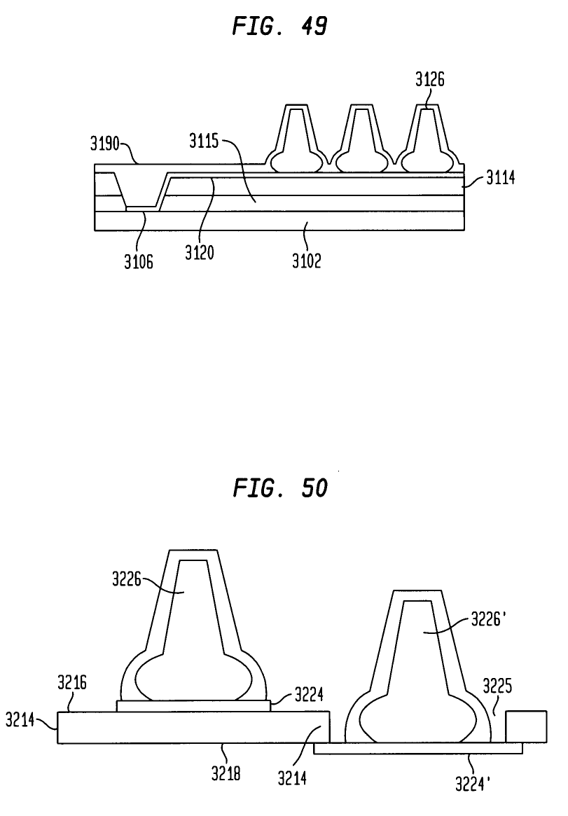

FIG. 49 shows a plurality of conductive posts 3126 assembled to a wafer 3102. The wafer 3102 includes an active surface having contacts 3106. A substrate 3114 is attached to the wafer 3102 using an adhesive 3115. The substrate 3114 has conductive traces 3120 extending over a surface thereof. The conductive traces 3120 are electrically interconnected with the contacts 3106. A dielectric layer 3190 may be formed over the conductive traces 3120 and the top surface of the substrate 3114. The conductive posts 3126 are preferably electrically interconnected with the conductive traces 3120 and project from a top surface of the substrate 3114. The conductive posts may be formed using the stud bumping process described above.

FIG. 50 shows a flexible substrate 3214 having a top surface 3216 with conductive pads 3224 formed thereon. The substrate also desirably includes an opening 3225 extending between the top surface 3216 and the bottom surface 3218. A second conductive pad 3224′ is accessible through the opening 3225. A first conductive post 3226 is formed atop the first conductive pad 3224 and a second conductive post 3226′ is formed atop the second conductive pad 3224′. The first conductive post 3226 is commonly referred to as being part of a “circuit out” assembly and the second conductive post 3226 is commonly referred to as being part of a “circuit in” assembly.

FIG. 51 shows a microelectronic assembly 3300, in accordance with another preferred embodiment of the present invention. The microelectronic assembly includes a semiconductor die 3302 having a top surface 3304. A flexible support layer 3314 is provided over the top surface 3304 of the semiconductor die 3302. A plurality of conductive posts 3326 is formed atop the substrate 3314. Support elements 3310 space the substrate 3314 from the chip 3302 and support the substrate 3314 over the chip 3302. Although the present invention is not limited by any particular theory of operation, it is believed that placing the support elements 3310 between the conductive posts 3326 provides mechanical compliance to permit the posts to move in vertical directions relative to the top surface 3304 of the semiconductor chip 3302. In certain preferred embodiments, the substrate 3314 is circuitized and the support elements 3310 are conductive elements that electrically interconnect the conductive post 3326 and one or more contacts on the semiconductor chip 3302.

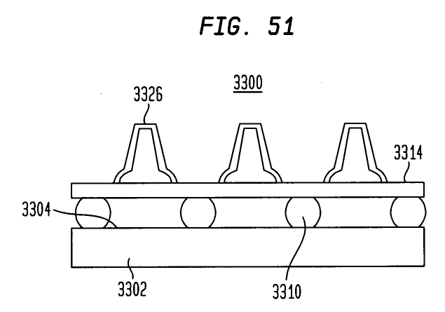

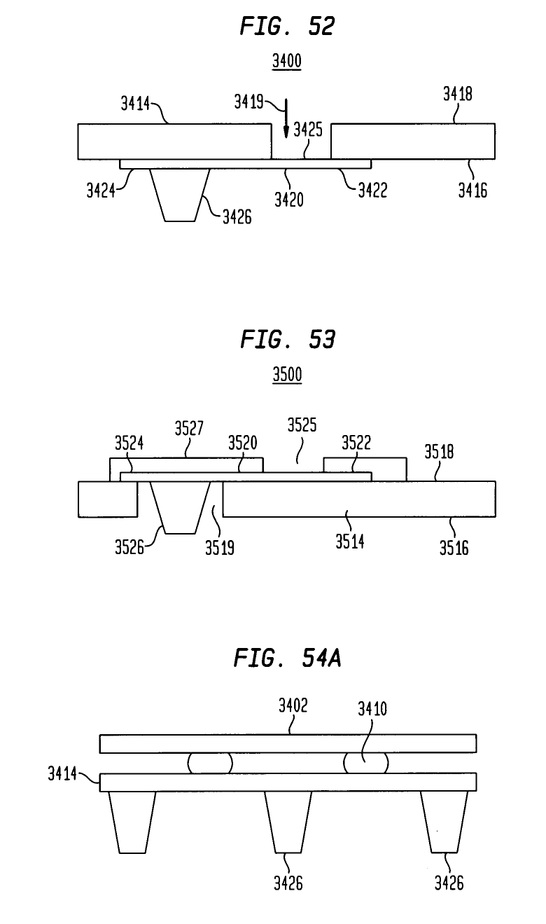

FIG. 52 shows a “circuit-in” microelectronic assembly in accordance with another preferred embodiment of the present invention. The assembly desirably includes a flexible dielectric film 3414 having a first surface 3416 and a second surface 3418 remote therefrom. The substrate 3414 is preferably made of a dielectric material such as polyimide. The substrate 3414 has at least one aperture 3419 extending between first surface 3416 and second surface 3418. The microelectronic assembly also desirably includes a conductive wiring trace 3420 having a first end 3422 and a second end 3424. The second end 3424 of conductive trace 3420 includes a conductive land 3425 that is in alignment with the aperture 3419 extending through substrate 3414. The microelectronic assembly 3400 also includes one or more conductive posts 3426 electrically connected to second end 3424 of conductive trace 3420. The conductive post 3426 projects away from the first surface 3416 of the substrate 3414. As noted above, the microelectronic assembly 3400 shown in FIG. 52 is a “circuit-in” assembly, whereby the conductive traces 3420 are on the same side of the substrate 3414 as the conductive posts 3426. Thus, the conductive land 3425 is accessible through aperture 3419 in the substrate 3414.

FIG. 53 shows a microelectronic assembly 3500 in accordance with another preferred embodiment of the present invention having a “circuit-out” configuration. The microelectronic assembly 3500 includes a flexible substrate 3514 such as a dielectric film having a first surface 3516 and a second surface 3518 remote therefrom. The substrate 3514 has one or more apertures 3519 extending from the first surface 3516 to the second surface 3518. The microelectronic assembly 3500 includes a conductive trace 3520 overlying the second surface 3518 of the substrate 3514. The conductive trace 3520 has a first end 3522 and a second end 3524. A solder mask 3527 is deposited over the second surface 3518 of the substrate 3514 and the conductive trace 3520. The solder mask 3527 includes an aperture for defining a conductive land 3525 on the conductive trace 3520. The microelectronic assembly 3500 also includes one or more conductive pins 3526 that are electrically interconnected with the second end 3524 of conductive trace 3520. The FIG. 53 arrangement is described as a “circuit-out” assembly because the conductive trace 3520 and the conductive land 3525 are located on the same surface 3518 of the flexible substrate 3514, with the conductive land 3525 being defined by the solder mask 3527.

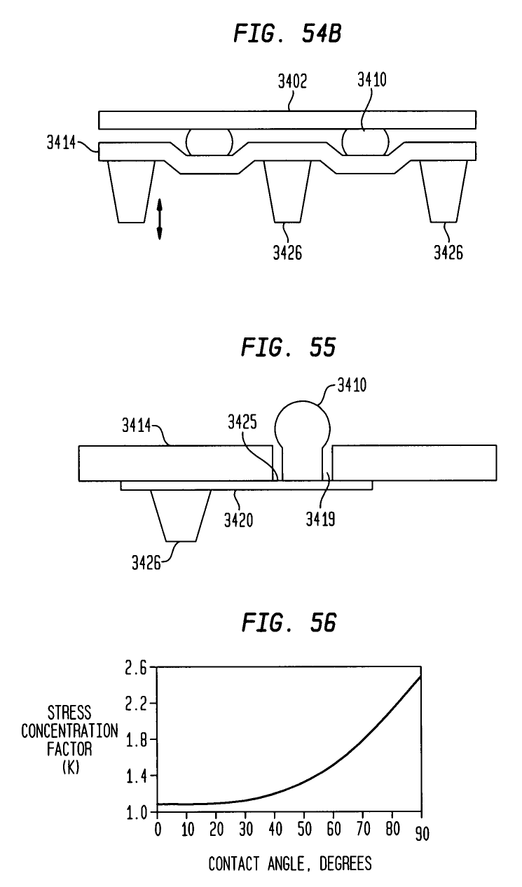

Referring to FIG. 54A, the microelectronic assembly 3400 of either FIG. 52 or FIG. 53 is assembled with a semiconductor chip 3402 to form a microelectronic package. The package includes semiconductor chip 3402, flexible substrate 3414 and conductive posts 3426. The contacts of the semiconductor chip 3402 are electrically interconnected with the conductive posts 3426 using conductive support elements 3410. In certain preferred embodiments, some of the support elements may be non-conductive.

FIG. 54B shows the microelectronic package of FIG. 54A, whereby the conductive posts 3426 are moveable relative to the front face of the semiconductor die 3402. The semiconductor chip 3402 is spaced from the flexible substrate 3414 by the conductive support elements 3410. The conductive posts 3426 are not in alignment with the conductive support elements 3410. As a result, the conductive posts 3426 are free to move relative to the die. In preferred embodiments, the posts are free to move in at least five orthogonal directions (i.e. up-down, forward-back, left-right, pitch and roll). The compliance of the conductive posts relative to the die facilitates making temporary electrical connections to the semiconductor chip for the purposes of electrical tests and burn-in, and also aids in the durability of the interconnects in service when the package is permanently connected (e.g., soldered) to another electronic elements such as a printed circuit board.

Although the trampoline structure shown in FIGS. 54A-54B provides a desirable degree of compliance for the conductive posts 3426, it renders the interface between the conductive support elements 3410 and the conductive lands 3425 (FIG. 52) vulnerable to premature failure through fatigue. This phenomenon arises due to the forces present at the junction between the conductive support elements and the flexible circuit, particularly when the latter is provided on a “circuit-in” assembly. This problem is shown in FIG. 55, whereby the microelectronic assembly includes substrate 3414 having aperture 3419, conductive trace 3420 with conductive land 3425 and conductive post 3426 attached to the conductive trace 3420. The conductive support element 3410 is typically unable to wet to the dielectric material of the substrate 3414. As a result, the conductive support element 3410 is forced to adopt an unnaturally high contact angle, without a fillet. It is well known to those skilled in the art that low contact angles and fillets at the periphery of solder joints boost the mechanical robustness through decreasing the stress concentration factor in that region. For example, referring to FIG. 56, under the same load, a joint with a contact angle of 90° experiences a stress concentration at its edge that is nearly 2.5 times greater than the stress concentration at a joint having a contact angle of less than 30°.

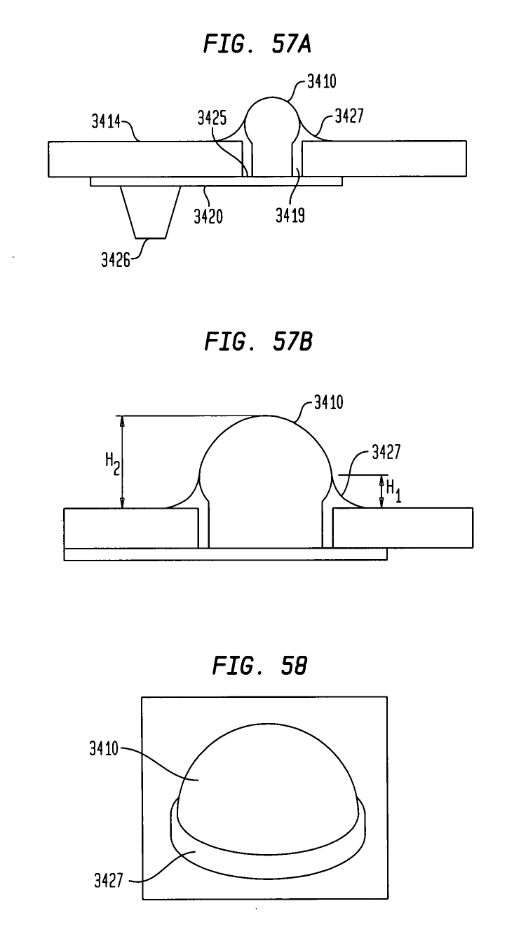

Referring to FIG. 57A, in order to minimize the effects of the stress at the joint, a polymeric material forming a polymer fillet 3427 is provided between the conductive support element 3410 and the dielectric substrate 3414. As shown in FIG. 57A, the dielectric substrate 3414 has an aperture 3419 with conductive land 3425 being accessible through the aperture 3419. The polymer fillet 3427 is disposed within the aperture 3419 and surrounds the base of the conductive support element 3410. As a result, the polymer fillet 3427 forms a low contact angle with the dielectric material of the flexible substrate 3414 and adheres strongly to both the dielectric substrate 3414 and the outer surface of the conductive support element 3410. The polymeric material fills the gap between the conductive support element and the dielectric substrate.

FIG. 58 shows a perspective view of the polymer fillet 3427 surrounding the conductive support element 3410. Although the present is not limited by any particular theory of operation, it is believed that the polymeric material 3427 not only forms an external fillet, but fills the gap 3419 between the solder 3410 and the openings in the dielectric substrate 3414. The cured polymer fillet therefore binds these parts of the structure together and decreases the level of stress at the joint between the solder and the land 3425.

Referring to FIG. 57B, the viscosity and surface tension of the polymer fillet 3427 are preferably controlled so that the cured polymer rises to a height H₁ of between ⅓ and ½ of the exposed height of the conductive sphere 3410.

In certain preferred embodiments, a measured quantity of polymeric material is applied to each conductive land. A solder ball drop process is then used to place a single solder sphere at each location. As the polymeric material holds the solder sphere in place, the subassembly is subjected to a solder reflow cycle. The particular formulation of the polymeric material is chosen so that as the temperature increases and the viscosity of the polymeric material decreases, the solder sphere drops through the polymeric material under the influence of gravity. When the temperature of the subassembly reaches the melting point of the solder, the solder material is in contact with the conductive land and is able to wet to and spread over the conductive land, without being impeded by the polymer material.

In certain preferred embodiments, the polymeric material is preferably slightly acidic in nature and acts as a temporary barrier to the through-diffusion of oxygen. These characteristics, coupled with the ready displacement of the polymeric material by the molten solder are the attributes of a flux. Thus, by design, the polymeric material used to reinforce the solder interconnect also fluxes the attachment of the solder spheres to the flexible circuit. The ability to dispense with conventional fluxes for this stage of processing means that the associated flux application and removal processes are obviated.

In certain preferred embodiments, the polymeric material includes a thermoplastic material. This is because the prepared microelectronic package including the flexible circuit is designed to be attached to a component by reflow of the solder spheres. Such an operation will result in a change to the shape of the solder from spheres to a more columnar profile because the molten metal is now wetted to two opposing planar surfaces.

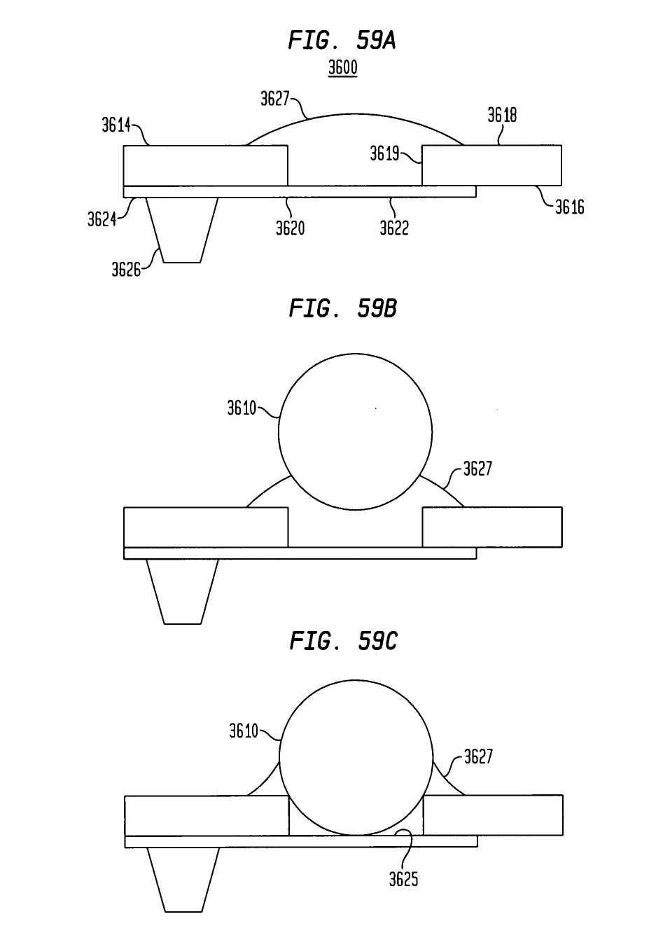

A process for connecting a conductive support element to a circuitized substrate is shown in FIGS. 59A-59C. Referring to FIG. 59A, a microelectronic element 3600 includes a flexible dielectric substrate 3614 having a first surface 3616 and a second surface 3618 remote therefrom. The flexible substrate 3614 includes at least one aperture 3619 extending therethrough. The microelectronic element 3600 also includes conductive traces 3620 having first ends 3622 in alignment with apertures 3619 and seconds ends 3624 supporting conductive posts 3626. A polymeric material 3627 is disposed within conductive traces 3620 having first ends 3622 in alignment with apertures 3619.

Referring to FIG. 29b, a solder sphere 3610 is deposited atop the polymeric material 3627. The solder sphere 3610 is held in place by the viscous polymeric material 3627. Referring to FIG. 29, the assembly is then heated for reducing the viscosity of the polymeric material 3627. Upon heating of the polymeric material 3627, the solder sphere 3610 drops through the polymeric material for allowing the solder sphere 3610 to contact the conductive land 3625.

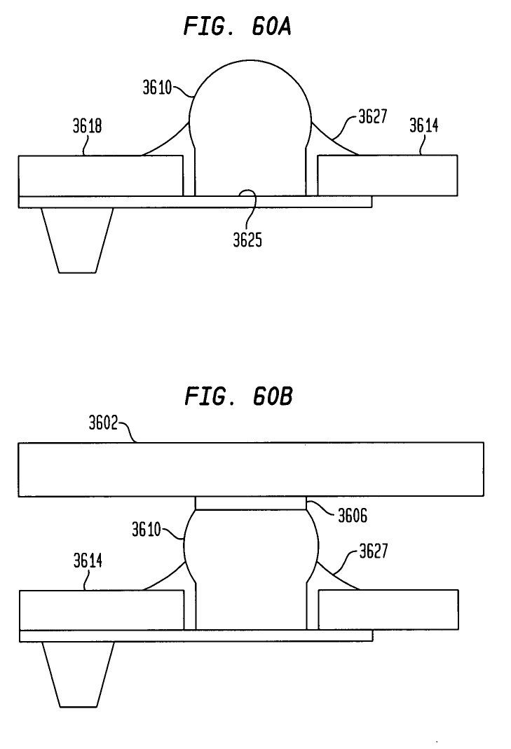

Referring to FIG. 60a, the solder 3610 reflows and wets to the conductive land 3625, but not to the substrate 3614. The polymeric material 3627 fills the gap between the dielectric substrate 3614 and the solder material 3610. The polymeric material 3627 also forms a surface fillet over the second surface 3618 of the flexible substrate 3614.

Referring to FIG. 60b, the microelectronic assembly is then interconnected with a second microelectronic element 3602 having contacts 3606. The solder 3610 wets to the contact 3606 on the second microelectronic component 3602. The polymeric material 3627 readjusts shape to enable the solder 3610 to change shape, while remaining adhered to the solder and the dielectric substrate 3614. In certain preferred embodiments, the structure shown in FIG. 60a-60b could also be used with flexible circuit having a “circuit-out” configuration (FIG. 53). However, in those particular embodiments, the benefits are not as significant because the solder is naturally able to form a low contact angle to the land, and there are no vertical features in the structure.

Nevertheless, the polymeric material does assist in retaining the solder spheres in location prior to reflow, eliminates the need for a separate flux and provides a low and consistent contact angle between the interconnect and the flexible circuit. One suitable polymeric material for use is polyurethane mixed with an organic thixotrope to provide the desired rheological characteristics.

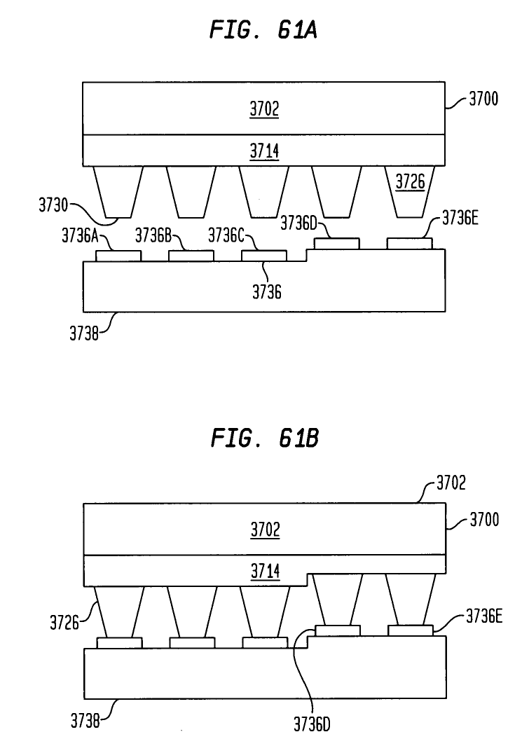

FIG. 61a shows a microelectronic package 3700 including a semiconductor chip 3702, a compliant layer 3714 and conductive posts 3726 projecting from the compliant layer. The compliant layer may include a flexible substrate and an encapsulant. The conductive posts 3726 preferably have the same length and preferably have tips 3730 that are at the same distance from the compliant layer 3714. The microelectronic package 3700 is juxtaposed with a printed circuit board 3738 having conductive pads 3736. Three of the conductive pads 3736a-3736c have top surfaces that lie in a different plane than two of the conductive pads 3736d and 3736e.

Referring to FIG. 61b, the microelectronic package 3700 is abutted against the printed circuit board 3738 so that the conductive posts 3726 are able to contact the contact pads 3736 on the printed circuit board. The compliant layer 3714 in the region aligned with conductive posts 3736d and 3736e is compressed so that all of the conductive posts are in contact with the opposing conductive pads. The compliant layer 3714 enables the conductive posts to move relative to the semiconductor chip 3702. As a result, a reliable electrical interconnection may be formed between all the conductive posts 3726 and all of the conductive pads 3726.

Many of the embodiments described above disclose conductive posts that are attached to a compliant material and/or structure. In certain instances, however, this “compliant” design may be undesirable because of costs, component design, wiring trace layout or thermal performance.

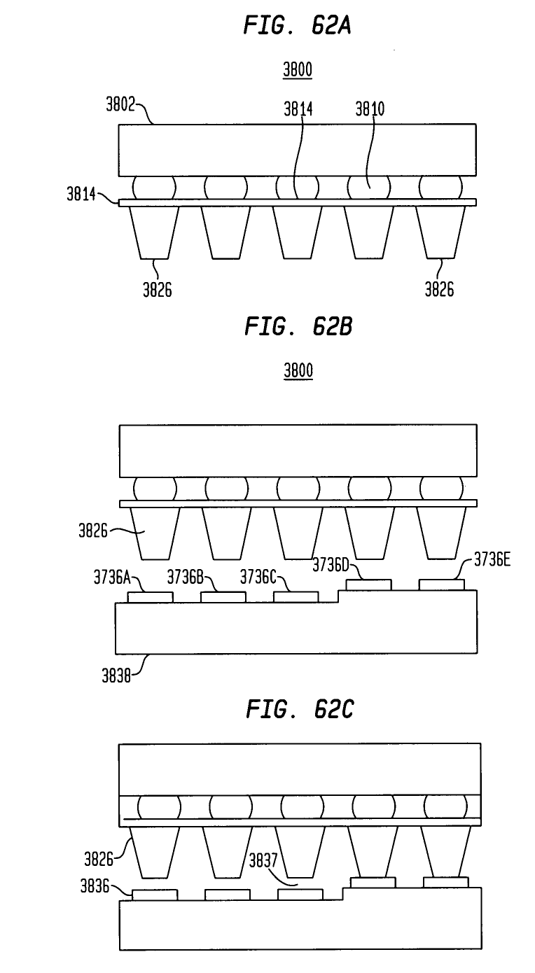

Referring to FIG. 62a, a microelectronic package 3800 may include a semiconductor chip 3802 juxtaposed with a flexible dielectric substrate 3814 having conductive posts 3826 attached thereto. The microelectronic package 3800 includes conductive support elements such as solder spheres 3810 used for supporting substrate 3814 over a contact bearing face of a semiconductor chip 3802. The solder spheres 3810 may also electrically interconnect the contacts (not shown) of the semiconductor chip 3802 and the conductive posts 3826 of the flexible substrate 3814.

Referring to FIG. 62b, the microelectronic package 3800 is place in alignment with the contacts 3836 of an opposing printed circuit board 3838. Due to non-planarities, the first three conductive pads 3836a-3836c are not in the same plane as the forth and fifth conductive pads 3836d and 3836e. During assembly, the conductive posts 3826 are placed in alignment with the opposing conductive pads 3836. Referring to FIG. 62c, due to the non-planarity of the contacts 3836, some of the conductive posts 3826 do not come in contact with some of the conductive pads 3836. Thus, a gap 3837 may extend between some of the conductive posts 3826 and some of the conductive pads 3836.

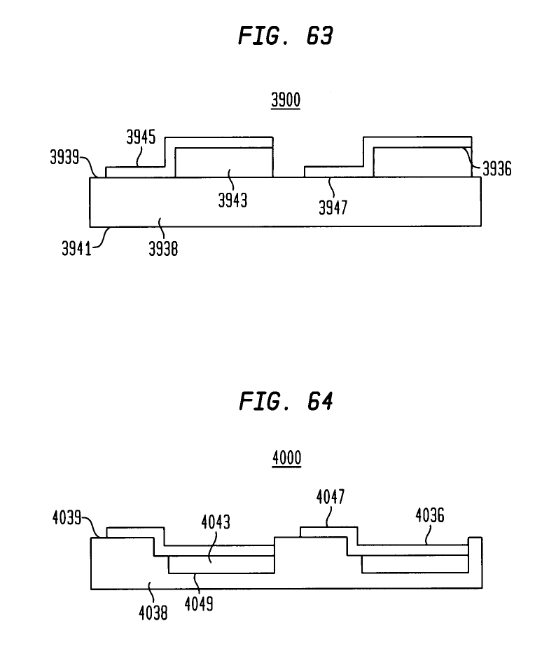

In order to avoid the non-planarity problem shown above in FIG. 62c, in certain preferred embodiments, the substrate or printed circuit board includes compliant conductive pads that overlie an elastomeric material. The compliant conductive pads are preferably able to accommodate planar mismatch between the conductive posts and the conductive pads. As shown in FIG. 63, a microelectronic assembly 3900 includes a substrate 3938 having a top surface 3939 and a bottom surface 3941 remote therefrom. The microelectronic assembly 3900 includes elastomeric pads 3943 that are formed over the first surface 3939 of the printed circuit board 3938. A metal layer 3945 is desirably deposited over the elastomeric pads 3943 and a portion of the first surface 3939 of the substrate 3941. The conductive metal layer 3945 forms conductive traces 3947 that are in electrical contact with conductive pads 3936. In certain preferred embodiments, the elastomeric material is a polyimide. In other preferred embodiments, the elastomeric material may be a compliant material having a low modulus, a large elastic range and high temperature stability. The thickness of the elastomeric pads 3943 is preferably as thin as possible because of the desire to minimize the thickness of the assembly. In certain preferred embodiments, the elastomeric pads may include a foam having air pockets therein for decreasing the modulus of the material.

FIG. 64 shows a microelectronic assembly 4000 that functions in similar way as the structure shown in FIG. 63. However, the structure in FIG. 64 has the compliant pads formed in recesses provided on a top surface of a substrate 4038. As shown in FIG. 64, the substrate 4038, such as a printed circuit board, has one or more recesses 4049 formed in a top surface thereof. The recesses are filled with a compliant material 4043, such as the elastomeric material described above. A layer of conductive metal is deposited over the compliant pads 4043 and a portion of the top surface 4039 of substrate 4038. The metal layer forms conductive pads 4036 overlying the compliant material 4043 and conductive traces 4047 electrically interconnected with the conductive pads 4036.

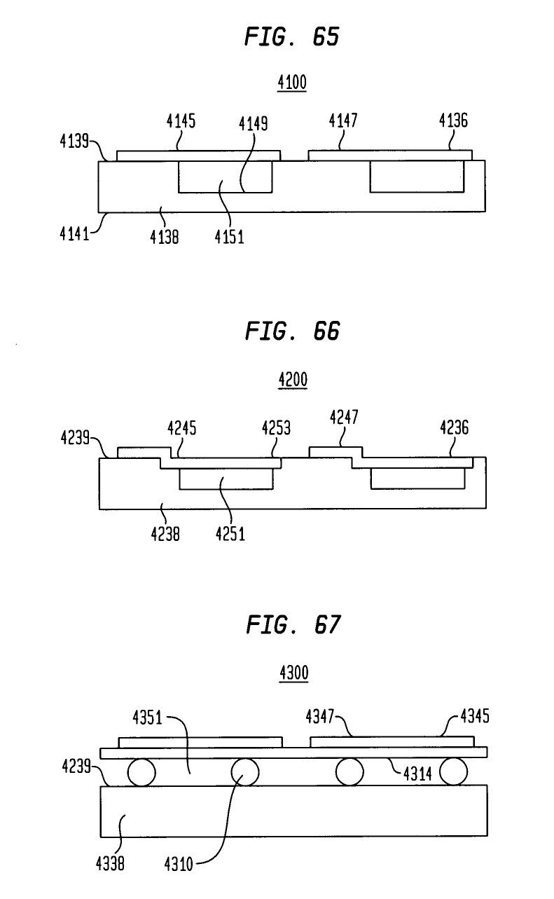

FIG. 65 shows a microelectronic assembly 4100, in accordance with another preferred embodiment of the present invention. The assembly 4100 includes a substrate 4138 including a top surface 4139 and a bottom surface 4141 remote therefrom. The top surface 4139 of the substrate 4138 has recesses 4149 formed therein. The recesses form air pockets 4151 within the interior of substrate 4138. A conductive metal 4145 is deposited over the top surface 4139 of the substrate 4138. The conductive metal 4145 includes conductive pads 4136 overlying the air gaps 4151 and conductive traces 4147 overlying the top surface 4139 of the substrate 4138. Due to the air pockets 4151 underneath the conductive lands 4136, the lands are movable relative to the substrate for accommodating non-planarities with opposing tip ends of conductive posts.

FIG. 66 shows a microelectronic assembly 4200, in accordance with another preferred embodiment of the present invention. The microelectronic assembly includes a substrate 4238 having recesses formed in a top surface thereof to define air gaps or air pockets 4251. The top surface of the substrate also defines shelves 4253 that bound the pockets 4251. A conductive metal layer 4245 is deposited atop the first surface 4239 of the substrate 4238. The metal layers include conductive lands 4236 and conductive traces 4247 connected to the lands. Due to the air gaps 4251 below the conductive lands 4236, the conductive lands are able to move relative to the substrate for accommodating non-planarities and thermal cycling mismatch.

FIG. 67 shows another preferred embodiment whereby a microelectronic assembly 4300 includes a printed circuit board 4348 having top surface 4339 and support elements 4310 for supporting a flexible substrate 4314 over the first surface 4339. The supports element 4310 may be conductive support elements such as solder balls. The support elements may also be made of any of the components described above for supporting a flexible substrate over the substrate 4338. The printed circuit board also desirably includes one or more conductive metal layers 4345 deposited over the flexible substrate 4314. The metal layers define conductive traces 4347. The support elements 4310 are spaced from one another so that air pockets 4351 lie between the support elements 4310 and the opposing faces of the printed circuit board 4348 and the flexible substrate 4314. The air pockets 4351 enable the metal layer 4345 and the flexible substrate to move relative to the first surface 4339 of the substrate 4348 so as to accommodate non-planarities.

The microelectronic assemblies shown in FIGS. 65, 66 and 67 are designed to provide a structure for connecting an array of conductive lands with an array of conductive posts. In certain preferred embodiments, the printed circuit board may be a test or burn-in board. In embodiments where a permanent connection is desired, the conductive pins may be attached to the conductive lands by solder or conductive adhesive. These approaches may require an additional material to be applied to either the conductive lands or the ends of the conductive posts.

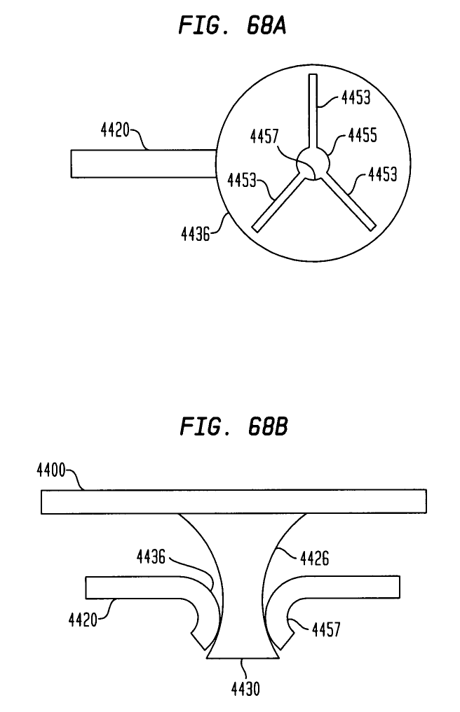

Referring to FIG. 68a, in certain preferred embodiments, a microelectronic assembly includes a conductive trace 4420 and a conductive land 4436. The conductive pad 4436 preferably includes radially extending gaps 4453 that extend outwardly from a center 4455. The radially extending gaps 4453 define flexible leaves 4457 that are divided from one another by the radially extending gaps 4453.

Referring to FIG. 68b, a microelectronic package 4400 including one or more conductive posts 4426 is juxtaposed with a second microelectronic element including the conductive trace 4420 and conductive land 4436 shown in FIG. 68a. As the tip end 4430 of the conductive post 4426 is inserted into the center 4455 of the conductive land 4436, the conductive post flexes the conductive leaves 4457 in an outward direction. The conductive land accommodates vertical displacement of the microelectronic assembly 4400 relative to an opposing microelectronic element because the leaves 4457 will bend when pressed by the conductive post. If the conductive post is pushed sufficiently far into the conductive land 4436, the tip end 4430 of the conductive post 4426 will protrude upon the ends of the leaves 4457, whereby the conductive post will lock to the land by virtue of the concave profile of the conductive post. Thus, for small vertical displacements, the structure in FIGS. 68a-68b provides a compliant, reworkable contact. For a large vertical displacement, however, the conductive land 4436 changes to a locking contact. For small vertical displacements, electrical contact is formed between the tip end 4430 of the conductive post 4436 and the top surface of the conductive land 4436. For large vertical displacements, the sidewalls of the conductive post 4426 contact the leaves 4457 of the conductive land 4436. In certain preferred embodiments, the conductive post can be disconnected from the conductive land, even after the post has been inserted to the position shown in FIG. 68B.

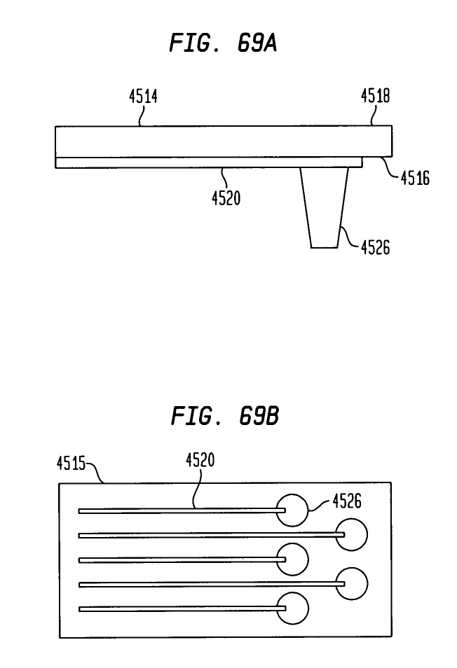

FIGS. 69a and 69b, in certain preferred embodiments of the present invention, a microelectronic assembly includes a flexible dielectric substrate 4514 having a first surface 4516 and a second surface 4518 remote therefrom. The assembly also preferably includes conductive traces 4520 extending over the first face 4516 of the flexible substrate 4515 and conductive posts 4526 electrically interconnected with the conductive traces 4520. The conductive posts 4526 are preferably provided at the ends of the flexible substrate with at least one gap lying between groups of posts that are spaced from one another.

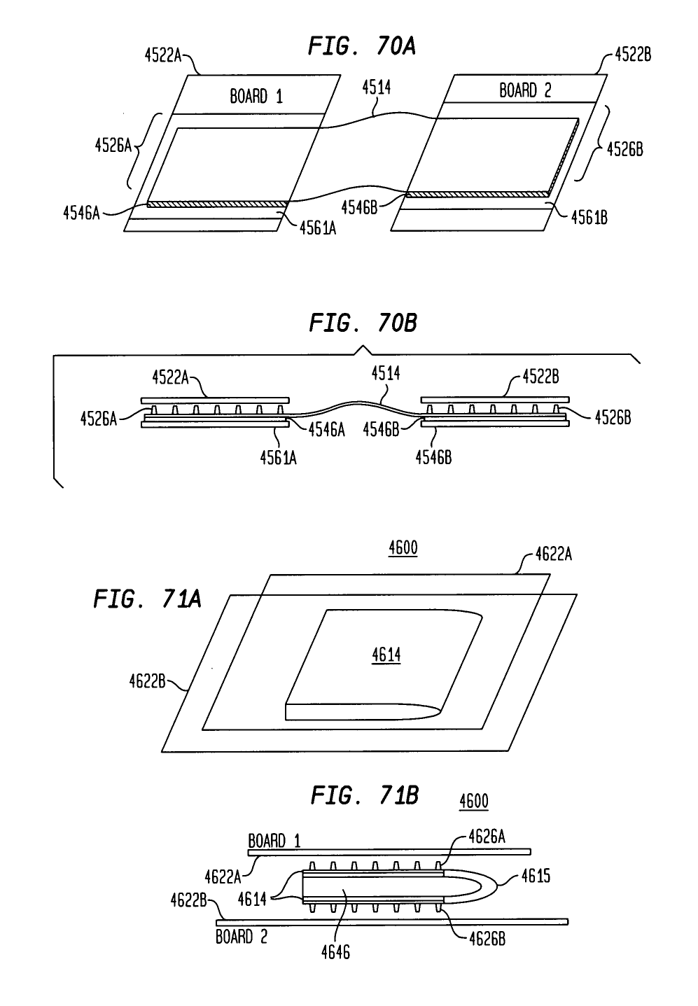

FIGS. 70a and 70b show the conductive posts provided at opposite ends of the flexible substrate 4514. Referring to FIG. 70b, a first set of conductive posts 4526a project from the flexible substrate 4514 and are positioned at a first end of the flexible substrate. A second set of conductive posts 4526b project from the flexible substrate 4514 and are positioned at a second end of the flexible substrate 4514. The first end of the flexible substrate is backed by a first compliant layer 4546a and a backing 4561a. The second set of conductive post 4526b is aligned with a second compliant layer 4546b and a second backing 4561b. The assembly includes a first printed circuit board 4522a in alignment with the first set of conductive posts 4526a and a second printed circuit board 4522b in alignment with the second set of conductive posts 4526b.

FIG. 70a shows a perspective view of the assembly shown in FIG. 70b. By providing a first set of conductive posts 4526a at a first end of the flexible substrate 4514 and a second set of conductive posts 4526b at a second end of the flexible substrate 4514, the flexible substrate 4514 is able to connect two or more printed circuit boards 4522a, 4522b together. In other preferred embodiments, more than two groups of conductive posts may be spaced from one another along the length of the flexible substrate 4514. As a result, more than two printed circuit boards (e.g. three printed circuit boards) may be connected together using the flexible substrate 4514 and the flexible substrate between the conductive posts may be bent as required. Although the present invention is not limited by any particular theory of operation, it is believed that providing groups of conductive posts at both ends of a flexible substrate, or at several sites along the length of the flexible substrate, enables two or more printed circuit boards to be connected together in a flexible arrangement. The conductive posts serve as connectors between the flexible substrate and the printed circuit boards. Due to the cost of dielectric materials, in certain preferred embodiments, it is preferred to use thinner dielectric sheets for supporting the conductive traces and augmenting the thickness of the dielectric sheet in the areas where the conductive posts are located. Increasing the thickness in the area of the conductive posts also increases the inherent flexibility of the flexible circuit, thereby enabling the flexible substrate to be routed through more complex geometries having bends of smaller radii. Initially, the conductive posts may be temporarily attached to the conductive pads on the printed circuit boards by abutting the tips of the posts against the conductive pads. For more permanent connections, the conductive posts may be permanently attached to the conductive pads on the printed circuit board by known methods such as soldering and using conductive adhesives, as well as pressure welding, diffusion bonding, and the locking connectors described herein (FIG. 68A).

FIGS. 71a and 71b show a microelectronic assembly 4600, in accordance with another preferred embodiment of the present invention. Referring to FIG. 71b, the microelectronic assembly includes a flexible substrate 4614 having a first set 4626a and a second set 4626b of conductive posts formed thereon. A mid-section of the flexible substrate 4615 is preferably devoid of conductive posts. The flexible substrate 4614 is folded over so that the first set of conductive posts 4626a face away from the second set of conductive posts 4626b. In certain preferred embodiments, the first set of conductive posts 4626a face away from the second set of conductive posts 4626b. A compliant material such as an elastomer 4646 is disposed between the first and second set of conductive posts 4626a, 4626b. The folded-over flexible substrate assembly may be disposed between a first printed circuit board 4622a and a second printed circuit board 4622b for electrically interconnecting the first and second circuit boards.

FIG. 71a shows a perspective view of the assembly 4600 including a first printed circuit board 4622a overlying a second printed circuit board 4622b. The printed circuit boards are electrically interconnected with one another through folded-over flexible substrate 4614 having the conductive posts projecting from upper and lower surfaces thereof. Although the embodiment shown in FIGS. 71a, 71b show a pair of printed circuit boards connected to the folded flexible substrate, the folded flexible substrate and conductive posts structure may also be used to make connections between a pair of components such as semiconductor chips, or between a semiconductor chip and a printed circuit board. The folded assembly may also be used as an interface converter, performing such functions as redistribution, fan-out, and management of die shrink and component obsolescence. The folded flexible substrate having conductive posts may also be used to form connections in flat panel displays, car-wiring looms that link printed circuit boards and personality modules in portable consumer products. In certain preferred embodiments, the conductive posts may have different lengths and/or different heights. If some of the pins are designed to be taller, these pins will make the first contact and break from contact last, which facilitates hot swapping of parts during testing and use.

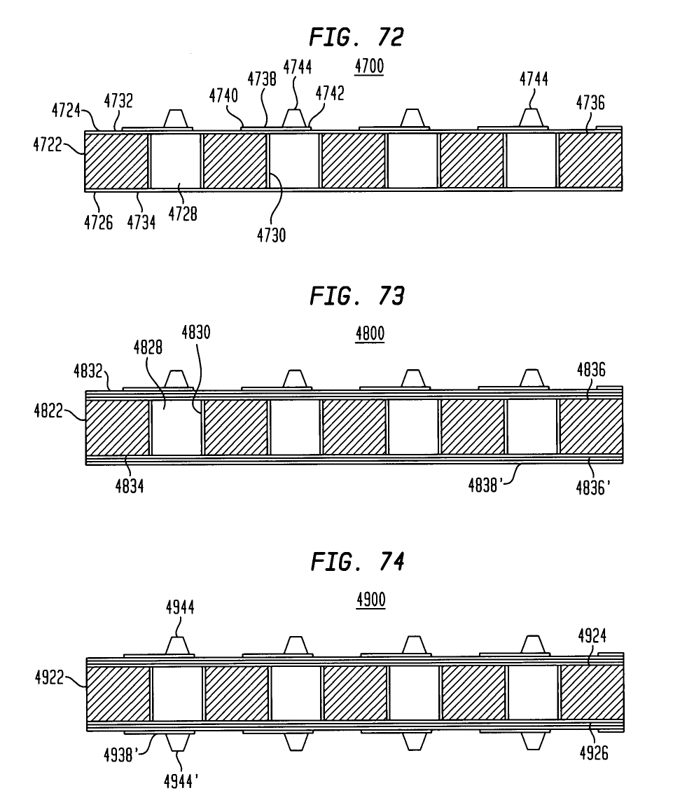

FIG. 72 shows a microelectronic assembly 4700 including a substrate 4722, such as a printed wiring board, including a top surface 4724 and a bottom surface 4726. The substrate 4722 includes a series of vias 4728 extending between the top surface 4724 and the bottom surface 4726. The vias are preferably covered by a metal layer 4730 so as to form metalized vias, including first conductive pads 4732 overlying the top surface 4724 and second conductive pads 4734 overlying the bottom surface 4726. The first and second conductive pads 4732, 4734 preferably extend outwardly in a radial direction from the vias 4728. A flexible substrate 4736 is secured over top surface 4724 of the substrate 4722. The flexible substrate is preferably a dielectric substrate such as a polyimide sheet. The flexible substrate has conductive traces 4738 formed thereon. Each conductive trace has a first end 4740 and a second end 4742, with conductive posts 4744 formed over the second ends 4742 of the conductive traces 4738. The conductive posts 4744 are preferably in at least partial alignment with the vias 4728 extending through the substrate 4722. In more preferred embodiments, the conductive posts 4744 are aligned with the vias 4728 in the substrate 4722. Although the present invention is not limited by any particular theory of operation, it is believed that aligning the conductive posts 474 with the vias 4728 and providing a conductive post on a flexible substrate 4736, enables the conductive posts to move at least vertically relative to the printed wiring board 4722. In certain preferred embodiments, the flexible substrate is laminated to the substrate using an adhesive such as an adhesive sheet. In further preferred embodiments, the flexible substrate 4736 may be placed in tension over the substrate so as to form a planar pin grid array atop the substrate.

Referring to FIG. 73, in another preferred embodiment of the present invention, a microelectronic assembly 4800 is generally similar to the assembly shown in FIG. 72. The microelectronic assembly 4800 includes a substrate 4822 having vias 4828 extending therethrough. The vias are metalized with metal layer 4830. The metal layer forms first conductive pads 4832 atop the substrate and second conductive pads 4834 underlying the substrate. A first flexible substrate 4836 is secured atop the substrate so that the conductive posts 4844 are in alignment with the vias 4828 extending through the substrate. A second flexible substrate 4836′ having conductive traces 4838 formed thereon is disposed over the bottom of the substrate 4822. The conductive posts 4844 and the conductive traces 4838′ are preferably in electrical contact with one another through the metalized vias 4828.

FIG. 74 shows a microelectronic assembly 4900 in accordance with another preferred embodiment of the present invention. The microelectronic assembly is generally similar to the assembly shown in FIG. 37, and includes a second set of conductive posts 4944′ being electrically connected with a second set of conductive traces 4938′. As such, a first set of conductive posts 4944 project from a top surface 4924 of the substrate 4922 and a second set of conductive posts 4944′ project from the bottom surface 4926 of the substrate 4922. Although the present invention is not limited by any particular theory of operation, it is believed that providing conductive posts on both sides of the substrate, whereby the posts are connected to a flexible substrate overlying a via, enables additional mechanical decoupling of the electrical interconnections.

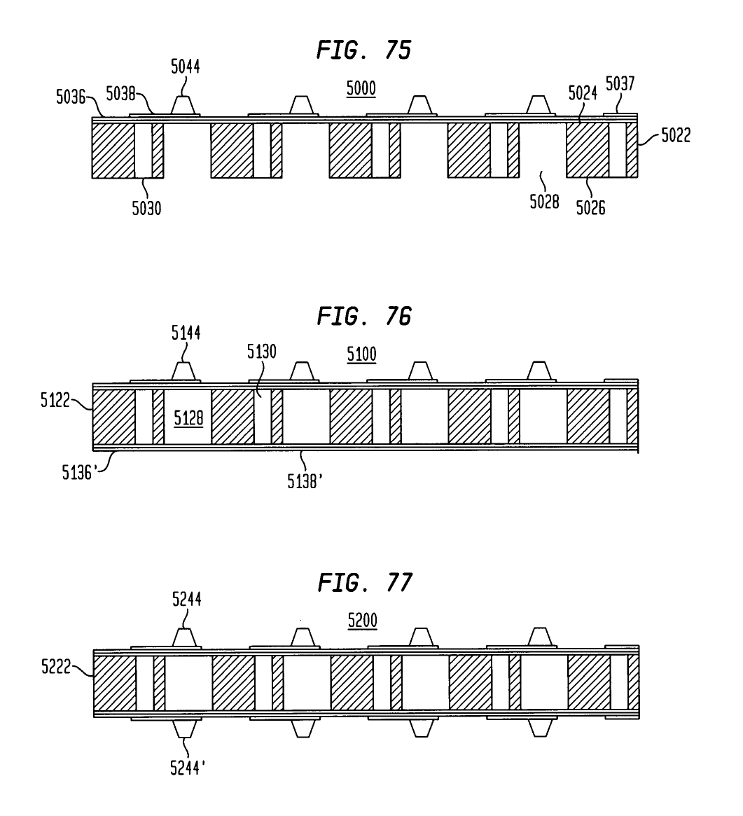

FIG. 75 shows a microelectronic assembly 5000 in accordance with another preferred embodiments of the present invention. The microelectronic assembly includes a substrate 5022 having a top surface 5024 and a bottom surface 5026. The substrate 5022 includes one or more vias 5028 extending between the top and bottom surfaces 5024, 5026. The substrate 5022 also includes elongated conductive elements 5030 that extend between top surface 5024 and bottom surface 5026. The elongated conductive elements 5030 are preferably made of any material that is able to conduct electrical signals. Microelectronic assembly also includes a flexible dielectric substrate 5036 having circuit traces 5038 and conductive posts 5044 formed thereon. The microelectronic assembly 5000 also includes conductive pads 5037 in alignment with upper ends of the elongated conductive elements 5030. After the flexible substrate 5036 has been disposed atop the substrate 5022, the conductive traces 5038 are electrically interconnected with the elongated conductive elements 5030 through the conductive pads 5037. As a result, the conductive posts 5044 are in electrical contact with the elongated conductive elements 5030. The conductive posts 5044 are preferably in alignment with the vias 5028 so that the posts may move vertically relative to the substrate 5022. As a result, the conductive posts 5044 are mechanically decoupled from the substrate 5022 and are movable relative to the substrate.

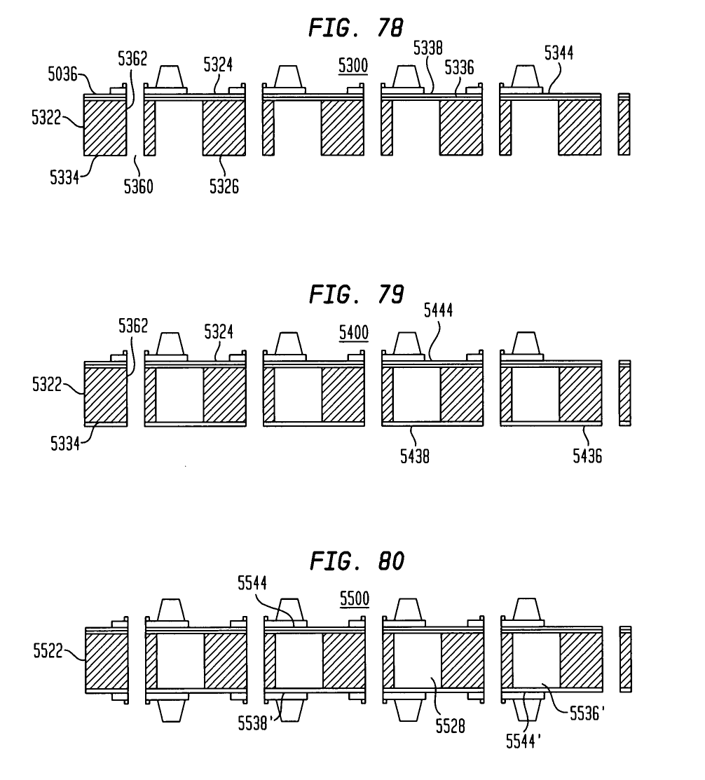

In another preferred embodiment shown in FIG. 76, a microelectronic assembly 5100 includes all of the features shown FIG. 75, plus a second flexible substrate 5136′ having second conductive traces 5138′ formed thereon. The ends of the second conductive traces 5138′ are in substantial alignment with the vias 5128 extending through the substrate 5122. The second set of conductive traces 5138′ are preferably in electrical contact with the conductive posts 5144 through the elongated conductive elements 5130 extending through the substrate 5122.

Referring to FIG. 77, in another preferred embodiment of the present invention, a microelectronic assembly 5200 includes a second set of conductive posts 5244′ that project from the bottom of the substrate 5222. The second set of conductive posts 5244′ are in general alignment with the first set of conductive posts 5244 projecting from an upper surface of the substrate 5222. As such, the first and second sets of conductive posts are mechanically decoupled from the substrate 5222, and are movable relative to the substrate.

Referring to FIG. 78, in another preferred embodiment of the present invention, a microelectronic assembly 5300 includes a substrate 5322 having a top surface 5324 and a bottom surface 5326. The substrate 5322 also includes vias 5328 extending between the top and bottom surfaces 5324, 5326. A flexible substrate 5336 is preferably secured over the first surface 5324 of the substrate 5322. The flexible substrate 5336 includes conductive traces 5338 and conductive posts 5344 connected with the conductive traces 5338. Holes are then punched through the substrate 5322 and the flexible substrate 5336 to form auxiliary vias 5360 that lie adjacent the main vias 5328. Each of the auxiliary vias is metalized with a conductive material 5362 to form a conductive path between top and bottom surfaces of the substrate 5322. The upper ends of the metalized auxiliary vias 5360 are in electrical contact with the conductive traces 5338. The alignment of the conductive post 5344 with the main vias 5328 enables the conductive posts 5344 to move relative to the substrate 5322, while the metalized auxiliary vias enable the conductive post 5344 to be in electrical contact with the conductive pads 5334 extending over the bottom surface of the substrate 5322.

Referring to FIG. 79, in another preferred embodiment of the present invention, a second flexible substrate 5436′ is secured over the bottom surface 5426 of a substrate 5422. The second flexible substrate 5436′ includes a second set of conductive traces 5438′ extending over the second flexible substrate 5436′. The second set of conductive traces 5438′ include a portion that is in alignment with the main vias 5428. The conductive posts 5444 of the first flexible substrate 5436 are in electrical contact with the second set of conductive traces 5438′ through the metalized auxiliary vias 5460.

Referring to FIG. 80, in another preferred embodiment of the present invention, a microelectronic assembly 5500 includes a second set of conductive posts 5544′ that are electrically connected with the second set of conductive traces 5538′ on the second substrate 5536′. The first set of conductive posts 5544 and the second set of conductive posts 5544′ are in alignment with the main vias 5528. As a result, the first and second set of conductive posts are mechanically decoupled from the substrate 5522.

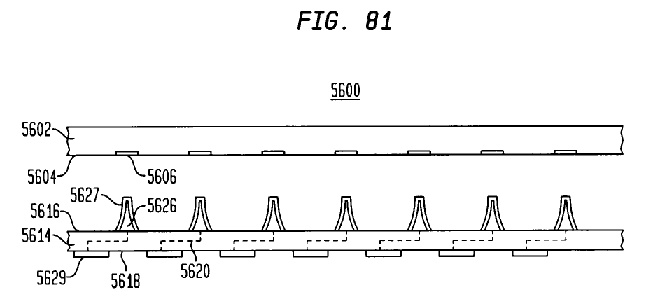

Referring to FIG. 81, in certain preferred embodiments of the present invention, a microelectronic assembly 5600 includes a flexible substrate 5614 having a first surface 5616 and a second surface 5618. The flexible substrate 5614 includes conductive posts 5626 projecting from the first surface 5616. Each of the conductive posts 5626 is covered with a layer of a noble metal such as gold 5627. The substrate 5614 also preferably includes terminals 5629 provided on the second surface 5618 thereof. The conductive post 5626 and the conductive terminals 5629 are electrically interconnected through conductive traces 5620. The flexible substrate is preferably made from a dielectric material such as polyimide.

The flexible substrate 5614 is desirably juxtaposed with a microelectronic element such as a semiconductor chip 5602 having a front face 5604 including contacts 5606. During assembly, the contacts 5606 of the chip 5602 are placed in substantial alignment with the conductive post 5626.

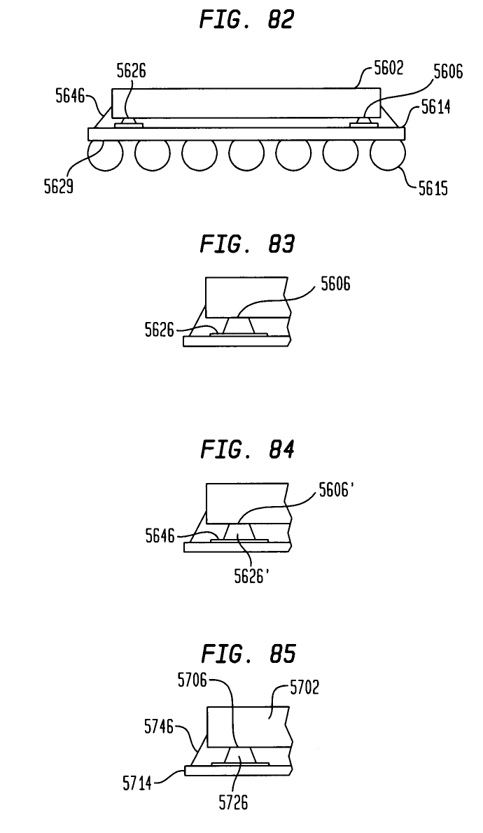

Referring to FIG. 82, the contacts 5606 of chip 5602 are abutted against the tip ends of the conductive posts 5626 for forming an electrical interconnection therebetween. An encapsulant material 5646 may be provided between the contact bearing face of the chip 5602 and the first surface of the flexible substrate 5614. Conductive elements such as solder balls 5615 may be provided over the conductive terminals 5629 provided at the second surface of the flexible substrate 5614. Referring to FIGS. 81 and 82, the flexibility of the substrate 5614 and the offset of the conductive elements 5615 and the conductive posts 5626 enables the conductive terminals 5629 to move relative to the contacts 5606 of the chip 5602.

Referring to FIG. 83, in one preferred embodiment, the conductive post 5626 is plated with a noble metal such as gold and is placed in direct contact with the chip contact 5606. The chip contact 5602 is preferably made of a conductive material such as aluminum. The electrical interconnection between the conductive posts 5626 and the chip contact 5602 may be made using a diffusion bonding process.

FIG. 84 shows another embodiment whereby the electrical interconnection between the conductive post 5626′ and the chip contact 5602′ is made using an anisotropic conductive film or anisotropic conductive paste 5646′ including conductive particles. As shown in FIG. 84, conductive particles are disposed between the contact 5602′ and the conductive post 5626′ for forming the electrical interconnection.

FIG. 85 shows another embodiment, whereby the chip 5702 and the substrate 5714 are held together using a non-conductive film 5746. The chip 5702 is pressed toward the flexible substrate 5714 so that the chip contact 5706 is in close contact with the tip end of the conductive post 5726. While the chip and the substrate are held in close contact, the non-conductive film 5746 is preferably cured so as to form a permanent assemblage of the chip 5702 and the substrate 5714 and a permanent electrical interconnection between the posts 5726 and the chip contact 5706.

In certain preferred embodiments of the present invention, a particle coating such as that disclosed in U.S. Pat. Nos. 4,804,132 and 5,083,697, the disclosures of which are incorporated by reference herein, may be provided on one or more electrically conductive parts of a microelectronic package for enhancing the formation of electrical interconnections between microelectronic elements and for facilitating testing of microelectronic packages. The particle coating is preferably provided over conductive parts such as conductive terminals or the tip ends of conductive posts. In one particularly preferred embodiment, the particle coating is a metalized diamond crystal coating that is selectively electroplated onto the conductive parts of a microelectronic element using standard photoresist techniques. In operation, a conductive part with the diamond crystal coating may be pressed onto an opposing contact pad for piercing the oxidation layer present at the outer surface of the contact pad. The diamond crystal coating facilitates the formation of reliable electrical interconnections through penetration of oxide layers, in addition to traditional wiping action.

As discussed above, the motion of the posts may include a tilting motion. This tilting motion causes the tip of each post to wipe across the contact pad as the tip is engaged with the contact pad. This promotes reliable electrical contact. As discussed in greater detail in the co-pending, commonly assigned application Ser. No. 10/985,126 filed Nov. 10, 2004, entitled “MICRO PIN GRID ARRAY WITH WIPING ACTION,” the disclosure of which is incorporated by reference herein, the posts may be provided with features which promote such wiping action and otherwise facilitate engagement of the posts and contacts. As disclosed in greater detail in the co-pending, commonly assigned application Ser. No. 10/985,119 filed Nov. 10, 2004, entitled “MICRO PIN GRID WITH PIN MOTION ISOLATION,” the disclosure of which is also incorporated by reference herein, the flexible substrate may be provided with features to enhance the ability of the posts to move independently of one another and which enhance the tilting and wiping action.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A microelectronic package comprising:
a microelectronic element having a first face including contacts;
a flexible substrate having a first surface and a second surface, conductive posts projecting from said first surface and conductive terminals accessible at said second surface, at least some of said conductive terminals and said conductive posts being electrically interconnected and at least some of said conductive terminals being offset from said conductive posts;
said first surface of said flexible substrate being juxtaposed with said first face of said microelectronic element so that said conductive posts project from said flexible substrate toward said first face of said microelectronic element, wherein said conductive posts are electrically interconnected with said contacts of said microelectronic element and at least some of said conductive terminals are movable relative to said microelectronic element.

2. The package as claimed in claim 1, wherein said microelectronic element comprises a semiconductor chip.

3. The package as claimed in claim 1, wherein said microelectronic element comprises a semiconductor wafer.

4. The package as claimed in claim 1, wherein at least some of said conductive posts are in direct contact with at least some of said contacts on said microelectronic element.

5. The package as claimed in claim 1, further comprising a conductive material disposed between said conductive posts and said contacts of said microelectronic element.

6. The package as claimed in claim 1, wherein said conductive posts have an outer surface comprising a noble metal.

7. The package as claimed in claim 1, further comprising conductive traces provided on said flexible substrate, wherein said conductive traces electrically interconnect at least some of said conductive posts with at least some of said conductive terminals.

8. The package as claimed in claim 7, wherein said conductive traces extend along the first surface of said flexible substrate.

9. The package as claimed in claim 7, wherein said conductive traces extend along the second surface of said flexible substrate.

10. The package as claimed in claim 7, wherein said conductive traces extend between said first and second surfaces of said flexible substrate.

11. The package as claimed in claim 1, wherein said flexible substrate comprises a dielectric sheet.

12. The package as claimed in claim 1, further comprising a compliant material disposed between said flexible substrate and said microelectronic element.

13. The package as claimed in claim 1, wherein said conductive posts are disposed in an array so that said conductive posts define a plurality of zones of said flexible substrate, each such zone being bounded by a plurality of said conductive posts defining corners of such zone, different ones of said conductive terminals being disposed in different ones of said zones.

14. The microelectronic package as claimed in claim 12, wherein only one of said conductive terminals is disposed in each of said zones.

15. A microelectronic assembly comprising a package as claimed in claim 1 and a circuit panel having contact pads, said conductive terminals of said flexible substrate confronting said contact pads and being electrically connected thereto.

16. A microelectronic package comprising:
a microelectronic element having a front face with contacts;
a flexible substrate juxtaposed with said microelectronic element, said flexible substrate having a first surface facing said microelectronic element and a second surface facing away from said microelectronic element;
a plurality of conductive posts extending from said first surface of said flexible substrate and projecting toward said microelectronic element, said conductive posts being electrically connected to said contacts of said microelectronic element; and
said flexible substrate having conductive terminals accessible at said second surface thereof, said conductive terminals being electrically interconnected with said conductive posts, said flexible substrate being supported above said front face of said microelectronic element by said conductive posts so that said substrate is at least partially unconstrained in flexure, wherein said conductive terminals are movable relative to said microelectronic element.

17. The microelectronic package as claimed in claim 16, wherein at least some of said conductive posts are offset from said conductive terminals.

18. The microelectronic package as claimed in claim 16, further comprising electrically conductive traces on said flexible substrate, at least some of said conductive traces electrically interconnecting at least some of said posts to at least some of said terminals.

19. A microelectronic assembly comprising:
(a) a microelectronic package comprising:
a microelectronic element having a first face including contacts;
a flexible substrate having a first surface and a second surface, conductive posts projecting from said first surface and conductive terminals accessible at said second surface, said conductive posts and said conductive terminals being electrically interconnected and at least some of said conductive terminals being offset from said conductive posts;
said first surface of said flexible substrate being juxtaposed with said first face of said microelectronic element so that said conductive posts project from said flexible substrate toward said first face of said microelectronic element, wherein said conductive posts are electrically interconnected with said contacts of said microelectronic element and at least some of said conductive terminals are movable relative to said first face of said microelectronic element;
(b) a circuit panel having contact pads, said conductive terminals of said flexible substrate confronting said contact pads;
(c) a bonding material securing said conductive terminals of said flexible substrate to said contact pads, said bonding material extending between said conductive terminals and said pads.

20. The assembly as claimed in claim 19, wherein said flexible substrate is at least partially unconstrained in flexure, said conductive terminals being attached to said flexible substrate so that said conductive terminals can move relative to said microelectronic element upon flexure of said substrate.
